(19) United States
(12) Patent Application Publication
(10) Pub. No.: US 2007/0011543 A1
(43) Pub. Date: Jan. 11, 2007

(54) Test pattern generation method

(76) Inventors: Shinichi Yoshimura, Kyoto (JP); Tomokazu Miura, Kyoto (JP); Mitsuyasu Ohta, Osaka (JP); Osamu Ichikawa, Osaka (JP)

Correspondence Address: MCDERMOTT WILL & EMERY LLP, 600 13TH STREET, N.W., WASHINGTON, DC, 20005-3096, US

(21) Appl. No.: 11/447,302

(22) Filed: Jun. 6, 2006

(30) Foreign Application Priority Data
Jun. 6, 2005 (JP) 2005-166065
May 31, 2006 (JP) 2006-152172

(51) Int. Cl. G01R 31/28; G06F 11/00

(52) U.S. Cl. 714/738

(57) ABSTRACT

A high-quality test pattern for testing a delay fault is generated at a high speed. In order that a second test pattern provided at a test cycle that follows a test cycle should be generated, a fault value set up in a circuit is propagated to an observation point. At a branch point in the circuit, a signal line for propagating the fault value is selected from the branches. Then, activation and justification are performed so that a value of the signal line in the circuit is acquired. When the activation and the justification have been successful, the second test pattern is updated on the basis of the acquired value of the signal line. In the selection of the signal line, one of branches is selected on the basis of the length of the longest path from each branch to the observation point.

### BACKGROUND OF THE INVENTION

1. Field of the Invention

The present invention relates to a test pattern generation method for generating a test pattern for testing a delay fault in a semiconductor integrated circuit.

2. Description of the Background Art

In the prior art, a method is known in which for the purpose of testing of a delay fault occurring during signal propagation in a semiconductor integrated circuit, delay faults are classified according to several fault models, and then a test pattern is generated in accordance with the feature of each fault model. Major fault models for delay faults are a path delay fault model and a transition fault model. The path delay fault model permits detection of a delay fault caused by pile-up of microscopic defects generated on a test target path and a large delay fault located at a position. In contrast, the transition fault model permits detection of a large delay fault located at a position in a signal line or a gate serving as a test target.

In general, in testing of a delay fault, two test sequences (test sequences T1 and T2, hereinafter) are necessary. An automatic test apparatus provides a test sequence T1 to a test target circuit at a particular timing, and then provides a test sequence T2 at the next test cycle. This test sequence is denoted by <T1,T2>. Described below are: a test pattern generation method for testing a path delay fault (a path delay fault test pattern generation method, hereinafter); and a test pattern generation method for testing a transition fault (a transition fault test pattern generation method, hereinafter).

A path delay fault test pattern generation method is described for example in C. J. Lin and S. M. Reddy, “On Delay Fault Testing in Logic Circuits”, IEEE Transactions on Computer-Aided Design, CAD-6(5), pp. 694-703, 1987 or in K. T. Cheng, A. Krstic and H. C. Chen, “Generation of High Quality Tests for Robustly Untestable Path Delay Faults”, IEEE Transactions on Computers, 45(12), pp. 1379-1392, 1996. A transition fault test pattern generation method is described for example in E. S. Park and M. R. Mercer, “An Efficient Delay Test Generation System for Combinational Logic Circuits”, IEEE Transactions on Computer-Aided Design, 11(7), pp. 926-938, 1992.

First, a path delay fault test pattern generation method is described below. In the path delay fault test pattern generation method, a test pattern is generated for example by assigning five logical values shown in FIG. 40 to each signal line in a test target circuit in accordance with implication tables shown in FIGS. 41A-41C and path activation tables shown in FIGS. 42A-42D. A logical value S0 shown in FIG. 40 indicates that the value of the signal line is 0 in both of the test sequences T1 and T2. A logical value S1 indicates that the value of the signal line is 1 in both of the test sequences T1 and T2. A logical value U0 indicates that the value of the signal line is X (0 or 1) in the test sequence T1 and 0 in the test sequence T2. A logical value U1 indicates that the value of the signal line is X in the test sequence T1 and 1 in the test sequence T2. A logical value XX indicates that the value of the signal line is X in both of the test sequences T1 and T2.

FIGS. 41A-41C show implication tables for an AND gate, an OR gate, and an inverter. Each implication table describes the output value for each combination of the above-mentioned five input values. For example, an output y for the case that an input “a” to the AND gate is S0 while an input b is U0 is acquired as follows. Since the input “a” is S0, the value of the input “a” is 0 in both of the test sequences T1 and T2. Further, since the input b is U0, the value of the input b is X in the test sequence T1 and 0 in the test sequence T2. Thus, the value of y becomes 0 in both of the test sequences T1 and T2. Using the five values, this situation is expressed by a statement that the output y is S0.

In the path delay fault test pattern generation method, when a test target path is activated, a robust condition or a non-robust condition is used (see FIG. 42). When the robust condition is used, a delay fault on the test target path is correctly detected even when another delay fault occurs in an input connected to a gate on the test target path but not located on the test target path (a non-test target input, hereinafter). On the other hand, when the non-robust condition is used, a delay fault on the test target path could not correctly be detected when another delay fault occurs in a non-test target input.

In the following description, ND denotes a rise transition in the signal line, while D denotes a fall transition in the signal line. For example, the condition for ensuring that in the AND gate, when the value of the input “a” varies from 0 to 1, the value of the output y should necessarily vary (that is, a rise transition ND should be propagated from the input “a” to the output y) is that a value U1 is provided to the input b (see FIG. 42A). Thus, the condition for ensuring that in the AND gate, the rise transition ND should be propagated under the robust condition is U1 (that is, a value U1 is provided to the non-test target input). Further, the condition for ensuring that in the OR gate, when the value of the input “a” varies from 1 to 0, the value of the output y should necessarily vary (that is, a fall transition D should be propagated from the input “a” to the output y) is that a value U0 is provided to the input b (see FIG. 42B). Thus, the condition for ensuring that in the OR gate, the fall transition D should be propagated under the robust condition is U0 (that is, a value U0 is provided to the non-test target input).

FIG. 42C shows activation conditions under the robust condition for an AND gate, a NAND gate, an OR gate, and a NOR gate. FIG. 42C shows values to be provided to the non-test target input of each gate of these kinds in order that a rise transition ND or a fall transition D should be propagated under the robust condition. FIG. 42D shows activation conditions under the non-robust condition for an AND gate, a NAND gate, an OR gate, and a NOR gate. FIG. 42D shows values to be provided to the non-test target input of each gate of these kinds in order that a rise transition ND or a fall transition D should be propagated under the non-robust condition.

When a value that satisfies the robust condition can be set up to the non-test target inputs of all the gates on the test target path, the test target path is referred to as a robust testable path. Further, when a value that satisfies the non-robust condition can be set up to the non-test target input of at least one of the gates on the test target path, the test target path is referred to as a non-robust testable path. A test pattern for testing a non-robust testable path is preferable to be constructed such that as many delay faults as possible on a test target path can be tested even when a delay fault occurs in a non-test target input. Such a test pattern is generated by a method in which a path for setting up a value to the non-test target input is considered such that the propagation delay value between the non-test target input and the gate on the test target path should be maximized or by a method in which when a multi-input gate is present on the test target path, a value for satisfying the robust condition is set up to as many non-test target inputs as possible (see K. T. Cheng, “Delay Fault Testing for VLSI Circuits”, pp. 52-53, pp. 112-113, 1998).

FIG. 43 shows an example of a test target circuit. Symbols SFF1-6 shown in FIG. 43 indicate scan flip-flops (each referred to as a scan FF, hereinafter). The entirety of these constitutes a scan chain. In each of the SFF1-6, when a clock signal inputted to a CK terminal rises, an input signal is acquired through a DT terminal in the case that an input signal through an SE terminal indicates a test mode. In contrast, in the case that the input signal through the SE terminal indicates a normal mode, an input signal is acquired through a D terminal. Thus, when a clock signal is inputted in the test mode, an input signal through a scan input terminal SIN is outputted through a Q-output of the SFF1. Then, Q-outputs of the SFF1-5 appear on the Q-outputs of the SFF2-6, respectively. The Q-output of the SFF6 is outputted to the outside via an external output terminal PO1.

A test pattern for testing a path delay fault occurring on a path P (a path extending from an input terminal X3 through gates g2, g5, and g6 to the SFF6; referred to as a test target path P, hereinafter) included in the test target circuit shown in FIG. 43 is generated as follows. First, as shown in FIG. 43, a signal transition is set up to each signal line on the test target path P. Then, in accordance with the path activation table shown in FIG. 42C, a signal value for activating each gate is provided to the non-test target input of each gate on the test target path P. Further, in accordance with the implication table shown in FIG. 41, a signal value to be provided to each input signal line is determined on the basis of the signal value provided to each signal line (see FIG. 44).

As a result of the above-mentioned processing, {SFF1, SFF2, SFF3, SFF4, SFF5}={0, X, 0, 0, X} is generated as a test sequence T1, while {SFF1, SFF2, SFF3, SFF4, SFF5}={0, X, 1, 0, 0} is generated as a test sequence T2. At last, the test sequence <T1,T2> is converted into a serial pattern. The test sequence T2 is obtained by a method (SKEWED-LOAD technique) in which the value set up to each scan FF in the test sequence T1 is further scan-shifted by one clock cycle, or alternatively by a method (BROAD-SIDE technique) in which after a value is set up to each scan FF in the test sequence T1, the circuit is operated normally by one clock cycle. In either method, justification processing of determining whether the value of the test sequence T2 can be set up to each scan FF is necessary. As for the test target path P included in the test target circuit shown in FIG. 43, a test pattern shown in FIG. 45A is obtained in the SKEWED-LOAD technique, while a test pattern shown in FIG. 45B is obtained in the BROAD-SIDE technique.

Next, a transition fault test pattern generation method is described below. In the transition fault test pattern generation method, a test pattern is generated by setting up a signal transition to a signal line or a gate serving as a test target and then determining a signal value for each gate such that the signal transition should be propagated to an external output or an observation flip-flop. At that time, a signal value is assigned to the activation path extending from the signal line or the gate serving as a test target to the external output or the observation flip-flop, in accordance with a predetermined path activation table and implication table. FIG. 46 shows an example of a path activation table and an implication table for an AND gate.

FIG. 47A shows an example of a test target circuit. In the test target circuit shown in FIG. 47A, a test pattern for testing a (slow-to-rise) transition fault where a rise transition in the output of a NAND gate g3 becomes slow is generated as follows. First, as shown in FIG. 47A, {X1, X2, X3, X4, X5}={X, X, 0, X, X} is generated as a test sequence T1 in order to provide an initial value of 0 to the output of the NAND gate g3. Then, a stuck fault is assumed where the output of the fault gate g3 is fixed to the initial value 0 (the set-up initial value). Thus, {X1, X2, X3, X4, X5}={0, X, 1, 1, 1} is generated as a test sequence T2 for testing this stuck fault (see FIG. 47B). The test sequence <T1,T2> acquired by the above-mentioned processing serves as a test sequence for testing the slow-to-rise fault in the output of the NAND gate g3.

When a transition fault model is used, the total number of faults assumed does not depend on the structure of the circuit and is equal to the total number of input and output terminals of the gates in the circuit. Thus, when a transition fault model is used, the number of states to be treated in test sequence generation processing or detection determination processing remains in the order of magnitude of the number of gates. Accordingly, even when a prior art method is employed, a test pattern can be obtained that has nearly a perfect detection ratio. In contrast, when a path delay fault model is used, the total number of faults assumed depends on the structure of the circuit and is, in a maximum case, proportional to an exponent of the number of gates in the circuit. From the perspective of reliability, the use of a path delay fault model is preferred where comprehensive test is performed on all the propagation paths for signal transition. Nevertheless, execution of a path delay fault test pattern generation method requires a long time depending on the number of test target paths. Thus, the path delay fault test pattern generation method has a problem that a test pattern for a large-scale circuit cannot be generated within a practical time.

In order to solve this problem, Japanese Laid-Open Patent Publication No. H11-218563 discloses a method of selecting a path to be adopted as a test target for a path delay fault from among a large number of paths in a test target circuit. In this method, first, paths that have a design delay value exceeding a predetermined threshold are selected from all the paths in the test target circuit. Then, among two paths included in the selected paths, it is determined which one should be adopted as a test target for a path delay fault.

Further, Japanese Laid-Open Patent Publication No. 2001-51027 discloses another method of selecting a path to be adopted as a test target for a path delay fault. In this method, a path that has a design delay value smaller than a predetermined threshold and that can be activated is determined as being detectable, on the basis of design delay information of the test target circuit and a test sequence (random numbers may alternatively be employed) that activates paths of a number sufficiently smaller than the number of paths in the test target circuit. As for a fault that cannot be detected even when the above-mentioned test sequence or random numbers are used, after selecting a test target signal line, the processing of acquiring the longest activation path with assigning an activation condition to the output side is performed.

Nevertheless, in the method disclosed in Japanese Laid-Open Patent Publication No. H11-218563, the number of paths selected as test targets for a path delay fault is still extremely large. Thus, in practice, a path delay fault cannot be tested for all the paths selected by this method.

Further, in the method disclosed in Japanese Laid-Open Patent Publication No. 2001-51027, since a short test sequence or random numbers are provided first, a detectable path delay fault can be detected efficiently. Nevertheless, as for a path delay fault that cannot be detected by this processing, the processing of acquiring the longest activation path with assigning an activation condition is performed. In general, a logic circuit having a branching and re-convergence structure has a property that an activation condition can be assigned but inconsistency arises easily in justification processing (the processing of assigning a signal to an input side storage element or an external input terminal). Thus, when the method disclosed in Japanese Laid-Open Patent Publication No. 2001-51027 is applied to a logic circuit having a branching and re-convergence structure, even a path having a long propagation time need be searched for repeatedly, and hence the processing time increases.

### SUMMARY OF THE INVENTION

An object of the present invention is to provide a test pattern generation method for generating at a high speed a high-quality test pattern for testing a delay fault.

A test pattern generation method according to the present invention is a test pattern generation method for generating a first test pattern and a second test pattern which is provided at a next test cycle, for the purpose of detection of a delay fault that occurs in a test target circuit, the method comprising steps of: acquiring as the first test pattern a combination of input values that cause a value of a test target signal line to agree with an initial value corresponding to an assumed delay fault; and acquiring as the second test pattern a combination of input values for propagating to an observation point the fault value set up to the test target signal line in correspondence to the assumed delay fault, wherein the step of acquiring a second test pattern includes steps of: selecting a signal line for propagating the fault value, from among a plurality of branches at a branch point included in the test target circuit; performing activation and justification in order to propagate the fault value to the selected signal line, and thereby acquiring a value of the signal line included in the test target circuit; and

updating the second test pattern on the basis of the acquired value of the signal line, when the activation and the justification have been successful, and wherein in the step of selecting a signal line, one of branches is selected on the basis of a length of the longest path from each branch to the observation point (a first aspect).

In this method, the test target signal line may be selected from control points and branches included in the test target circuit. Further, in the step of selecting a signal line, signal lines may be collectively selected that constitute a path that leads to a stem or an observation point which can be reached from a branch without going via a branch point (a second aspect).

Alternatively, in the step of selecting a signal line, when the length of the longest test path including a particular branch does not satisfy a predetermined criterion, the branch may be excluded from candidates of signal line selection (a third aspect).

Alternatively, in the step of acquiring the value of a signal line, activation may be performed according to a robust condition. Further, the test pattern generation method may further comprise a step of updating the first test pattern on the basis of the acquired value of the signal line, when the activation under the robust condition and the justification have been successful (a fourth aspect).

Alternatively, in the step of acquiring the value of a signal line, activation may be performed according to a non-robust condition (a fifth aspect).

Alternatively, in the step of acquiring the value of a signal line, activation may be performed according to a robust condition first, and then when activation under the robust condition has been unsuccessful for all branches that are selectable at a particular branch point, activation may be performed according to a non-robust condition. Further, the test pattern generation method may further comprise a step of updating the first test pattern on the basis of the acquired value of the signal line, when the activation under the robust condition and the justification have been successful (a sixth aspect).

Alternatively, in the step of acquiring the value of a signal line, for a selected branch, activation may be performed according to a robust condition, and then when the processing has been unsuccessful, activation may be performed according to a non-robust condition. Further, the test pattern generation method may further comprise a step of updating the first test pattern on the basis of the acquired value of the signal line, when the activation under the robust condition and the justification have been successful (a seventh aspect).

Alternatively, the step of acquiring a second test pattern may further include a step of backtracking to a branch point where signal line selection has been performed in the past, when the activation and the justification have been unsuccessful for all branches that are selectable at a particular branch point (an eighth aspect).

Alternatively, in the step of backtracking, the backtracking may be performed to a branch point where signal line selection has been performed immediately before (a ninth aspect).

Alternatively, in the step of backtracking, the backtracking may be performed to a nearest branch point where signal line selection has been performed, among branch points where a length of the longest test path including any one of not-selected branches satisfies a predetermined criterion (a tenth aspect).

Alternatively, in the step of backtracking, the backtracking may be performed to a branch point having the maximum length of the longest test path including a not-selected branch, among branch points where signal line selection has been performed in the past (an eleventh aspect).

Alternatively, in the step of backtracking, the backtracking may be performed in a state that the value of a control point acquired in order to propagate a fault value beyond the branch point serving as a backtracking destination is holding intact (a twelfth aspect).

Alternatively, when the length of the longest test path including a particular control point does not satisfy a predetermined criterion, the control point may be excluded from the test target signal line. Further, when the length of the longest test path including a particular branch does not satisfy a predetermined criterion, the branch may be excluded from the test target signal line and excluded from the candidates of signal line selection in the step of selecting a signal line (a thirteenth aspect).

Alternatively, the test pattern generation method may further comprise a step of specifying a control point, a signal line, and an observation point which are included in the test target circuit. Further, among the signal lines included in the test target circuit, a signal line that constitutes a path leading to a branch point which can be reached from the specified control point without going via a branch point, a signal line that constitutes a path extending from the specified signal line to an arbitrary observation point, and a signal line included solely in a path that leads to the specified observation point may be excluded from the test target signal line and excluded from the candidates of signal line selection in the step of selecting a signal line, so that a fixed value may be provided at the step of acquiring the value of a signal line (a fourteenth aspect).

A fifteenth aspect of the present invention is directed to a test pattern generation method for generating a first test pattern and a second test pattern which is provided at a next test cycle, for the purpose of detection of a delay fault that occurs in a test target circuit. The test pattern generation method comprises steps of: setting up a signal transition to a test target signal line selected from a plurality of signal lines included in the test target circuit and then setting up the test target signal line to be a control signal line; acquiring a length of the longest path from a control candidate signal line to a control point where a signal is inputted, for each of one or more control candidate signal lines that propagate a signal to the control signal line, and then selecting a control candidate signal line from the control candidate signal lines on the basis of the maximum value of the acquired lengths of the longest paths; performing activation and justification in order to propagate the signal transition from the selected control candidate signal line to the control signal line, and thereby acquiring a signal value to be set up to the signal line included in the test target circuit; and determining the first and the second test patterns on the basis of the acquired signal value when the activation and the justification have been successful.

In this method, when the activation and the justification have been successful, the selected control candidate signal line may be re-set to be a control signal line. Further, when the activation and the justification have been unsuccessful, a signal line may be selected from the not-selected control candidate signal lines. Furthermore, the step of selecting a signal line, the step of acquiring a signal value, and the step of determining the first and the second test patterns may be repeated until a controllable control point is reached (a sixteenth aspect).

Alternatively, the test pattern generation method may further comprise a step of backtracking to a signal line where signal line selection has been performed in the past, when the activation and the justification have been unsuccessful for all of the control candidate signal lines that propagate a signal to a particular control signal line (a seventeenth aspect).

Alternatively, in the step of acquiring a signal value, when a plurality of control candidate signal lines are present, a signal transition may be set up only for a control candidate signal line having a longest path from the control candidate signal line to the control point while a fixed signal value may be set up to the other control candidate signal lines. (an eighteenth aspect).

Alternatively, in the step of selecting a signal line, a path having a maximum value in the number of gates included in a path extending from the control signal line to the control point may be selected as the longest path (a nineteenth aspect).

Alternatively, in the step of selecting a signal line, a path having a maximum value in the number of via holes included in a path extending from the control signal line to the control point may be selected as the longest path (a twentieth aspect).

Alternatively, in the step of selecting a signal line, a longest path may be selected on the basis of delay information of each path extending from the control signal line to the control point (a twenty-first aspect).

The twenty-second aspect of the present invention is directed to a test pattern generation method for generating a first test pattern and a second test pattern which is provided at a next test cycle, for the purpose of detection of a delay fault that occurs in a test target circuit. The test pattern generation method comprises: a step of selecting a test target signal line from a plurality of signal lines included in the test target circuit and then setting up a signal transition to the test target signal line; a first determination step of determining the first and the second test patterns that propagate the signal transition set up to the test target signal line, from the test target signal line to an observation point where a signal is outputted; and a second determination step of determining the first and the second test patterns that propagate the set-up signal transition from an observation point where a signal is outputted to the test target signal line. The first determination step includes steps of: setting up the test target signal line to be a reaching signal line; acquiring a length of the longest path from the control candidate signal line to any one of control points, for each of one or more reaching candidate signal lines that branch from the reaching signal line, and then selecting a reaching candidate signal line from the reaching candidate signal lines on the basis of the maximum value of the acquired lengths of the longest paths; performing activation and justification in order to propagate a signal to the selected reaching candidate signal line, and thereby acquiring a signal value to be set up to the signal line included in the test target circuit; and updating the first and the second test patterns on the basis of the acquired signal value, when the activation and the justification have been successful. The second determination step includes steps of: setting up the test target signal line to be a control signal line; acquiring a length of the longest path from the control candidate signal line to any one of control points, for each of one or more control candidate signal lines that propagate a signal to the control signal line, and then selecting a control candidate signal line from the control candidate signal lines on the basis of the maximum value of the acquired lengths of the longest paths; performing activation and justification in order to propagate the signal transition from the selected control candidate signal line to the control signal line, and thereby acquiring a signal value to be set up to the signal line included in the test target circuit; and determining the first and the second test patterns on the basis of the acquired signal value when the activation and the justification have been successful.

In this method, the first determination step may be performed before the second determination step (a twenty-third aspect).

Alternatively, the first determination step may be performed after the second determination step (a twenty-fourth aspect).

Alternatively, the test pattern generation method may further comprise a step of calculating as a first maximum path length a maximum value of the lengths of the paths from the test target signal line to the observation point and calculating as a second maximum path length a maximum value of the lengths of the paths from the test target signal line to the control point. Further, when the first maximum path length is longer than the second maximum path length, the first determination step may be performed before the second determination step, while when the first maximum path length is shorter than or equal to the second maximum path length, the first determination step may be performed after the second determination step (a twenty-fifth aspect).

According to the first aspect described above, a fault is propagated using a longer path so that the quality of the test pattern is improved.

According to the second aspect described above, activation, implication operation, and justification are performed collectively for a plurality of signal lines so that the processing time is shortened.

According to the third aspect described above, branches included in a short path are excluded in advance from the candidates of signal line selection, so that the processing time is shortened.

According to the fourth aspect described above, activation is performed according to a robust condition so that a delay fault on a path including a test target signal line can be tested regardless of whether a delay fault occurs on another signal line.

According to the fifth aspect described above, activation is performed according to a non-robust condition so that the influence of delay on a path including a test target signal line can be detected using a longer path.

According to the sixth aspect described above, when activation according to a robust condition has been unsuccessful, activation is performed according to a non-robust condition. Thus, a test pattern can be generated that permits test of a fault which is untestable under the robust condition.

According to the seventh aspect described above, activation according to a robust condition is executed with priority. Thus, even when the detection path for a delay fault is the same, a high-quality test pattern can be generated.

Accordingly the eighth aspect described above, when the activation and the justification have been unsuccessful, backtracking is performed. Thus, a test pattern can be generated that cannot be generated without backtracking.

According to the ninth aspect described above, backtracking is performed to a branch point where selection has been performed immediately before. Thus, a test pattern can be generated that cannot be generated without backtracking.

According to the tenth aspect described above, return destinations in the backtracking are restricted so that the processing time is shortened.

According to the eleventh aspect described above, return destinations in the backtracking are restricted so that a longer path is selected with priority. Thus, the influence of delay in the test target signal line can be detected using propagation along a longer path.

According to the twelfth aspect described above, the value assigned to a signal line when a fault value is to be propagated need not be held, so that the processing time is shortened while the memory utilization is reduced.

According to the thirteenth aspect described above, processing is performed in a state that control points and signal lines which do not satisfy a predetermined criterion are excluded, so that the processing time is shortened while the memory utilization is reduced.

According to the fourteenth aspect described above, processing is performed in a state that specified signal lines are excluded, so that the processing time is shortened while the memory utilization is reduced.

According to the fifteenth aspect described above, a test pattern can be generated in such a manner that the path extending from a control point to a test target signal line becomes longer, so that the quality of the test pattern is improved.

According to the sixteenth aspect described above, a test pattern can be determined by repeating the above-mentioned steps and thereby selecting a path starting from a test target signal line toward a control point. This permits more efficient generation of a test pattern.

According to the seventeenth aspect described above, when the activation and the justification have been unsuccessful, backtracking is performed. This permits more reliable generation of a test pattern that can propagate a signal transition from a control point to a test target signal line.

According to the eighteenth aspect described above, a fixed value is set up to the paths other than the longest path that can propagate a signal from a control point to a test target signal line. This reduces the influence of signal delay in the non-test target paths, and hence improves the reliability of the test pattern.

According to the twenty-second aspect described above, the path is selected in such a manner that the path length from a test target signal line to an observation point and the path length from a test target signal line to a control point to should become longer. Thus, a test pattern can be generated in which the length of the path extending from a control point to an observation point becomes longer.

According to the twenty-third aspect described above, a path that can propagate a signal from a test target signal line to an observation point is selected first. This permits efficient generation of a test pattern for a path that can reliably be observed in the test target signal line.

According to the twenty-fourth aspect described above, a path that can propagate a signal from a control point to a test target signal line is selected first. This permits efficient generation of a test pattern for a path that can reliably be observed in the test target signal line.

According to the twenty-fifth aspect described above, the length of the longest path from a test target signal line to an observation point is compared with the length of the longest path from the test target signal line to a control point, so that a test pattern that propagates a signal through the longer path is determined first. This permits efficient generation of a test pattern.

These and other objects, features, aspects, and effects of the present invention will become clear from the following description with reference to the accompanied drawings.

### BRIEF DESCRIPTION OF THE DRAWINGS

FIG. 1 is a diagram showing a configuration of a test pattern generation system for executing a test pattern generation method according to each embodiment of the present invention;

FIG. 2 is a diagram showing an example of a delay value table;

FIGS. 3A and 3B are diagrams each showing an example of a via hole table;

FIG. 4 is a flow chart showing a test pattern generation method according to a first embodiment of the present invention;

FIG. 5 is a diagram showing an example of a test target circuit;

FIG. 6 is a flow chart showing a transition fault test pattern generation method according to the prior art;

FIG. 7 is a flow chart showing a test pattern generation method according to a second embodiment of the present invention;

FIG. 8 is a diagram showing an example of a test target circuit;

FIG. 9 is a diagram showing an edge graph based on a test target circuit shown in FIG. 8;

FIG. 10 is a diagram showing another example of an edge graph;

FIG. 11 is a flow chart showing a test pattern generation method according to a third embodiment of the present invention;

FIG. 12 is a flow chart showing a test pattern generation method according to a fourth embodiment of the present invention;

FIG. 13 is a diagram showing an example of a test target circuit;

FIG. 14 is a flow chart showing a test pattern generation method according to a fifth embodiment of the present invention;

FIG. 15 is a flow chart showing a test pattern generation method according to a sixth embodiment of the present invention;

FIG. 16 is a diagram showing an example of a test target circuit;

FIG. 17 is a flow chart showing a test pattern generation method according to a seventh embodiment of the present invention;

FIG. 18 is a flow chart showing a test pattern generation method according to an eighth embodiment of the present invention;

FIG. 19 is a flow chart showing a test pattern generation method according to a ninth embodiment of the present invention;

FIG. 20 is a flow chart showing a test pattern generation method according to a tenth embodiment of the present invention;

FIG. 21 is a flow chart showing a test pattern generation method according to an eleventh embodiment of the present invention;

FIG. 22 is a diagram showing an example of a test target circuit;

FIG. 23 is a flow chart showing a test pattern generation method according to a twelfth embodiment of the present invention;

FIG. 24 is a diagram showing an edge graph generated by simplifying an edge graph shown in FIG. 9;

FIG. 25 is a flow chart showing a test pattern generation method according to a thirteenth embodiment of the present invention;

FIG. 26 is a diagram showing values used in a test pattern generation method according to fourteenth through nineteenth embodiments of the present invention;

FIGS. 27A-27D are diagrams showing an example of path activation tables used in a test pattern generation method according to fourteenth through nineteenth embodiments of the present invention;

FIGS. 28A and 28B are diagrams showing another example of path activation tables used in a test pattern generation method according to fourteenth through nineteenth embodiments of the present invention;

FIG. 29 is a flow chart showing a test pattern generation method according to a fourteenth embodiment of the present invention;

FIG. 30 is a flow chart showing details of test sequence generation processing shown in FIG. 29;

FIG. 31 is a diagram showing an example of a test target circuit;

FIG. 32 is a flow chart showing a test pattern generation method according to a fifteenth embodiment of the present invention;

FIG. 33 is a diagram showing an example of a test target circuit;

FIG. 34 is a flow chart showing a test pattern generation method according to a sixteenth embodiment of the present invention;

FIG. 35 is a flow chart showing a test pattern generation method according to a seventeenth embodiment of the present invention;

FIG. 36 is a flow chart showing details of first determination processing shown in FIG. 35;

FIG. 37 is a diagram showing an example of a test target circuit;

FIG. 38 is a flow chart showing a test pattern generation method according to an eighteenth embodiment of the present invention;

FIG. 39 is a flow chart showing a test pattern generation method according to a nineteenth embodiment of the present invention;

FIG. 40 is a diagram showing five values used in a path delay fault test pattern generation method;

FIG. 41A-41C are diagrams showing implication tables used in a path delay fault test pattern generation method;

FIGS. 42A-42D are diagrams showing path activation tables used in a path delay fault test pattern generation method;

FIG. 43 is a diagram showing propagation of a signal transition in a path delay fault test pattern generation method;

FIG. 44 is a diagram showing an example of execution of a path delay fault test pattern generation method;

FIGS. 45A and 45B are diagrams showing serial patterns obtained by converting a test sequence;

FIG. 46 is a diagram showing a path activation table and an implication table used in a transition fault test pattern generation method; and

FIGS. 47A and 47B are diagrams showing an example of execution of a transition fault test pattern generation method.

### DESCRIPTION OF THE PREFERRED EMBODIMENTS

First through thirteenth embodiments of the present invention are described below each concerning a test pattern generation method for generating a test pattern for testing a delay fault. In the following description, test pattern generation methods according to the first through the thirteenth embodiments are referred to as first through thirteenth generation methods, respectively.

First, representation and terminology used in the following description are described below. A value “X” set up to a signal line indicates that either a value 0 or a value 1 may be set up to the signal line. When a signal line branches into a plurality at a branch point, among these signal lines, the part before the branching is referred to as a “stem”. Each part after the branching is referred to as a “branch”. The output of a scan FF is referred to as a “pseudo external input”. The input of a scan FF is referred to as a “pseudo external output”. Each of the external input and the pseudo external input is referred to as a “control point”. Each of the external output and the pseudo external output is referred to as an “observation point”. In a test target circuit, a terminal PI* (“*” indicates an arbitrary character strings) denotes a control point, while a terminal PO* indicates an observation point. Among the steps in each embodiment, steps having already been described in a previous embodiment are denoted by the same step numbers, and hence their description is omitted.

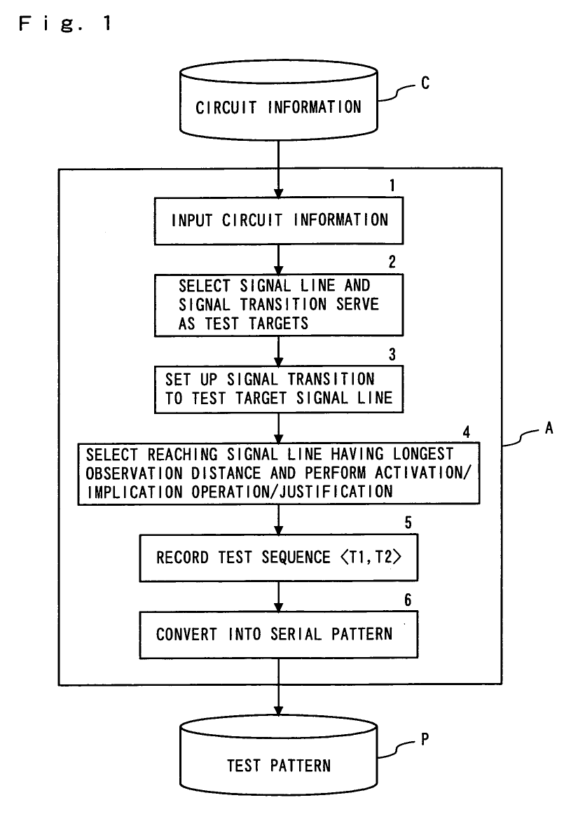

FIG. 1 is a diagram showing a configuration of a test pattern generation system for executing first through thirteenth generation methods. The test pattern generation system A shown in FIG. 1 (the apparatus, hereinafter) generates a test pattern P on the basis of inputted circuit information C. The outline of operation of the apparatus is as follows. At Step 1, information concerning storage elements and logic elements that constitute the test target circuit as well as concerning wiring between these elements is inputted as circuit information to the apparatus. At Step 2, the apparatus selects a signal line and a signal transition serving as test targets. At Step 3, the apparatus sets up the signal transition selected at Step 2, to the signal line selected at Step 2. At Step 4, the apparatus sequentially selects paths for propagating the signal transition set up at Step 3 toward the observation point, and then performs activation, implication operation, and justification. At that time, when the signal line for propagating the signal transition branches, the apparatus selects a branch having the longest propagation path length (the observation distance, hereinafter) to the observation point, and then propagates the signal transition to the selected branch. As a result of execution of Step 4, a test sequence <T1,T2> is obtained. At Step 5, the apparatus records the obtained test sequence <T1,T2> temporarily into the inside or into a file. At Step 6, the apparatus converts the test sequence <T1,T2> recorded at Step 5, into a test pattern P in a serial form that can be used by an automatic test apparatus. Flow charts described in the first through the thirteenth embodiments are detailed ones of the flow chart show in FIG. 1.

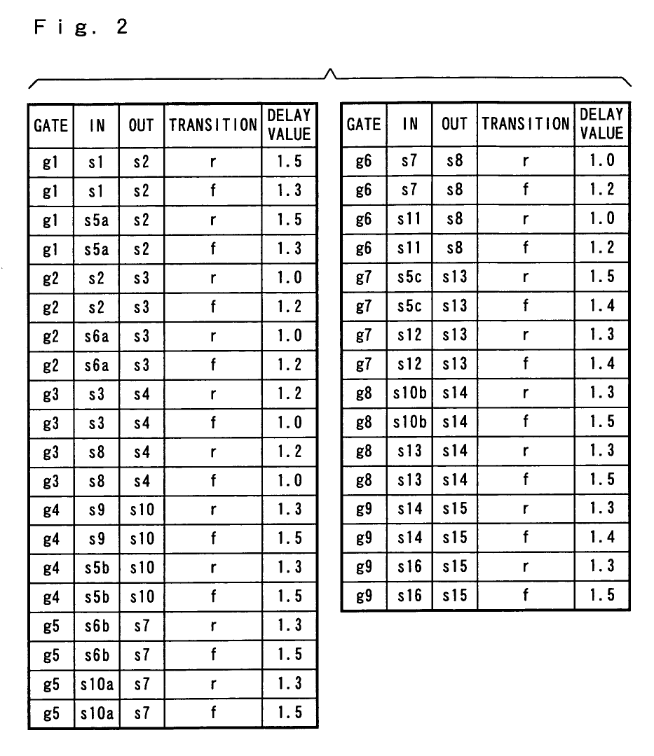

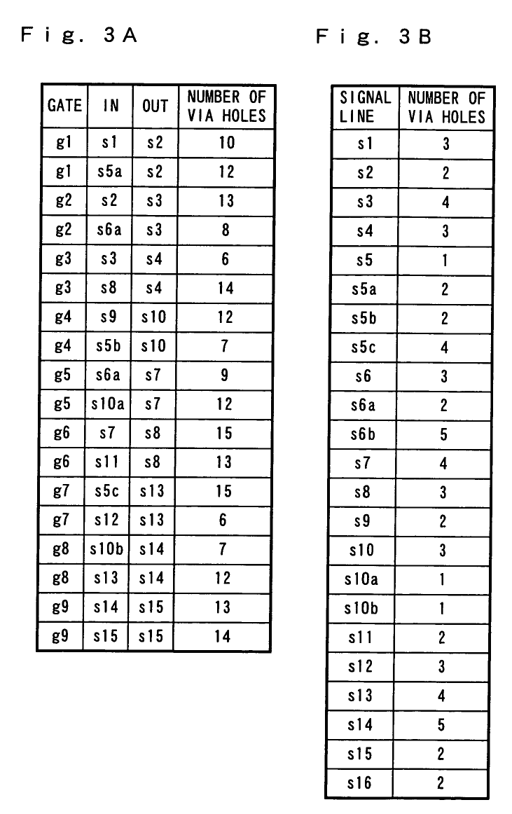

At Step 4, the observation distance is calculated on the basis of the circuit information C inputted at Step 1, in accordance with a predetermined calculation method. For example, the observation distance is calculated using a delay value table (FIG. 2) and via hole tables (FIGS. 3A and 3B) which are included in the circuit information C. In the delay value table shown in FIG. 2, the gate indicates the name of each gate included in the test target circuit, while the IN and the OUT indicate respectively the names of the input signal line and the output signal line of the gate. The transition indicates the transition of the input signal line. The transition r indicates a rise transition, while the transition f indicates a fall transition. The delay value indicates the propagation time of the signal transition from the IN to the OUT of each gate. In the via hole table shown in FIG. 3A, the gate indicates the name of each gate included in the test target circuit, while the IN and the OUT indicate respectively the names of the input signal line and the output signal line of the gate. The number of via holes indicates the total of the number of via holes and the number of via contacts from the IN to the OUT of each gate. In the via hole table shown in FIG. 3B, the signal line indicates the name of the signal line, while the number of via holes indicates the total of the number of via holes and the number of via contacts provided on the signal line.

Here, the delay value table may store delay values that vary depending on the voltage or the temperature. Further, in addition to the delay table corresponding to the gate, a delay value table corresponding the wiring may be used. Further, the delay value table may store delay values for control points and observation points. Further, in place of the via hole table corresponding to the wiring and the gate, a via hole table corresponding solely to the wiring or a via hole table corresponding solely to the gate may be used. Furthermore, the via hole table may store the number of via holes for each control point and each observation point. The delay value table and the via hole table may be prepared manually or alternatively acquired using a computer. Their form may also be arbitrary.

### First Embodiment

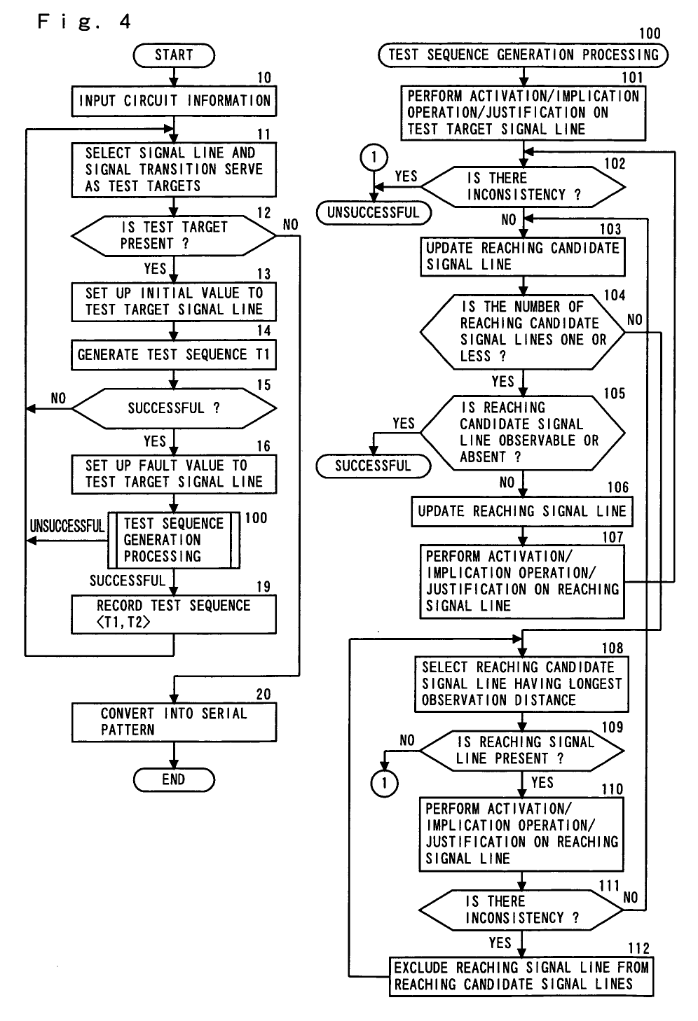

FIG. 4 is a flow chart showing a first generation method. In the first generation method, the following processing is executed.

(Step 10) Information concerning storage elements and logic elements (gates) that constitute the test target circuit as well as concerning wiring between these elements is inputted as circuit information to the apparatus. In addition, information for specifying a signal line serving as a test target is inputted to the apparatus. Here, the information for specifying a signal line serving as a test target may be inputted manually or alternatively using a computer.

(Step 11) The apparatus selects a signal line serving as a test target and a signal transition serving as a test target. At Step 11, signal lines where a test pattern has already been generated and signal lines where a test pattern has already been determined as not capable of being generated are excluded from the targets of selection. Here, the signal line and the signal transition serving as test targets may be selected manually, or alternatively may be selected automatically by a computer on the basis of circuit information.

(Step 12) When a signal line and a signal transition serving as test targets have been selected at Step 11, the apparatus goes to Step 13. Otherwise, the apparatus goes to Step 20.

(Step 13) The apparatus sets up an initial value (0 for a rise transition and 1 for a fall transition) for the signal transition selected at Step 11, to the test target signal line selected at Step 11.

(Step 14) The apparatus acquires a combination of input values for causing the value of the test target signal line selected at Step 11 to agree with the initial value set up at Step 13. As a result, a test sequence T1 is generated.

(Step 15) When the generation of the test sequence T1 has been successful at Step 14, the apparatus goes to Step 16. Otherwise, the apparatus goes to Step 11.

(Step 16) The apparatus sets up a fault value (ND for a rise transition and D for a fall transition) corresponding to the signal transition selected at Step 11, to the test target signal line selected at Step 11.

(Step 100) The apparatus performs test sequence generation processing described later, and thereby generates a test sequence T2. In the test sequence generation processing, the test sequence T1 generated at Step 14 could be updated in some cases. When the generation of the test sequence T2 (and the update of the test sequence T1) has been successful, the apparatus goes to Step 19. Otherwise, the apparatus goes to Step 11.

(Step 19) The apparatus records the test sequence<T1,T2> generated at Steps 14 and 100, temporarily into the inside or into a file. Further, when a signal line where test pattern generation has already been determined as being impossible is present, the apparatus may check whether the signal line can be tested using the generated test sequence <T1,T2>. Then, the apparatus goes to Step 11. As such, Steps 11-19 are executed for all combinations of the signal lines and the signal transitions serving as test targets.

(Step 20) The apparatus converts into a serial pattern the test sequence <T1,T2> recorded at Step 19, and then terminates the processing.

At Step 100, the following processing is executed. In the following description, a signal line to which the fault value has been propagated most recently is referred to as a “reaching signal line”. Further, each signal line which is connected to the output side of the reaching signal line and which the fault value could reach next is referred to as a “reaching candidate signal line”.

(Step 101) In order to set up a fault value to the test target signal line and then propagate the set-up fault value toward the output side of the test target signal line by one gate stage, the apparatus performs activation, implication operation, and justification. Here, when a value to be provided to the control point has been determined in the justification, the test sequence T2 is updated. Further, depending on the situation, the test sequence T1 is also updated. This holds for all the justification processes described below.

(Step 102) When inconsistency arises at Step 101, the apparatus goes to Step 11. Otherwise, the apparatus goes to Step 103.

(Step 103) On the basis of the reaching signal line, the apparatus updates the reaching candidate signal line. Specifically, when the input signal line of the gate is a reaching signal line while the output signal line of the gate does not branch, the output signal line of the gate become a reaching candidate signal line. Further, when the input signal line of the gate is a reaching signal line while the output signal line of the gate branches, the stem of the output signal lines of the gate becomes a reaching candidate signal line. Further, when the stem is a reaching signal line, the entire branches connected to the output side of the stem become reaching candidate signal lines.

(Step 104) When the number of reaching candidate signal lines is one or less (that is, zero or one), the apparatus goes to Step 105. Otherwise, the apparatus goes to Step 108.

(Step 105) When the reaching candidate signal line can be observed or alternatively when the number of reaching candidate signal lines is zero (that is, when a reaching candidate signal line is connected to the observation point or alternatively when no reaching candidate signal line is present), the apparatus goes to Step 19. Otherwise, the apparatus goes to Step 106.

(Step 106) The apparatus reaches this step only when the number of reaching candidate signal lines is one. The apparatus sets up the only reaching candidate signal line to be a new reaching signal line.

(Step 107) In order to propagate the fault value toward the output side of the reaching signal line by one gate stage, the apparatus performs activation, implication operation, and justification. Here, when the reaching signal line is a stem, the value of the branch has already been determined by the implication operation. Thus, the apparatus does not perform activation, implication operation, and justification. After that, the apparatus goes to Step 102.

(Step 108) The apparatus reaches this step from Step 104 only when two or more reaching candidate signal lines (branches) are present. For each branch, the apparatus acquires the length (the observation distance) of a path to each observation point, and then acquires the maximum value (the longest observation distance, hereinafter) of the observation distances. As described above, the observation distance is calculated using the delay value table (FIG. 2), the via hole table (FIG. 3), and the like. The apparatus selects as a new reaching signal line a signal line having the maximum longest observation distance among the reaching candidate signal lines.

(Step 109) When a reaching signal line has been selected at Step 108, the apparatus goes to Step 110. Otherwise, the apparatus goes to Step 11.

(Step 110) The apparatus performs the same processing as Step 107.

(Step 111) When inconsistency arises at Step 110, the apparatus goes to Step 112. Otherwise, the apparatus goes to Step 103.

(Step 112) The apparatus excludes from the reaching candidate signal lines the reaching signal line selected at Step 108, and then goes to Step 108.

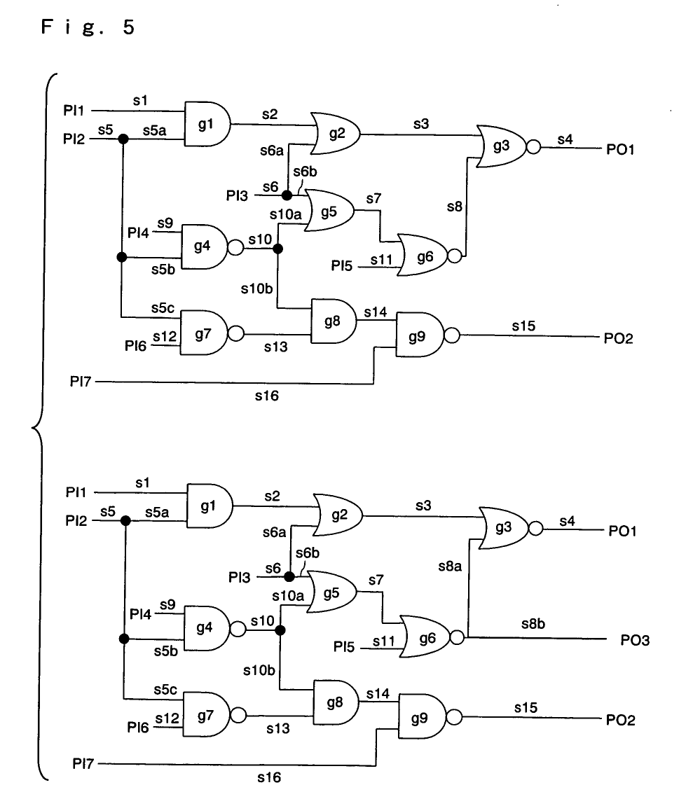

The processing is described below for the case that the first generation method is applied to a test target circuit shown in FIG. 5. Here, a rise transition in a signal line s9 is adopted as a test target. {PI1, PI2, PI3, PI4, PI5, PI6, PI7} is denoted by {P}.

(Step 13) The apparatus sets up an initial value of 0 to the test target signal line s9.

(Step 14) In order to set up an initial value of 0 to the test target signal line s9, the apparatus sets up a value 0 to the control point PI4. The test sequence T1 is updated into {P}={X, X, X, 0, X, X, X}.

(Step 15) Since the generation of the test sequence T1 has been successful, the apparatus goes to Step 16.

(Step 16) The apparatus sets up a fault value ND to the test target signal line s9.

(Step 101) In order to set up a fault value ND to the test target signal line s9, and then propagate the set-up fault value to the signal line s10, the apparatus performs activation, implication operation, and justification. As a result, a value 1 is set up to the signal lines s5, s5a, s5b, and s5c and the control points PI2 and PI4, so that a fault value D is propagated to the signal line s10. The test sequence T2 is updated into {P}={X, 1, X, 1, X, X, X}.

(Step 102) Since no inconsistency arises at Step 101, the apparatus goes to Step 103.

(Step 103) The apparatus sets up the signal line s10 to be a reaching candidate signal line.

(Step 104) Since the number of reaching candidate signal lines is one, the apparatus goes to Step 105.

(Step 105) Since the signal line s10 cannot be observed, the apparatus goes to Step 106.

(Step 106) The apparatus sets up the signal line s10 to be a reaching signal line.

(Step 107) Since the reaching signal line s10 is a stem, the apparatus goes to Step 102 without performing activation, implication operation, and justification.

(Step 102) Since no inconsistency arises at Step 107, the apparatus goes to Step 103.

(Step 103) Since the signal line s10 is a stem, the apparatus sets up the signal lines s10a and s10b to be reaching candidate signal lines.

(Step 104) Since two reaching candidate signal lines are present, the apparatus goes to Step 2508.

(Step 108) The apparatus acquires the longest observation distances of the reaching candidate signal lines s10a and s10b. When the observation distance is estimated in terms of the number of gate stages, the longest observation distance of the signal line s10a is 3, while the longest observation distance of the signal line s10b is 2. Thus, the apparatus selects as a reaching signal line the reaching candidate signal line s10a having the maximum longest observation distance.

(Step 109) Since a reaching signal line has been selected at Step 108, the apparatus goes to Step 110.

(Step 110) In order to propagate the fault value D of the reaching signal line s10a to the signal line s7, the apparatus performs activation, implication operation, and justification. As a result, a value 0 is set up to the signal lines s6, s6a, and s6b and the control point PI3, so that a fault value D is propagated to the signal line s7. The test sequence T2 is updated into {P}={X, 1, 0, 1, X, X, X}.

(Step 111) Since no inconsistency arises at Step 110, the apparatus goes to Step 103.

(Steps 103-106) The apparatus sets up the signal line s7 (unobservable) to be a reaching candidate signal line, and then sets up the signal line s7 to be a reaching signal line.

(Step 107) In order to propagate the fault value D of the reaching signal line s7 to the signal line s8, the apparatus performs activation, implication operation, and justification. As a result, a value 0 is set up to the signal line s11 and the control point PI5, so that a fault value ND is propagated to the signal line s8. The test sequence T2 is updated into {P}={X, 1, 0, 1, 0, X, X}.

(Step 102) Since no inconsistency arises at Step 107, the apparatus goes to Step 103.

(Steps 103-106) The apparatus sets up the signal line s8 (unobservable) to be a reaching candidate signal line, and then sets up the signal line s8 to be a reaching signal line.

(Step 107) In order to propagate the fault value ND of the reaching signal line s8 to the signal line s4, the apparatus performs activation, implication operation, and justification. As a result, a value 0 is set up to the signal lines s3, s2, and s1 and the control point PI1, so that a fault value D is propagated to the signal line s4. The test sequence T2 is updated into {P}={0, 1, 0, 1, 0, X, X}.

(Step 102) Since no inconsistency arises at Step 107, the apparatus goes to Step 103.

(Step 103) The apparatus sets up the signal line s4 to be a reaching candidate signal line.

(Step 104) Since the number of reaching candidate signal lines is one, the apparatus goes to Step 105.

(Step 105) The reaching candidate signal line s4 is connected to the observation point PO1 and can be observed. Thus, the apparatus goes to Step 19.

As a result of the above-mentioned processing, {P}={X, X, X, 0, X, X, X} is generated as the test sequence T1, while {P}={0, 1, 0, 1, 0, X, X} is generated as the test sequence T2.

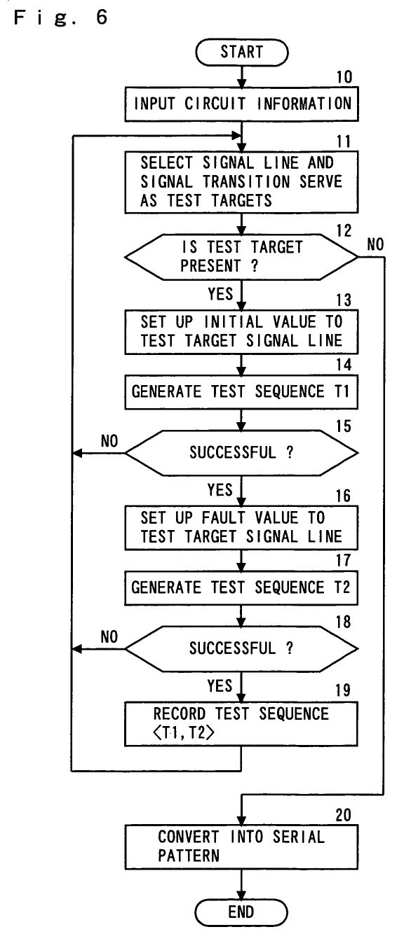

FIG. 6 is a flow chart showing a transition fault test pattern generation method according to the prior art. The above-mentioned first generation method is a modification of the method of FIG. 6, where Steps 17 and 18 are replaced by Step 100. In the method of FIG. 6, instead of Step 100 the following processing are performed.

(Step 17) In order to propagate to the observation point the fault value D or ND set up at Step 16, the apparatus performs activation, implication operation, and justification, and thereby generates a test sequence T2.

(Step 18) When the generation of the test sequence T2 has been successful at Step 17, the apparatus goes to Step 19. Otherwise, the apparatus goes to Step 11.

The processing is described below for the case that the method of FIG. 6 is applied to the test target circuit shown in FIG. 5. Here, a fall transition in the signal line s6 is adopted as a test target. {PI1, PI2, PI3, PI4, PI5, PI6, PI7} is denoted by {P}.

(Step 13) The apparatus sets up an initial value of 1 to the test target signal line s6.

(Step 14) In order to set up an initial value of 1 to the test target signal line s6, the apparatus sets up a value 1 to the control point PI3. The test sequence T1 is updated into {P}={X, X, 1, X, X, X, X}.

(Step 16) The apparatus sets up a fault value D to the test target signal line s6

(Step 17) In order to propagate the fault value D of the test target signal line s6 to the observation point, the apparatus performs activation, implication operation, and justification. First, in order that the fault value D of the signal line s6 should be propagated to the signal line s3, a value 0 is set up to the signal line s2. Then, in order that the fault value D of the signal line s3 should be propagated to the signal line s4, a value 0 is set up to the signal line s8. After the fault value has been propagated to the observation point PO1, justification is performed for each signal line. In order that the signal line s6 should be justified into 0, a value 0 is set up to the control point PI3. In order that the signal line s2 should be justified into 0, a value 0 is set up to the signal line s1 and the control point PI1. In order that the signal line s8 should be justified into 0, a value 1 is set up to the signal line s1 and the control point PI5. The test sequence T2 is updated into {P}={0, X, 0, X, 1, X, X}.

As a result of the above-mentioned processing, {p}={X, X, 1, X, X, X, X} is generated as the test sequence T1, while {P}={0, X, 0, X, 1, X, X} is generated as the test sequence T2.

In the test target circuit shown in FIG. 5, a path going via the signal line s6a and a path going via the signal line s6b are included as candidates for the path for propagating the fault value set up to the signal line s6. When a plurality of paths are present that can propagate the fault value, in the prior art method shown in FIG. 6, a signal line to which the fault value is to be propagated next is selected on the basis of the easiness of observation (an observable cost), the easiness of control (a controllable cost), and the like at the time of propagation of the fault value to each signal line. In the above-mentioned example, the signal line s6a having a high observable cost (easy to observe) has been selected. However, depending on a particular condition, the signal line s6b can be selected. In either case, justification is performed after the fault value has been propagated to the observation point.

In contrast, in the first generation method, when a plurality of paths are present that can propagate the fault value, a branch having the maximum longest observation distance is selected as a signal line to which the fault value is to be propagated next. As such, a fault is propagated using a longer path so that the quality of the test pattern is improved.

Here, the above-mentioned description has been given for the case that the longest observation distance is acquired for each branch at Step 108. Instead, in order to avoid that the longest observation distance is calculated repeatedly for the same branch, the apparatus may acquire in advance the longest observation distance for each branch included in the test target circuit, for example, between Step 10 and Step 11.

Further, in the processing of propagating the fault value, depending on the circuit configuration, such a case can arise that the fault value has already been propagated to a reaching candidate signal line connected to the output side of the reaching signal line. In this case, the apparatus need not perform activation for the reaching candidate signal line.

### Second Embodiment

FIG. 7 is a flow chart showing a second generation method. The second generation method is a modification of the first generation method, where Step 201 is added, while Step 107 is omitted, and while Steps 11, 16, 101, 106, and 110 are replaced by Steps 202-206, respectively. The second generation method is characterized in that the test target circuit is represented by an edge graph so that a test pattern is generated at a high speed. Each vertex in the edge graph corresponds to one or more signal lines in the test target circuit. In the following description, signal lines corresponding to each vertex in the edge graph is referred to as signal lines in a group.

The following steps appear for the first time in the second generation method.

(Step 201) The apparatus performs later-described circuit conversion on a test target circuit and thereby acquires an edge graph.

(Step 202) The apparatus selects a signal line serving as a test target from a vertex of the edge graph obtained at Step 201, and then selects a signal transition serving as a test target.

(Step 203) The apparatus sets up a fault value corresponding to the signal transition selected at Step 202, to the test target signal line selected at Step 202. At that time, for each signal line in the group, the apparatus sets up a fault value that is to be acquired when the set-up fault value is propagated correctly to the first signal line in the group.

(Step 204) In order to set up a fault value to the signal lines in the group, and then propagate the set-up fault value, the apparatus performs activation, implication operation, and justification.

(Step 205) The apparatus selects the group of reaching candidate signal lines as new reaching signal lines. After that, the apparatus goes to Step 204.

(Step 206) The apparatus performs the same processing as Step 204.

At Step 201, an edge graph is obtained on the basis of the circuit information inputted at Step 10 according to the following processing (not shown in the figure).

(Step 201a) The apparatus replaces a partial circuit (including a gate and a signal line) in a region extending from a storage element or an external input to a stem, into a vertex provided with the name of the storage element or the external input.

(Step 201b) The apparatus replaces a partial circuit located in a region from a branch to a stem or an observation point, into a vertex provided with the name of the branch.

(Step 201c) In the test target circuit, when an element in a particular group and an element in another group are connected to each other, the apparatus generates a directional branch directing from the input side to the output side, between the vertexes corresponding to these two groups.

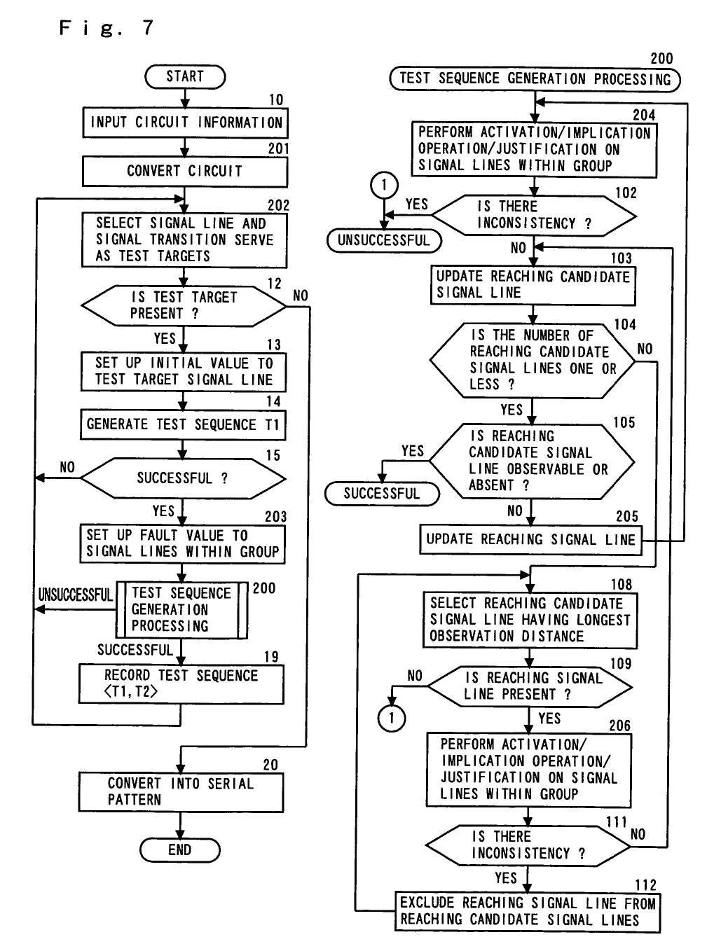

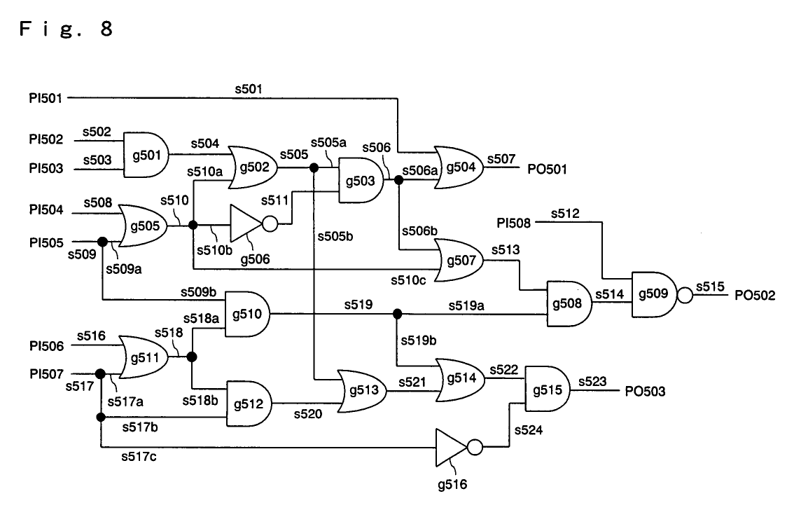

When the circuit conversion of Step 201 is executed for the test target circuit shown in FIG. 8, an edge graph shown in FIG. 9 is obtained. In the edge graph shown in FIG. 9, vertexes PI501-PI508 correspond to control points, while vertexes PO501 and PO502 correspond to observation points. The other vertexes correspond to branches. Each vertex shown in FIG. 9 is provided with the name of the branch included in the partial circuit corresponding to each vertex in the test target circuit shown in FIG. 8. For example, the branch going from the vertex PI504 to the vertex s510a indicates that a path is present that goes to the branch s510a via the external input PI504 or one or more signal lines in the test target circuit shown in FIG. 8.

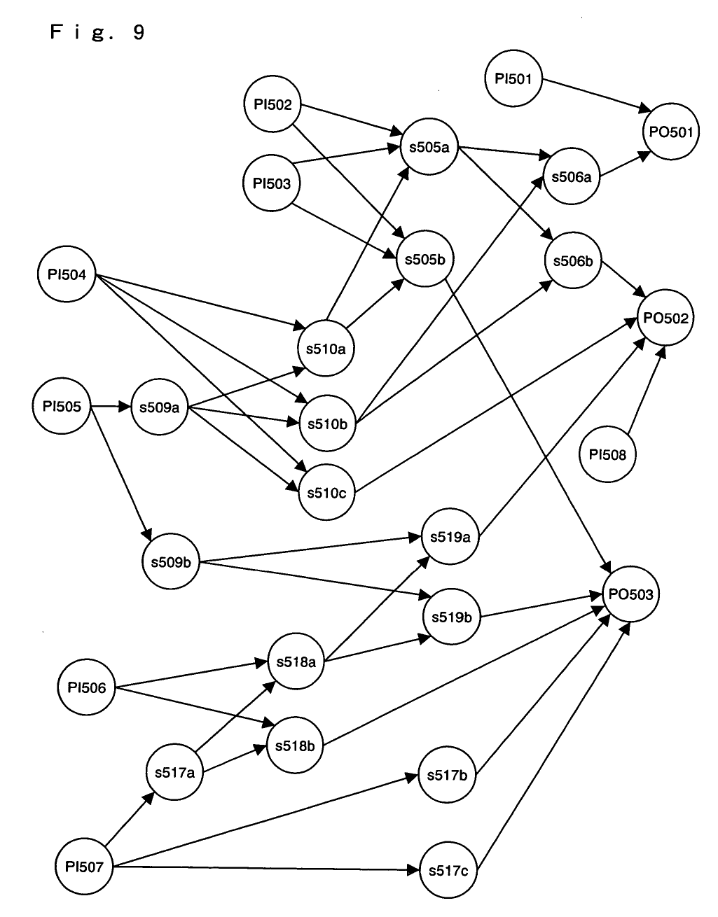

Here, the names provided to the vertexes at Steps 201a and 201b may be arbitrary as long as they differ from each other. Further, as in the vertex s517a shown in FIG. 10, when a vertex to which an input branch and an output branch are connected is included in the edge graph, the apparatus may merge this vertex into a vertex (the vertex PI507 in FIG. 10) connected to the input branch.

The processing is described below for the case that the second generation method is applied to a test target circuit shown in FIG. 8. Here, a rise transition in the signal line s502 is adopted as a test target. {PI501, PI502, PI503, PI504, PI505, PI506, PI507, PI508} is denoted by {P}.

(Step 201) The apparatus performs circuit conversion on the test target circuit shown in FIG. 8, and thereby acquires an edge graph.

(Step 202) The apparatus selects a rise transition in the signal line s502 as a signal line and a signal transition serving as test targets. In association with this, the signal lines s502, s504, and s505 are incorporated into signal lines in the group.

(Step 13) The apparatus sets up an initial value of 0 to the test target signal line s502.

(Step 14) In order to set up an initial value of 0 to the test target signal line s502, the apparatus sets up a value 0 to the control point PI2. The test sequence T1 is updated into {P}={X, 0, X, X, X, X, X, X}.

(Step 15) Since the generation of the test sequence T1 has been successful, the apparatus goes to Step 203.

(Step 203) For the signal lines s502, s504, and s505 in the group, the apparatus sets up a fault value that is to be acquired when the set-up fault value ND is propagated correctly to the signal line s502 (corresponding to the first signal line in the group). As a result, a fault value ND is set up to the signal lines s502, s504, and s505.

(Step 204) In order to set up or propagate a fault value ND to the signal lines s502, s504, and s505 in the group, the apparatus performs activation, implication operation, and justification. As a result, a value 1 is set up to the signal lines s502 and s503, while a value 0 is set up to the signal line s510a. In association with this, a value 1 is set up to the control points PI502 and PI503, while a value 0 is set up to the control points PI504 and PI505. The test sequence T2 is updated into {P}={X, 1, 1, 0, 0, X, X, X}.

(Step 102) Since no inconsistency arises at Step 204, the apparatus goes to Step 103.

(Steps 103-104) Since the signal line s505 is a stem, the apparatus sets up the signal lines s505a and s505b to be reaching candidate signal lines, and then goes to Step 108.

(Step 108) The apparatus acquires the longest observation distances of the reaching candidate signal lines s505a and s505b. When the observation distance is estimated in terms of the number of gate stages, the longest observation distance of the signal line s505a is 4, while the longest observation distance of the signal line s505b is 3. Thus, the apparatus selects as a reaching signal line the reaching candidate signal line s505a having the maximum longest observation distance. In association with this, the signal lines s505a and s506 are incorporated into signal lines in the group.

(Step 109) Since a reaching signal line has been selected at Step 109, the apparatus goes to Step 206.

(Step 206) In order to propagate the fault value to the signal lines s505a and s506 in the group, the apparatus performs activation, implication operation, and justification. However, before this step is executed, a value 1 has been set up to the signal line s511. Thus, without the necessity of setting up a new value to the signal line, a fault value ND is propagated to the signal lines s505a and s506 in the group.

(Step 111) Since no inconsistency arises at Step 206, the apparatus goes to Step 103.

(Steps 103-104) Since the signal line s506 is a stem, the apparatus sets up the signal lines s506a and s506b to be reaching candidate signal lines, and then goes to Step 108.

(Step 108) The apparatus acquires the longest observation distances of the reaching candidate signal lines s506a and s506b. When the observation distance is estimated in terms of the number of gate stages, the longest observation distance of the signal line s506a is 1, while the longest observation distance of the signal line s506b is 3. Thus, the apparatus selects as a reaching signal line the reaching candidate signal line s506b having the maximum longest observation distance. In association with this, the signal lines s506b, s513, s514, and s515 are incorporated into signal lines in the group.

(Step 206) In order to propagate the fault value to the signal lines s506b, s513, s514, and s515 in the group, the apparatus performs activation, implication operation, and justification. Nevertheless, before this step is executed, a value 0 has been set up to the signal line s519a. Thus, when the apparatus sets up a value 1 to the signal line s519a in order to propagate the fault value ND of the signal line s513 to the signal line s514, inconsistency arises.

(Step 111) Since inconsistency arises at Step 206, the apparatus goes to Step 112.

(Step 112) The apparatus excludes the reaching signal line s506b from the reaching candidate signal lines. At this time point, the only reaching candidate signal line is the signal line s506a.

(Step 108) The apparatus selects as new reaching signal lines the group including the reaching candidate signal line s506a. In association with this, the signal lines s506a and s507 are incorporated into signal lines in the group.

(Step 206) In order to propagate the fault value to the signal lines s506a and s507 in the group, the apparatus performs activation, implication operation, and justification. As a result, a value 0 is set up to the signal line s501 and the control point PI501, so that a fault value ND is propagated to the signal lines s506a and s507. The test sequence T2 is updated into {P}={1, 1, 1, 0, 0, X, X, X}.

(Step 111) Since no inconsistency arises at Step 206, the apparatus goes to Step 103.

(Step 103) The apparatus sets up the signal line s507 to be a reaching candidate signal line.

(Step 104) Since the number of reaching candidate signal lines is one, the apparatus goes to Step 105.

(Step 105) The reaching candidate signal line s507 is connected to the observation point PO501 and can be observed. Thus, the apparatus goes to Step 19.

As a result of the above-mentioned processing, {P}={X, 0, X, X, X, X, X, X} is generated as the test sequence T1, while {P}={1, 1, 1, 0, 0, X, X, X} is generated as the test sequence T2.

As described above, according to the second generation method, activation, implication operation, and justification are performed collectively for a plurality of signal lines so that the processing time is shortened.

In the description given above, the apparatus has performed circuit conversion at Step 201. However, Instead, in the activation, the implication operation, and the justification of the reaching signal line, a partial circuit located in a part from a branch (or an external input) to a stem (or external output) connecting without going via a branch point may be treating as one group. Even in this method, the same effect is obtained.

### Third Embodiment

FIG. 11 is a flow chart showing a third generation method. The third generation method is a modification of the first generation method, where Steps 301 and 302 are added while Step 103 is replaced by Step 303. The third generation method is characterized in that branches included in a short path are excluded in advance from the candidates of reaching signal lines.

The maximum value of the lengths of the paths from a particular point to another point within the test target circuit is referred to as the longest distance between the two points. Further, for each signal line in the test target circuit, paths are defined from each control point to each observation point via the signal line. Then, the maximum value of the lengths of the paths is referred to as the longest test path length of the signal line. Further, for each control point in the test target circuit, paths are defined from the control point to each observation point. Then, the maximum value of the lengths of the paths is referred to as the longest test path length of the control point. Here, the path length is calculated on the basis of: the time delay obtained from the wiring of the circuit and the gate delay information; the number of gates on the path; the number of via holes on the path; and the like.

The following steps appear for the first time in the third generation method.

(Step 301) The apparatus sets up the criterion value for determining whether the branch is included in the reaching candidate signal line

(Step 302) For each branch on a path extending from the test target signal line selected at Step 11 to an arbitrary observation point, the apparatus calculates the longest test path length. This length is obtained by adding the longest distance between the selected test target signal line and the stem to the longest distance between the branch and an arbitrary observation point.

(Step 303) The apparatus updates the reaching candidate signal line similarly to Step 103. However, when the signal line connected to the output side of the reaching signal line is a branch, branches having the longest test path length greater than or equal to the criterion value set up at Step 301 are incorporated into reaching candidate signal lines.

The processing is described below for the case that the third generation method is applied to the test target circuit shown in FIG. 5. Here, a rise transition in the signal line s9 is adopted as a test target. {PI1, PI2, PI3, PI4, PI5, PI6, PI7} is denoted by {P}.

(Step 301) The apparatus sets up the criterion value of the reaching candidate signal line into 4.

(Step 302) In the test target circuit shown in FIG. 5, the paths extending from the test target signal line s9 to the observation points PO1 and PO2 include the branches s10a and s10b. When the length of a path is estimated in terms of the number of gate stages, the longest distance between the test target signal line s9 and the stem s10 is 1, while the longest distance between the branch s10a and the observation point PO1 is 3, and while the longest distance between the branch s10b and the observation point PO2 is 2. Thus, the longest test path lengths of the branches s10a and s10b are 4 and 3, respectively.

(Steps 13-16 and 101-102) The apparatus performs the same processing as that of the first generation method. The test sequence T1 is updated into {P}={X, X, X, 0, X, X, X}, while the test sequence T2 is updated into {P}={X, 1, X, 1, X, X, X}.

(Step 303) The apparatus sets up the signal line s9 to be a reaching signal line. Since the signal line connected to the output side of the reaching signal line is not a branch, the apparatus sets up the signal line s10 to be a reaching candidate signal line.

(Steps 104-107 and 102) The apparatus performs the same processing as that of the first generation method. In particular, at Step 106, the apparatus sets up the test target signal line s10 to be a reaching signal line.

(Step 303) The reaching signal line s10 is a stem, while the signal lines s10a and s10b are connected to the output side of the reaching signal line s10. Here, the length of the longest test path of the branch s10a is 4, and hence is greater than or equal to the criterion value set up at Step 301. On the other hand, the length of the longest test path of the branch s10b is 3, and hence is smaller than the criterion value. Thus, the apparatus incorporates the signal line s10a into reaching candidate signal lines, but does not incorporate the signal line s10b into reaching candidate signal lines. As such, the apparatus sets up the signal line s10a to be a reaching candidate signal line.

(Steps 104-106) The reaching candidate signal line s10a is in a single number and cannot be observed. Thus, the apparatus sets up the signal line s10a to be a reaching signal line.

(Step 107) In order to propagate the fault value D of the reaching signal line s10a to the signal line s7, the apparatus performs activation, implication operation, and justification. As a result, a value 0 is set up to the signal lines s6, s6a, and s6b and the control point PI3, so that a fault value D is propagated to the signal line s7. The test sequence T2 is updated into {P}={X, 1, 0, 1, X, X, X}.

(Step 102) Since no inconsistency arises at Step 107, the apparatus goes to Step 303.

(Step 303) The apparatus sets up the signal line s7 to be a reaching candidate signal line.

(The subsequent steps) The apparatus performs the same processing as that of the first generation method. Here, in the third generation method, Step 303 is executed in place of Step 103. However, when the reaching signal line is not a branch, the contents of Step 303 are the same as those of Step 103.

As a result of the above-mentioned processing, similarly to the first generation method, {P}={X, X, X, 0, X, X, X} is generated as the test sequence T1, while {P}={0, 1, 0, 1, 0, X, X} is generated as the test sequence T2.

As described above, according to the third generation method, branches included in a short path are excluded in advance from the candidates of reaching signal lines, so that the processing time is shortened.

### Fourth Embodiment

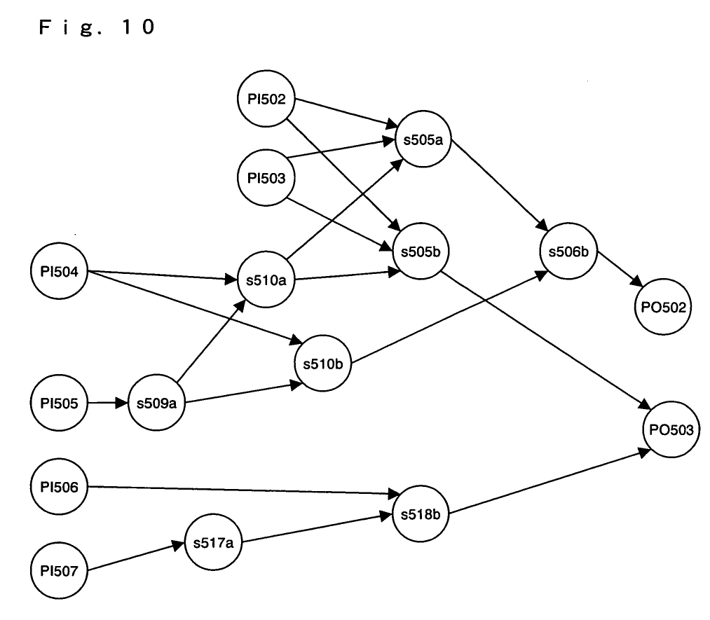

A fourth generation method is a modification of the first generation method (FIG. 4), where Step 100 is replaced by Step 400 (FIG. 12). Step 400 is a modification of Step 100, where Steps 101, 107, and 110 are replaced by Steps 401-403, respectively. The fourth generation method is characterized in that activation is performed according to a robust condition. At Step 400, the test sequence T1 generated at Step 14 is updated in addition to the test sequence T2.

The following steps appear for the first time in the fourth generation method.

(Step 401) In order to set up a fault value to the test target signal line and then propagate the set-up fault value toward the output side by one gate stage, the apparatus performs activation, implication operation, and justification. At that time, the apparatus performs the activation under the robust condition.

(Step 402) In order to propagate the fault value toward the output side of the reaching signal line by one gate stage, the apparatus performs activation, implication operation, and justification. At that time, the apparatus performs the activation under the robust condition. After that, the apparatus goes to Step 102.

(Step 403) The apparatus performs the same processing as Step 402. After that, the apparatus goes to Step 111.

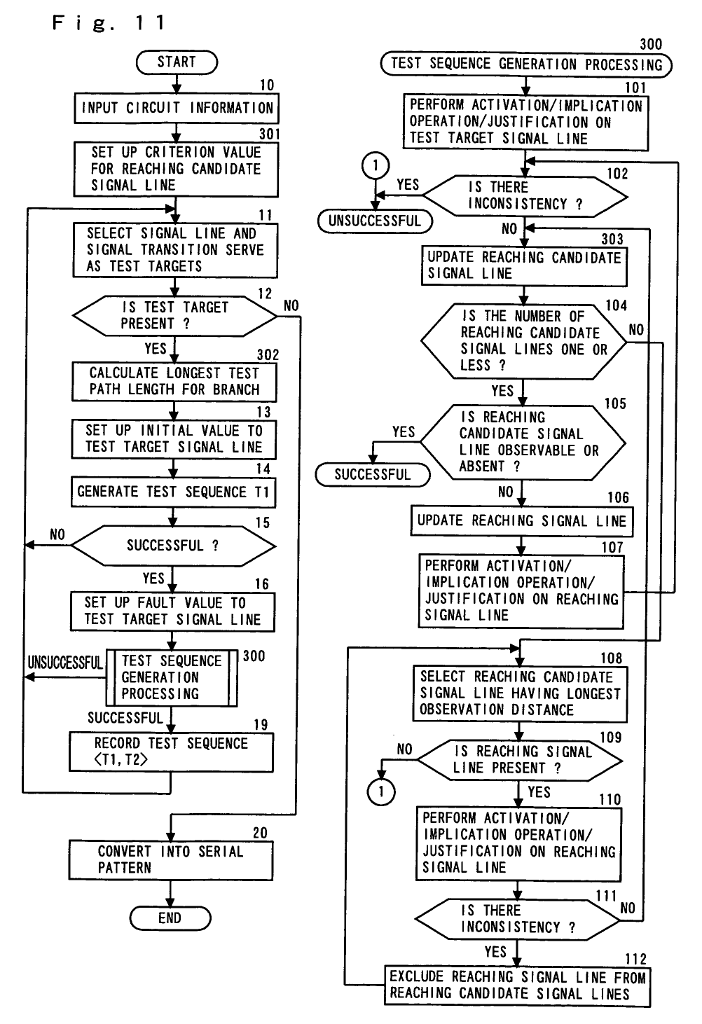

The processing is described below for the case that the fourth generation method is applied to the test target circuit shown in FIG. 13. Here, a fall transition in the signal line s25 is adopted as a test target. {PI21, PI22, PI23, PI24, PI25, PI26, PI27} is denoted by {P}.

(Step 13) The apparatus sets up an initial value of 1 to the test target signal line s25.

(Step 14) In order to set up an initial value of 1 to the test target signal line s25, the apparatus sets up a value 1 to the control point PI22. The test sequence T1 is updated into {P}={X, 1, X, X, X, X, X}.

(Step 15) Since the generation of the test sequence T1 has been successful, the apparatus goes to Step 16.

(Step 16) The apparatus sets up a fault value D to the test target signal line s37.

(Step 401) In order to set up a fault value D to the test target signal line s37 and then propagate the set-up fault value D to the signal line s30, the apparatus performs activation under the robust condition, implication operation, and justification. As a result, a value 0 is set up to the control point PI22, while a value S1 is set up to the signal line s29 and the control point PI24, so that a fault value D is propagated to the signal line s30. The test sequence T1 is updated into {P}={X, 1, X, 1, X, X, X}, while the test sequence T2 is updated into {P}={X, 0, X, 1, X, X, X}.

(Step 102) Since no inconsistency arises at Step 401, the apparatus goes to Step 103.

(Steps 103-106) The apparatus sets up the signal line s30 (unobservable) to be a reaching candidate signal line, and then sets up the signal line s30 to be a reaching signal line.

(Step 402) Since the reaching signal line s30 is a stem, the apparatus goes to Step 102 without performing activation, implication operation, and justification.

(Step 102) Since no inconsistency arises at Step 402, the apparatus goes to Step 103.

(Steps 103-104) Since the signal line s30 is a stem, the apparatus sets up the signal lines s30a and s30b to be reaching candidate signal lines, and then goes to Step 108.

(Step 108) The apparatus acquires the longest observation distances of the reaching candidate signal lines s30a and s30b. When the observation distance is estimated in terms of the number of gate stages, the longest observation distance of the signal line s30a is 3, while the longest observation distance of the signal line s30b is 2. Thus, the apparatus selects as a reaching signal line the reaching candidate signal line s30a having the maximum longest observation distance.

(Step 109) Since a reaching signal line has been selected at Step 108, the apparatus goes to Step 403.

(Step 403) In order to propagate the fault value D of the reaching signal line s30a to the signal line s27, the apparatus performs activation under the robust condition, implication operation, and justification. As a result, a value S1 is set up to the control point PI23, so that a value ND is propagated to the signal line s27. The test sequence T1 is updated into {P}={X, 1, 1, 1, X, X, X}, while the test sequence T2 is updated into {P}={X, 0, 1, 1, X, X, X}.

(Step 111) Since no inconsistency arises at Step 403, the apparatus goes to Step 103.

(Steps 103-106) The apparatus sets up the signal line s27 (unobservable) to be a reaching candidate signal line, and then sets up the signal line s27 to be a reaching signal line.

(Step 402) In order to propagate the fault value ND of the reaching signal line s27 to the signal line s28, the apparatus performs activation under the robust condition, implication operation, and justification. As a result, a value S0 is set up to the signal line s31 and the control point PI25, so that a value ND is propagated to the signal line s28. The test sequence T1 is updated into {P}={X, 1, 1, 1, 0, X, X}, while the test sequence T2 is updated into {P}={X, 0, 1, 1, 0, X, X}.

(Step 102) Since no inconsistency arises at Step 402, the apparatus goes to Step 103.

(Steps 103-106) The apparatus sets up the signal line s28 (unobservable) to be a reaching candidate signal line, and then sets up the signal line s28 to be a reaching signal line.

(Step 402) In order to propagate the fault value D of the reaching signal line s28 to the signal line s24, the apparatus performs activation under the robust condition, implication operation, and justification. As a result, a value S0 is set up to the signal lines s23, s22, and s21 and the control point PI21, so that a fault value D is propagated to the signal line s24. The test sequence T1 is updated into {P}={0, 1, 1, 1, 0, X, X}, while the test sequence T2 is updated into {P}={X, 0, 1, 1, 0, X, X}.

(Step 102) Since no inconsistency arises at Step 402, the apparatus goes to Step 103.

(Step 103) The apparatus sets up the signal line s24 to be a reaching candidate signal line.

(Step 104) Since the number of reaching candidate signal lines is one, the apparatus goes to Step 105.

(Step 105) The reaching candidate signal line s24 is connected to the observation point PO21 and can be observed. Thus, the apparatus goes to Step 19.

As a result of the above-mentioned processing, {P}={0, 1, 1, 1, 0, X, X} is generated as the test sequence T1, while {P}={X, 0, 1, 1, 0, X, X} is generated as the test sequence T2. Here, in the above-mentioned example, when the activation under the robust condition, the implication operation, and the justification are performed, the test sequence T1 is not updated. However, in general, when the activation under the robust condition, the implication operation, and the justification are performed, the test sequence T1 is updated.

As described above, according to the fourth generation method, activation is performed according to a robust condition so that a delay fault on a path including a test target signal line can be tested regardless of whether a delay fault occurs on another signal line.

### Fifth Embodiment

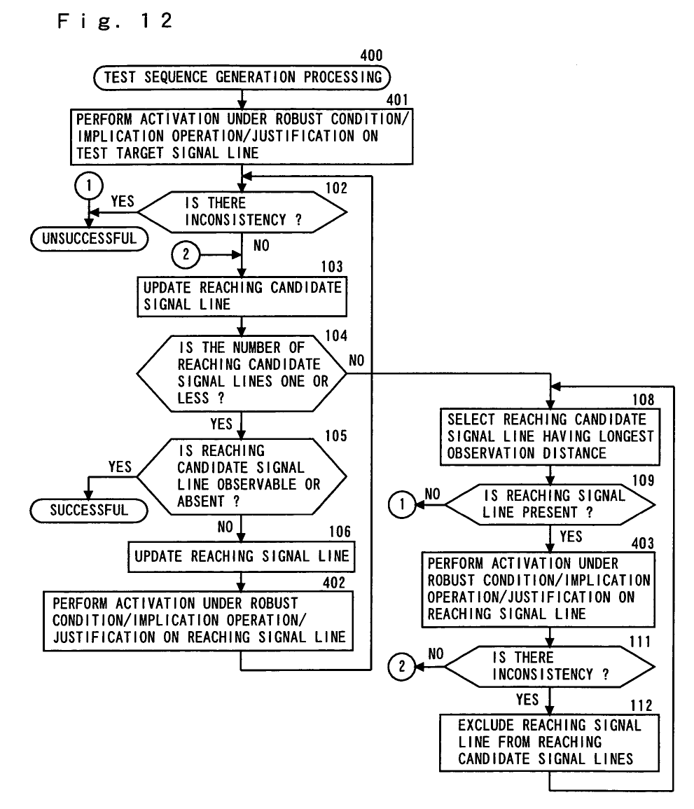

A fifth generation method is a modification of the first generation method (FIG. 4), where Step 100 is replaced by Step 500 (FIG. 14). Step 500 is a modification of Step 100, where Steps 101, 107, and 110 are replaced by Steps 501-503. The fifth generation method is characterized in that activation is performed according to a non-robust condition.

The following steps appear for the first time in the fifth generation method.

(Step 501) In order to set up a fault value to the test target signal line and then propagate the set-up fault value toward the output side by one gate stage, the apparatus performs activation, implication operation, and justification. At that time, the apparatus performs activation according to the non-robust condition.

(Step 502) In order to propagate the fault value toward the output side of the reaching signal line by one gate stage, the apparatus performs activation, implication operation, and justification. At that time, the apparatus performs activation according to the non-robust condition. After that, the apparatus goes to Step 102.

(Step 503) The apparatus performs the same processing as Step 502. After that, the apparatus goes to Step 111.

The processing is described below for the case that the fifth generation method is applied to the test target circuit shown in FIG. 5. Here, a fall transition in the signal line s6 is adopted as a test target. {PI1, PI2, PI3, PI4, PI5, PI6, PI7} is denoted by {P}.

(Step 13) The apparatus sets up an initial value of 1 to the test target signal line s6.

(Step 14) In order to set up an initial value of 1 to the test target signal line s6, the apparatus sets up a value 1 to the control point PI3. The test sequence T1 is updated into {P}={X, X, 1, X, X, X, X}.

(Step 15) Since the generation of the test sequence T1 has been successful, the apparatus goes to Step 16.

(Step 16) The apparatus sets up a fault value D to the test target signal line s6.

(Step 501) In order to set up a fault value D to the test target signal line s6, the apparatus performs activation under the non-robust condition, implication operation, and justification. As a result, a value 0 is set up to the signal line s6 and the control point PI3. The test sequence T2 becomes {p}={X, X, 0, X, X, X, X}.

(Step 102) Since no inconsistency arises at Step 501, the apparatus goes to Step 103.

(Steps 103-104) Since the signal line s6 is a stem, the apparatus sets up the signal lines s6a and s6b to be reaching candidate signal lines, and then goes to Step 108.

(Step 108) The apparatus acquires the longest observation distances of the reaching candidate signal lines s6a and s6b. When the observation distance is estimated in terms of the number of gate stages, the longest observation distance of the signal line s6a is 2, while the longest observation distance of the signal line s6b is 3. Thus, the apparatus selects as a reaching signal line the reaching candidate signal line s6b having the maximum longest observation distance.

(Step 109) Since no inconsistency arises at Step 108, the apparatus goes to Step 503.

(Step 503) In order to propagate the fault value D of the reaching signal line s6b to the signal line s7, the apparatus performs activation under the non-robust condition, implication operation, and justification. As a result, a value U0 is set up to the signal line s10a, so that a value D is propagated to the signal line s7. Further, a value U1 is set up to the signal lines s9 and s5b and the control points PI2 and PI4. The test sequence T2 is updated into {P}={X, 1, 0, 1, X, X, X}.

(Step 111) Since no inconsistency arises at Step 503, the apparatus goes to Step 103.

(Steps 103-106) The apparatus sets up the signal line s7 (unobservable) to be a reaching candidate signal line, and then sets up the signal line s7 to be a reaching signal line.

(Step 502) In order to propagate the fault value D of the test target signal line s7 to the signal line s8, the apparatus performs activation under the non-robust condition, implication operation, and justification. As a result, a value U0 is set up to the signal line s11 and the control point PI5. The test sequence T2 is updated into {P}={X, 1, 0, 1, 0, X, X}.

(Step 102) Since no inconsistency arises at Step 502, the apparatus goes to Step 103.

(Steps 103-106) The apparatus sets up the signal line s8 (unobservable) to be a reaching candidate signal line, and then sets up the signal line s8 to be a reaching signal line.

(Step 502) In order to propagate the fault value ND of the test target signal line s8 to the signal line s4, the apparatus performs activation under the non-robust condition, implication operation, and justification. As a result, a value U0 is set up to the signal lines s3, s2, and s1 and the control point PI1, so that a fault value D is propagated to the signal line s4. The test sequence T2 is updated into {P}={0, 1, 0, 1, 0, X, X}.

(Step 102) Since no inconsistency arises at Step 502, the apparatus goes to Step 103.

(Step 103) The apparatus sets up the signal line s4 to be a reaching candidate signal line.

(Step 104) Since the number of reaching candidate signal lines is one, the apparatus goes to Step 105.

(Step 105) The signal line s4 is connected to the observation point PO1 and can be observed. Thus, the apparatus goes to Step 19.

As a result of the above-mentioned processing, {P}={X, X, 1, X, X, X, X} is generated as the test sequence T1, while {P}={0, 1, 0, 1, 0, X, X} is generated as the test sequence T2.

As described above, according to the fifth generation method, activation is performed according to a non-robust condition so that the influence of delay on a path including a test target signal line can be detected using a longer path.

### Sixth Embodiment

A sixth generation method is a modification of the first generation method (FIG. 4), where Step 100 is replaced by Step 600 (FIG. 15). Step 600 is a modification of Step 400 (FIG. 12), where Steps 601-609 are added. The sixth generation method is characterized in that activation is performed according to a robust condition and then when the activation according to the robust condition has been unsuccessful for all reaching candidate signal lines which can be selected at a particular branch point, activation is performed according to a non-robust condition. At Step 600, the test sequence T1 generated at Step 14 is updated in addition to the test sequence T2.

The following steps appear for the first time in the sixth generation method.

(Step 601) When inconsistency arises at Step 402, the apparatus goes to Step 602. Otherwise, the apparatus goes to Step 103.

(Step 602) The apparatus performs the same processing as Step 502.

(Step 603) The apparatus holds the reaching candidate signal lines at the time point, for the purpose of later referencing.

(Step 604) The apparatus re-sets the signal line held at Step 603, to be a reaching candidate signal line.

(Step 605) The apparatus performs the same processing as Step 108.

(Step 606) When a reaching signal line has been selected at Step 605, the apparatus goes to Step 607. Otherwise, the apparatus goes to Step 11.

(Step 607) The apparatus performs the same processing as Step 502.

(Step 608) When inconsistency arises at Step 607, the apparatus goes to Step 609. Otherwise, the apparatus goes to Step 103.

(Step 609) The apparatus performs the same processing as Step 112. After that, the apparatus goes to Step 605.

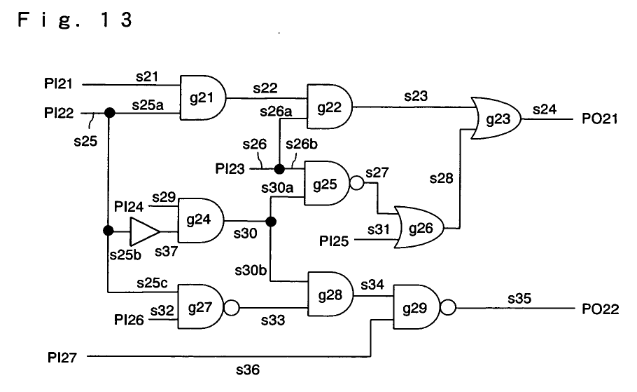

The processing is described below for the case that the sixth generation method is applied to the test target circuit shown in FIG. 16. Here, a fall transition in the signal line s1502 is adopted as a test target. {PI1501, PI1502, PI1503, PI1504} is denoted by {P}.

(Step 13) The apparatus sets up an initial value of 1 to the signal line s1502.

(Step 14) In order to set up an initial value of 1 to the test target signal line s1502, the apparatus sets up a value 1 to the control point PI1502. The test sequence T1 is updated into {P}={X, 1, X, X}.

(Step 15) Since the generation of the test sequence T1 has been successful, the apparatus goes to Step 16.

(Step 16) The apparatus sets up a fault value D to the test target signal line s1502.

(Step 401) In order to set up a fault value D to the test target signal line s1502, the apparatus performs activation under the robust condition, implication operation, and justification. As a result, a value 0 is set up to the signal line s1502 and the control point PI1502. The test sequence T2 is updated into {P}={X, 0, X, X}.

(Step 102) Since no inconsistency arises at Step 401, the apparatus goes to Step 103.

(Steps 103-104) Since the signal line s1502 is a stem, the apparatus sets up the signal lines s1502a and s1502b to be reaching candidate signal lines, and then goes to Step 603.

(Step 603) The apparatus holds the reaching candidate signal lines s1502a and s1502b.

(Step 108) The apparatus acquires the longest observation distances of the reaching candidate signal lines s1502a and s1502b. When the observation distance is estimated in terms of the number of gate stages, the longest observation distance of the signal line s1502a is 3, while the longest observation distance of the signal line s1502b is 4. Thus, the apparatus selects as a reaching signal line the reaching candidate signal line s1502b having the maximum longest observation distance.

(Step 109) Since a reaching signal line has been selected at Step 108, the apparatus goes to Step 403.

(Step 403) In order to propagate the fault value D of the reaching signal line s1502b to the signal line s1505, the apparatus performs activation under the robust condition, implication operation, and justification. As a result, a value S1 is set up to the signal line s1503 and the control point PI1503, so that a fault value D is propagated to the signal line s1505. The test sequence T1 is updated into {P}={X, 1, 1, X}, while the test sequence T2 is updated into {P}={X, 0, 1, X}.

(Step 111) Since no inconsistency arises at Step 403, the apparatus goes to Step 103.

(Steps 103-106) The apparatus sets up the signal line s1505 (unobservable) to be a reaching candidate signal line, and then sets up the signal line s1505 to be a reaching signal line.

(Step 402) Since the reaching signal line s1505 is a stem, the apparatus goes to Step 601 without performing activation, implication operation, and justification.

(Step 601) Since no inconsistency arises at Step 402, the apparatus goes to Step 103.

(Steps 103-104) Since the signal line s1505 is a stem, the apparatus sets up the signal lines s1505a and s1505b to be reaching candidate signal lines, and then goes to Step 603.

(Step 603) The apparatus holds the reaching candidate signal lines s1505a and s1505b.

(Step 108) The apparatus acquires the longest observation distances of the reaching candidate signal lines s1505a and s1505b. When the observation distance is estimated in terms of the number of gate stages, the longest observation distance of the signal line s1505a is 3, while the longest observation distance of the signal line s1505b is 2. Thus, the apparatus selects as a reaching signal line the reaching candidate signal line s1505a having the maximum longest observation distance. The fault value propagated to the signal line s1505a is necessarily propagated to the signal line s1508. Thus, when the apparatus selects the signal line s1505a, the signal line s1508 is necessarily selected as a reaching signal line. A fault value ND is propagated to the signal line s1508.

(Step 109) Since a reaching signal line has been selected at Step 108, the apparatus goes to Step 403.

(Step 403) In order to propagate the fault value ND of the reaching signal line s1508 to the signal line s1509, the apparatus performs activation under the robust condition, implication operation, and justification. As a result, a value S0 is set up to the signal line s1504a and the control point PI1504, so that a fault value ND is propagated to the signal line s1509. The test sequence T1 is updated into {P}={X, 1, 1, 0}, while the test sequence T2 is updated into {P}={X, 0, 1, 0}.

(Step 111) Since no inconsistency arises at Step 403, the apparatus goes to Step 103.

(Steps 103-106) The apparatus sets up the signal line s1509 (unobservable) to be a reaching candidate signal line, and then sets up the signal line s1509 to be a reaching signal line.

(Step 402) Since the reaching signal line s1509 is a stem, the apparatus goes to Step 601 without performing activation, implication operation, and justification.

(Step 601) Since no inconsistency arises at Step 402, the apparatus goes to Step 103.

(Steps 103-104) Since the signal line s1509 is a stem, the apparatus sets up the signal lines s1509a, s1509b, and s1509c to be reaching candidate signal lines, and then goes to Step 603.

(Step 603) The apparatus holds the reaching candidate signal lines s1509a, s1509b, and s1509c.

(Step 108) The apparatus acquires the longest observation distances of the reaching candidate signal lines s1509a, s1509b, and s1509c. When the observation distance is estimated in terms of the number of gate stages, the longest observation distance of each of these three reaching candidate signal lines is 1. Since any of these three reaching candidate signal lines may be selected, the apparatus selects the reaching candidate signal line s1509a as a reaching signal line.

(Step 109) Since a reaching signal line has been selected at Step 108, the apparatus goes to Step 110.

(Step 110) In order to propagate the fault value ND of the reaching signal line s1509a to the signal line s1511, the apparatus performs activation under the robust condition, implication operation, and justification. Nevertheless, before this step is executed, the values of the control point PI1502 and the signal line s1507 in the test sequence T1 have already been determined as 1 each. Thus, when the apparatus sets up a value S0 to the signal line s1507 in order to propagate the fault value ND of the signal line s1509a to the signal line s1511, inconsistency arises.

(Step 111) Since inconsistency has arisen at Step 206, the apparatus goes to Step 112.

(Step 112) The apparatus excludes the reaching signal line s1509a from the reaching candidate signal lines. At this time point, the reaching candidate signal lines are the signal lines s1509b and s1509c. After that, the apparatus goes to Step 108.

(Step 108) From among the reaching candidate signal lines s1509b and s1509c, the apparatus selects arbitrarily the reaching candidate signal line s1509b as a reaching signal line.

(Step 109) Since a reaching signal line has been selected at Step 108, the apparatus goes to Step 110.

(Step 110) In order to propagate the fault value ND of the reaching signal line 1509b to the signal line s1512, the apparatus performs activation under the robust condition, implication operation, and justification. Nevertheless, before this step is executed, the values of the control points PI1502 and PI1503 and the signal line s1510 in the test sequence T1 have already been determined as 1. Thus, when the apparatus sets up a value S0 to the signal line s1510a in order to propagate the fault value ND of the signal line s1509b to the signal line s1512, inconsistency arises.

(Step 111) Since inconsistency has arisen at Step 206, the apparatus goes to Step 112.

(Step 112) The apparatus excludes the reaching signal line s1509b from the reaching candidate signal lines. At this time point, the only reaching candidate signal line is the signal line s1509c. After that, the apparatus goes to Step 108.

(Step 108) The apparatus selects the reaching candidate signal line s1509c as a reaching signal line.

(Step 109) Since a reaching signal line has been selected at Step 108, the apparatus goes to Step 110.

(Step 110) In order to propagate the fault value ND of the reaching signal line s1509c to the signal line s1513, the apparatus performs activation under the robust condition, implication operation, and justification. Nevertheless, as described above, before this step is executed, the value of the control point PI1510 in the test sequence T1 has been determined as 1. Thus, when the apparatus sets up a value S0 to the signal line s1510b in order to propagate the fault value ND of the signal line s1509c to the signal line s1513, inconsistency arises.

(Step 111) Since inconsistency has arisen at Step 110, the apparatus goes to Step 112.

(Step 112) The apparatus excludes the reaching signal line s1509c from the reaching candidate signal lines. At this time point, no reaching candidate signal line is present. After that, the apparatus goes to Step 108.

(Step 108) Since no reaching candidate signal line is present, the apparatus does not select any reaching candidate signal line as a reaching signal line.

(Step 109) Since no reaching signal line has been selected at Step 108, the apparatus goes to Step 604.

(Step 604) The apparatus re-sets the signal lines s1509a, 1509b, 1509c held at Step 603, to be a reaching candidate signal line.

(Step 605) From among the reaching candidate signal lines s1509a, s1509b, and s1509c, the apparatus selects arbitrarily the reaching candidate signal line s1509a as a reaching signal line.

(Step 606) Since a reaching signal line has been selected at Step 605, the apparatus goes to Step 607.

(Step 607) In order to propagate the fault value ND of the reaching signal line s1509a to the signal line s1511, the apparatus performs activation under the non-robust condition, implication operation, and justification. As a result, a value U0 is set up to the signal line s1507, while a value U1 is set up to the control point PI1501, so that a fault value ND is propagated to the signal line s1511. The test sequence T1 is updated into {P}={X, 1, 1, 0}, while the test sequence T2 is updated into {P}={1, 0, 1, 0}.

(Step 608) Since no inconsistency arises at Step 607, the apparatus goes to Step 103.

(Step 103) The apparatus sets up the signal line s1511 to be a reaching candidate signal line.

(Step 104) Since the number of reaching candidate signal lines is one, the apparatus goes to Step 105.

(Step 105) The reaching candidate signal line s1511 is connected to the observation point PO1501 and can be observed. Thus, the apparatus goes to Step 19.

As a result of the above-mentioned processing, {P}={X, 1, 1, 0} is generated as the test sequence T1, while {P}={1, 0, 1, 0} is generated as the test sequence T2.

As described above, in the sixth generation method, activation is performed according to a robust condition and then when the activation according to the robust condition has been unsuccessful for all reaching candidate signal lines located at a particular branch point, activation is performed according to a non-robust condition. Thus, a test pattern can be generated that permits test of a fault which is untestable under the robust condition.

### Seventh Embodiment

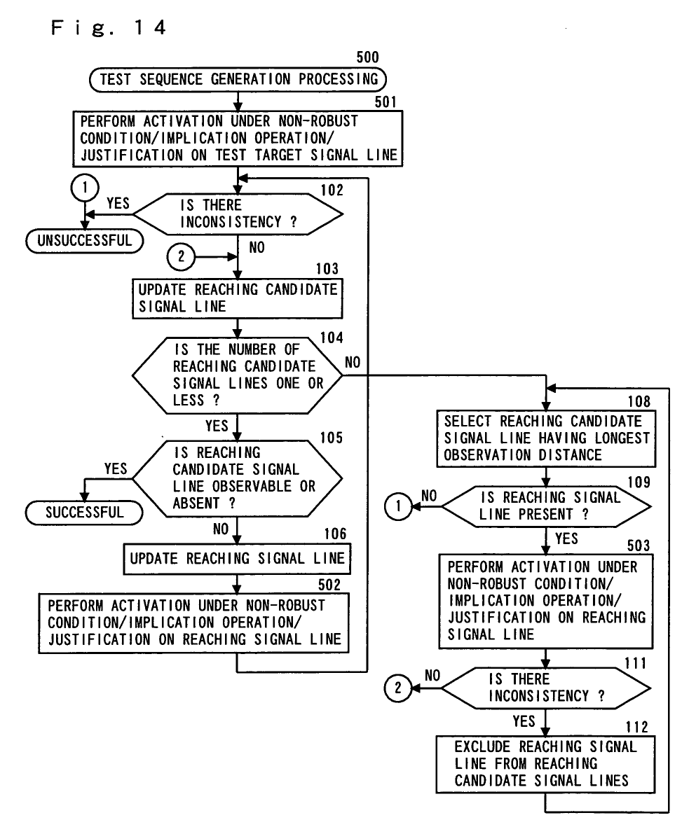

A seventh generation method is a modification of the first generation method (FIG. 4), where Step 100 is replaced by Step 700 (FIG. 17). Step 700 is a modification of Step 600 (FIG. 15), where Step 701 is added while Steps 111, 112, and 603-606 are omitted. The seventh generation method is characterized in that for each reaching candidate signal line, activation is first performed according to the robust condition and then when the activation has been unsuccessful, activation is performed according to a non-robust condition. At Step 700, the test sequence T1 generated at Step 14 is updated in addition to the test sequence T2.

The following steps appear for the first time in the seventh generation method.

(Step 701) When inconsistency arises at Step 403, the apparatus goes to Step 607. Otherwise, the apparatus goes to Step 103.

The processing is described below for the case that the seventh generation method is applied to the test target circuit shown in FIG. 5. Here, a fall transition in the signal line s6 is adopted as a test target. {PI1, PI2, PI3, PI4, PI5, PI6, PI7} is denoted by {P}.

(Steps 13-16) The apparatus performs the same processing as that of the fifth generation method. The test sequence T1 is updated into {P}={X, X, 1, X, X, X, X}.

(Step 401) In order to set up a fault value D to the test target signal line s6, the apparatus performs activation under the robust condition, implication operation, and justification. As a result, a value U0 is set up to the signal lines s6, s6a, and s6b, while a value 0 is set up to the control point PI3. The test sequence T2 is updated into {P}={X, X, 0, X, X, X, X}.

(Step 102) Since no inconsistency arises at Step 501, the apparatus goes to Step 103.

(Steps 103-104) Since the signal line s6 is a stem, the apparatus sets up the signal lines s6a and s6b to be reaching candidate signal lines, and then goes to Step 108.

(Step 108) The apparatus acquires the longest observation distances of the reaching candidate signal lines s6a and s6b. When the observation distance is estimated in terms of the number of gate stages, the longest observation distance of the signal line s6a is 2, while the longest observation distance of the signal line s6b is 3. Thus, the apparatus selects as a reaching signal line the reaching candidate signal line s6b having the maximum longest observation distance.

(Step 109) Since a reaching signal line has been selected at Step 108, the apparatus goes to Step 403.

(Step 403) In order to propagate the fault value D of the reaching signal line s6b to the signal line s27, the apparatus performs activation under the robust condition, implication operation, and justification. As a result, a value U0 is set up to the signal line s10a, while a value U1 is set up to the control points PI2 and PI4, so that a fault value D is propagated to the signal line s7. The test sequence T2 is updated into {P}={X, 1, 0, 1, X, X, X}.

(Step 701) Since no inconsistency arises at Step 403, the apparatus goes to Step 103.

(Steps 103-106) The apparatus sets up the signal line s7 (unobservable) to be a reaching candidate signal line, and then sets up the signal line s7 to be a reaching signal line.

(Step 402) In order to propagate the fault value D of the reaching signal line s7 to the signal line s8, the apparatus performs activation under the robust condition, implication operation, and justification. As a result, a value U0 is set up to the signal line s11 and the control point PI5, so that a fault value ND is propagated to the signal line s8. The test sequence T2 is updated into {P}={X, 1, 0, 1, 0, X, X}.

(Step 102) Since no inconsistency arises at Step 402, the apparatus goes to Step 103.

(Steps 103-104) Since the signal line s8 is a stem, the apparatus sets up the signal lines s8a and s8b to be reaching candidate signal lines, and then goes to Step 108.

(Step 108) The apparatus acquires the longest observation distances of the reaching candidate signal lines s8a and s8b. When the observation distance is estimated in terms of the number of gate stages, the longest observation distance of the signal line s8a is 1, while the longest observation distance of the signal line s8b is 0. Thus, the apparatus selects as a reaching signal line the reaching candidate signal line s8a having the maximum longest observation distance.

(Step 109) Since a reaching signal line has been selected at Step 108, the apparatus goes to Step 403.

(Step 403) In order to propagate the fault value ND of the reaching signal line s8a to the signal line s4, the apparatus performs activation under the robust condition, implication operation, and justification. Nevertheless, before this step is executed, the values of the control point PI3 and the signal line s3 in the test sequence T1 have already been determined as 1. Thus, when the apparatus sets up a value S0 to the signal line s3 in order to propagate the fault value ND of the signal line s8a to the signal line s4, inconsistency arises.

(Step 701) Since inconsistency has arisen at Step 701, the apparatus goes to Step 607.

(Step 607) In order to propagate the fault value ND of the reaching signal line s8a to the signal line s4, the apparatus performs activation under the non-robust condition, implication operation, and justification. As a result, a value U0 is set up to the signal lines s1, s2, and s3 and the control point PI1, so that a fault value ND is propagated to the signal line s4. The test sequence T2 is updated into {P}={0, 1, 0, 1, 0, X, X}.

(Step 102) Since no inconsistency arises at Step 608, the apparatus goes to Step 103.

(Step 103) The apparatus sets up the signal line s4 to be a reaching candidate signal line.

(Step 104) Since the number of reaching candidate signal lines is one, the apparatus goes to Step 105.

(Step 105) The reaching candidate signal line s4 is connected to the observation point PO1 and can be observed. Thus, the apparatus goes to Step 19.

As a result of the above-mentioned processing, {P}={X, X, 1, X, X, X, X} is generated as the test sequence T1, while {P}={0, 1, 0, 1, 0, X, X} is generated as the test sequence T2.

As described above, in the seventh generation method, for each reaching candidate signal line, activation is first performed according to the robust condition, and then when the activation has been unsuccessful, activation is performed according to a non-robust condition. As such, activation according to a robust condition is executed with priority, so that even when the detection path for a delay fault is the same, a high-quality test pattern can be generated.

In the sixth and seventh generation methods, when the activation had been unsuccessful under the robust condition, activated has been performed under the non-robust condition. Alternatively, when the activation is unsuccessful under the robust condition, the apparatus may perform activation in accordance with the path activation table and the implication table shown in FIG. 46 in place of the non-robust condition. Further, when the activation is unsuccessful under the robust condition and under the non-robust condition, the apparatus may perform activation in accordance with the path activation table and the implication table shown in FIG. 46 in place of these conditions.

### Eighth Embodiment

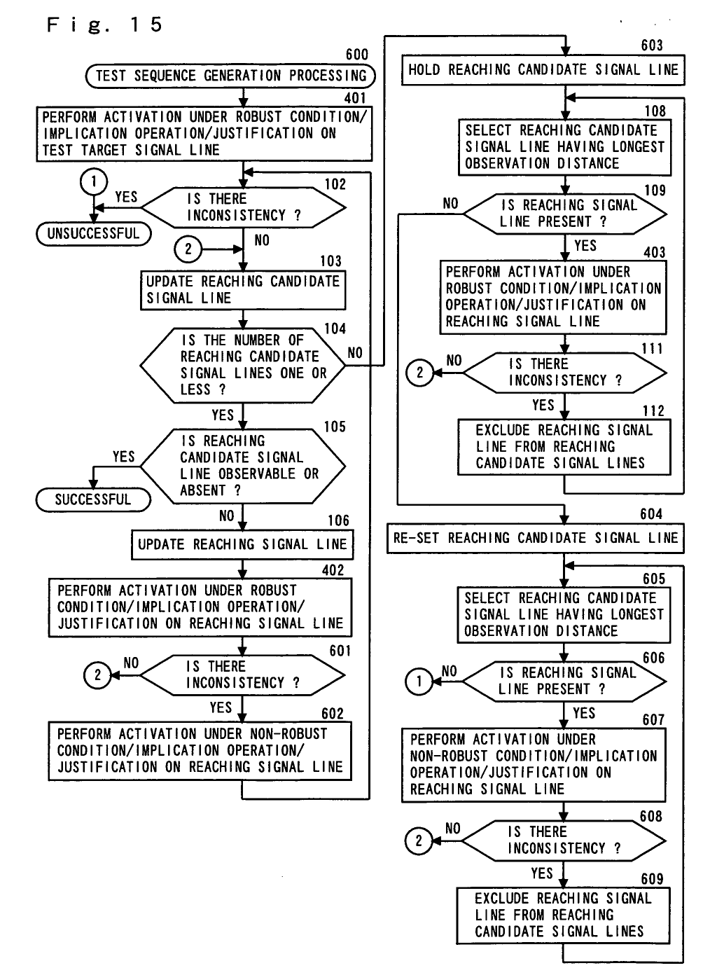

An eighth generation method is a modification of the first generation method (FIG. 4), where Step 100 is replaced by Step 800 (FIG. 18). Step 800 is a modification of Step 100, where Steps 801, 802, and 805-810 are added while Steps 109 and 111 are replaced by Steps 803 and 804. The eighth generation method is characterized in that when activation and justification have been unsuccessful for all reaching candidate signal lines at a particular branch point, the processing is returned (backtracked) to a branch point where selection has been performed immediately before.

The following steps appear for the first time in the eighth generation method. In the following steps, a transition path set and a non-reaching signal line are used. The initial values for these quantities are void (no element).

(Step 801) When inconsistency arises at Step 107, the apparatus goes to Step 805. Otherwise, the apparatus goes to Step 802.

(Step 802) The apparatus adds the reaching signal line at this time point, to the transition path set. After that, the apparatus goes to Step 103.

(Step 803) When a reaching signal line has been selected at Step 108, the apparatus goes to Step 110. Otherwise, the apparatus goes to Step 805.

(Step 804) When inconsistency arises at Step 110, the apparatus goes to Step 112. Otherwise, the apparatus goes to Step 802.

(Step 805) When the propagation path of the fault value is traced back from the reaching signal line, the apparatus acquires signal lines (each referred to as a propagation fail signal line, hereinafter) located between the reaching signal line and the first-appearing branch (including the signal lines at both ends), and then adds the propagation fail signal lines to non-reaching signal lines.

(Step 806) The apparatus restores into the original one the value of each signal line that has been assigned for the purpose of propagation of a fault value to the propagation fail signal line.

(Step 807) Among the input side signal lines of the propagation fail signal line, the apparatus sets up to be a reaching signal line a signal line included in the transition path set.

(Step 808) When there is a reaching signal line other than the test target signal line, the apparatus goes to Step 809. Otherwise, the apparatus goes to Step 11.

(Step 809) The apparatus acquires reaching candidate signal lines of the reaching signal line set up at Step 807. Then, when any reaching candidate signal line is not included in non-reaching signal lines, the apparatus goes to Step 810. Otherwise, the apparatus goes to Step 805.

(Step 810) The apparatus deletes the signal lines included in the non-reaching signal lines, from the reaching candidate signal lines. After that, the apparatus goes to Step 103.

The processing is described below for the case that the eighth generation method is applied to the test target circuit shown in FIG. 8. Here, a rise transition in the signal line s504 is adopted as a test target. {PI501, PI502, PI503, PI504, PI505, PI506, PI507, PI508} is denoted by {P}. In the following example, the apparatus performs activation according to the robust condition.

(Step 13) The apparatus sets up an initial value of 0 to the test target signal line s504.

(Step 14) In order to set up an initial value of 0 to the test target signal line s504, the apparatus sets up a value 0 to the control point PI502. The test sequence T1 is updated into {P}={X, 0, X, X, X, X, X, X}.

(Step 15) Since the generation of the test sequence T1 has been successful, the apparatus goes to Step 16.

(Step 16) The apparatus sets up a fault value ND to the test target signal line s504.

(Step 101) In order to set up a fault value ND to the test target signal line s504, the apparatus performs activation under the robust condition, implication operation, and justification. As a result, a value 1 is set up to the values of the signal line s502 and the control point PI502 in the test sequence T2. Further, a value U1 is set up to the signal line s503 and the control point PI503. The test sequence T2 is updated into {P}={X, 1, 1, X, X, X, X, X}.

(Step 102) Since no inconsistency arises at Step 101, the apparatus goes to Step 103.

(Steps 103-106) The apparatus sets up the signal line s504 (unobservable) to be a reaching candidate signal line, and then sets up the signal line s504 to be a reaching signal line.

(Step 107) In order to propagate the fault value ND of the reaching signal line s504 to the signal line s505, the apparatus performs activation under the robust condition, implication operation, and justification. As a result, a value S0 is set up to the signal line s510a and the control points PI504 and PI505, so that a fault value ND is propagated to the signal line s505. The test sequence T1 is updated into {P}={X, 0, X, 0, 0, X, X, X}, while the test sequence T2 is updated into {P}={X, 1, 1, 0, 0, X, X, X}.

(Step 801) Since no inconsistency arises at Step 107, the apparatus goes to Step 802.

(Step 802) The apparatus adds the reaching signal line s504 to the transition path set. After that, the apparatus goes to Step 103.

(Steps 103-106) The apparatus sets up the signal line s505 (unobservable) to be a reaching candidate signal line, and then sets up the signal line s505 to be a reaching signal line.

(Step 107) Since the reaching signal line s505 is a stem, the apparatus goes to Step 801 without performing activation, implication operation, and justification.

(Step 801) Since no inconsistency arises at Step 107, the apparatus goes to Step 802.

(Step 802) The apparatus adds the reaching signal line s505 to the transition path set. After that, the apparatus goes to Step 103.

(Steps 103-104) Since the signal line s505 is a stem, the apparatus sets up the signal lines s505a and s505b to be reaching candidate signal lines, and then goes to Step 108.

(Step 108) The apparatus acquires the longest observation distances of the reaching candidate signal lines s505a and s505b. When the observation distance is estimated in terms of the number of gate stages, the longest observation distance of the signal line s505a is 4, while the longest observation distance of the signal line s505b is 3. Thus, the apparatus selects as a reaching signal line the reaching candidate signal line s505a having the maximum longest observation distance.

(Step 803) Since a reaching signal line has been selected at Step 108, the apparatus goes to Step 110.

(Step 110) In order to propagate the fault value ND of the reaching signal line s505a to the signal line s506, the apparatus performs activation under the robust condition, implication operation, and justification. However, before this step is executed, a value S0 has been set up to the signal line s510, while a value S1 has been set up to the signal line s511. Thus, without the necessity of setting up new values to the signal lines, a fault value ND is propagated to the signal line s506.

(Step 804) Since no inconsistency arises at Step 110, the apparatus goes to Step 802.

(Step 802) The apparatus adds the reaching signal line s505a to the transition path set. After that, the apparatus goes to Step 103.

(Steps 103-106) The apparatus sets up the signal line s506 (unobservable) to be a reaching candidate signal line, and then sets up the signal line s506 to be a reaching signal line.

(Step 107) Since the reaching signal line s506 is a stem, the apparatus goes to Step 801 without performing activation, implication operation, and justification.

(Step 801) Since no inconsistency arises at Step 107, the apparatus goes to Step 802.

(Step 802) The apparatus adds the reaching signal line s506 to the transition path set. After that, the apparatus goes to Step 103.

(Steps 103-104) Since the signal line s506 is a stem, the apparatus sets up the signal lines s506a and s506b to be reaching candidate signal lines, and then goes to Step 108.

(Step 108) The apparatus acquires the longest observation distances of the reaching candidate signal lines s506a and s506b. When the observation distance is estimated in terms of the number of gate stages, the longest observation distance of the signal line s506a is 1, while the longest observation distance of the signal line s506b is 3. Thus, the apparatus selects as a reaching signal line the reaching candidate signal line s506b having the maximum longest observation distance.

(Step 803) Since a reaching signal line has been selected at Step 108, the apparatus goes to Step 110.

(Step 110) In order to propagate the fault value ND of the reaching signal line s506b to the signal line s513, the apparatus performs activation under the robust condition, implication operation, and justification. However, before this step is executed, a value S0 has been set up to the signal line s510c. Thus, without the necessity of setting up a new value to the signal line, a fault value ND is propagated to the signal line s513.

(Step 804) Since no inconsistency arises at Step 110, the apparatus goes to Step 802.

(Step 802) The apparatus adds the reaching signal line s506b to the transition path set. After that, the apparatus goes to Step 103.

(Steps 103-106) The apparatus sets up the signal line s513 (unobservable) to be a reaching candidate signal line, and then sets up the signal line s513 to be a reaching signal line.

(Step 107) In order to propagate the fault value ND of the reaching signal line s513 to the signal line s514, the apparatus performs activation under the robust condition, implication operation, and justification. Nevertheless, before this step is executed, a value S0 has been set up to the control point PI505 and the signal line s519a. Thus, when the apparatus sets up a value U1 to the signal line s519a in order to propagate the fault value ND of the signal line s513 to the signal line s514, inconsistency arises.

(Step 801) Since inconsistency has arisen at Step 107, the apparatus goes to Step 805.

(Step 805) At this time point, when the propagation path of the fault value is traced back from the reaching signal line s513, the signal line s513 and s506b are present between the reaching signal line s513 and the first-appearing branch s506b. Thus, the apparatus adds these propagation fail signal lines s513 and s506b to the non-reaching signal lines.

(Step 806) The apparatus restores, into the original one, the value of each signal line that has been set up for the purpose of propagation of a fault value to the propagation fail signal lines s513 and s506b. In this example, no signal line has been provided with a value for the purpose of propagation of the fault value to the fail signal lines s513 and s506b. Thus, no actual operation is performed at this step.

(Step 807) Among the input side signal lines of the propagation fail signal lines s513 and s506b, the apparatus sets up to be a reaching signal line the signal line s506 which is included in the transition path set.

(Step 808) Since there is a reaching signal line other than the test target signal line s504, the apparatus goes to Step 809.

(Step 809) The apparatus sets up to be reaching candidate signal lines the signal lines s506a and s506b connected to the output side of the reaching signal line s506. Among these, since the signal line s506a is not included in the non-reaching signal lines, the apparatus goes to Step 810.

(Step 810) The apparatus deletes the signal line s606b included in the non-reaching signal lines, from the reaching candidate signal lines. As a result, the signal line s606a is solely included in the reaching candidate signal line. After that, the apparatus goes to Step 103.

(Steps 103-106) The apparatus sets up the signal line s506a (unobservable) to be a reaching candidate signal line, and then sets up the signal line s506a to be a reaching signal line.

(Step 107) In order to propagate the fault value ND of the reaching signal line s506a to the signal line s507, the apparatus performs activation under the robust condition, implication operation, and justification. As a result, a value S0 is set up to the signal line s501 and the control point PI501. The test sequence T1 is updated into {P}={0, 0, X, 0, 0, X, X, X}, while the test sequence T2 is updated into {P}={0, 1, 1, 0, 0, X,

(Step 801) Since no inconsistency arises at Step 107, the apparatus goes to Step 802.

(Step 802) The apparatus adds the reaching signal line s506a to the transition path set. After that, the apparatus goes to Step 103.

(Step 103) The apparatus sets up the signal line s507 to be a reaching candidate signal line.

(Step 104) Since the number of reaching candidate signal lines is one, the apparatus goes to Step 105.

(Step 105) The reaching candidate signal line s507 is connected to the observation point PO501 and can be observed. Thus, the apparatus goes to Step 19.

As a result of the above-mentioned processing, {P}={0, 0, X, 0, 0, X, X, X} is generated as the test sequence T1, while {P}={0, 1, 1, 0, 0, X, X, X} is generated as the test sequence T2.

As described above, according to the eighth generation method, when the activation and the justification have been unsuccessful for all reaching candidate signal lines at a particular branch point, backtracking is performed to a branch point where selection has been performed immediately before. Thus, a test pattern can be generated that cannot be generated without backtracking.

### Ninth Embodiment

A ninth generation method is a modification of the third generation method (FIG. 11), where Step 300 is replaced by Step 900 (FIG. 19). Step 900 is a modification of Step 800 (FIG. 18), where Steps 103 and 809 are replaced by Steps 303 and 901, respectively. The ninth generation method is characterized in that backtracking is performed to the nearest branch point that satisfies a predetermined criterion.

The following steps appear for the first time in the ninth generation method.

(Step 901) The apparatus acquires reaching candidate signal lines of the reaching signal line set up at Step 807. Then, when a reaching candidate signal line is present that is not included in non-reaching signal lines and that satisfies a predetermined criterion, the apparatus goes to Step 810. Otherwise, the apparatus goes to Step 302. Here, when the length of the longest test path of a reaching candidate signal line is greater than or equal to the criterion value set up at Step 301, this situation is expressed as that the reaching candidate signal line satisfies the criterion.

The processing is described below for the case that the ninth generation method is applied to the test target circuit shown in FIG. 8. Here, a rise transition in the signal line s504 is adopted as a test target. (PI501, PI502, PI503, PI504, PI505, PI506, PI507, PI508} is denoted by {P}. In the following example, the apparatus performs activation according to the robust condition.

(Step 301) The apparatus sets up the criterion value of the signal line into 4.

(Step 302) In the test target circuit shown in FIG. 8, the paths extending from the test target signal line s504 to the observation points PO501, PO502, and PO503 include the branches s505a, s505b, s506a, and s506b. When the length of a path is estimated in terms of the number of gate stages, the longest distance from the test target signal line s504 to the stem s55 is 1, while the longest distance from the test target signal line s504 to the stem s506 is 2. Further, the longest distances from the branches s505a, 505b, 506a, and 506b to the three observation points are 4, 3, 1, and 3, respectively. Thus, the longest test path lengths of the branches s505a, s505b, s506a, and s506b are 5, 4, 3, and 5, respectively.

In the ninth generation method, branches having the longest test path length greater than or equal to the criterion value set up at Step 301 are solely treated as branches satisfying the criterion, and then set up to be reaching candidate signal lines. Thus, in this example, among the four branches described above, the branch s506a is not set up to be a reaching candidate signal line at Steps 303 and 901. The processing after Step 302 is executed under this condition. Thus, according to the ninth generation method, a test pattern different from that of the eighth generation method is generated as described below.

In the eighth generation method, the branches s505a, s505b, s506a, and s506b can be selected as a path for propagating the fault value. When propagating the fault value set up to the signal line s504, the apparatus first selects the branch s505a that has the longer length of the longest test path among the branches s505a and 505b. Then, the apparatus selects the branch s506b that has the longer length of the longest test path among the branches s506a and 506b. When the apparatus performs activation and justification in order to propagate the fault value to the gates that follow the branch s506b, inconsistency arises. Thus, the apparatus performs backtrack processing (Step 805-810), and thereby backtracks to the branch point where selection has been performed immediately before. After that, the apparatus propagates the fault value to the observation point PO501 via the branch s506a.

In contrast, in the ninth generation method, the branches s505a, s505b, and s506b can be selected as a path for propagating the fault value. However, the branch s506a cannot be selected as a path for propagating the fault value. When propagating the fault value set up to the signal line s504, the apparatus first selects the branch s505a that has the longer length of the longest test path among the branches s505a and 505b. Then, the apparatus selects the only selectable branch s506b. When the apparatus performs activation and justification in order to propagate the fault value to the gates that follow the branch s506b, inconsistency arises. Thus, the apparatus performs backtrack processing (Steps 805-808, 901, and 810). At that time, at Step 901 the apparatus selects the branch s505b to be a reaching candidate signal line that is not included in the non-reaching signal lines and that has the longest test path length greater than or equal to the criterion value 4. After that, the apparatus propagates the fault value to the observation point PO503 via the branch s505b.

In order to propagate the fault value ND of the reaching signal line s505 to the observation point PO503 via the branch s505b, the apparatus performs activation under the robust condition, implication operation, and justification. Here, these three processes are performed at each time that the fault value is propagated by one gate stage. As a result, values S0 and U1 are set up respectively to the signal lines s540 and s524, while a value S0 is set up to the control point PI507.

As a result of the above-mentioned processing, {P}={X, 0, X, 0, 0, X, 0, X} is generated as the test sequence T1, while {P}={0, 1, 1, 0, 0, X, 0, X} is generated as the test sequence T2.

As described above, according to the ninth generation method, return destinations in the backtracking are restricted so that the processing time is shortened.

### Tenth Embodiment

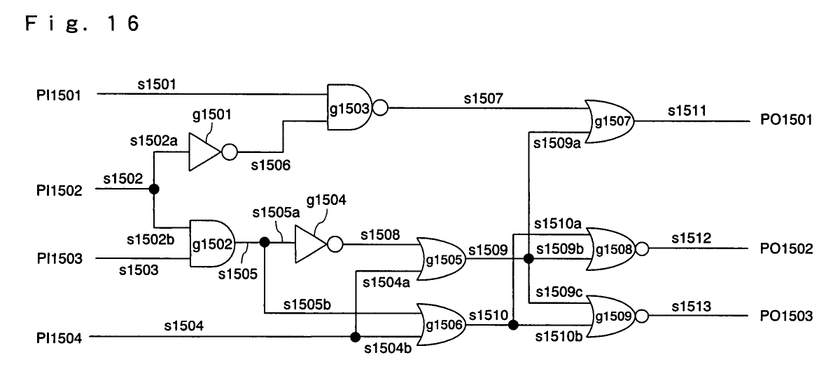

A tenth generation method is a modification of the third generation method (FIG. 11), where Step 300 is replaced by Step 1000 (FIG. 20). Step 1000 is a modification of Step 900 (FIG. 19), where Step 807 is replaced by Steps 1001 and 1002, while, where Step 901 is replaced by Steps 1003 and 1002, and while Step 810 is omitted. The tenth generation method is characterized in that backtracking is performed to a branch point that has the longest length of the longest test path including a not selected branch.

The following steps appear for the first time in the tenth generation method.

(Step 1001) For each branch on a path extending from the test target signal line selected at Step 11 to an arbitrary observation point, the apparatus calculates the longest test path length. Nevertheless, a path including a non-reaching signal line is not used in the calculation of the longest test path length.

(Step 1002) Among the stems included in the transition path set, the apparatus sets up to be a reaching signal line a stem that is connected to the branch having the maximum length of the longest test path calculated at Step 1001.

(Step 1003) Among the branches of the reaching signal line, when a branch has the maximum length of the longest test path and satisfies the predetermined criterion, the apparatus goes to Step 303. Otherwise, the apparatus goes to Step 805. Here, when the length of the longest test path of a reaching candidate signal line is greater than or equal to the criterion value set up at Step 301, this situation is expressed as that the reaching candidate signal line satisfies the criterion.

The processing is described below for the case that the tenth generation method is applied to the test target circuit shown in FIG. 8. Here, a rise transition in the signal line s504 is adopted as a test target. {PI501, PI502, PI503, PI504, PI505, PI506, PI507, PI508} is denoted by {P}. In the following example, activation is performed according to a robust condition, while the criterion value of the reaching signal line is set up into 4 at Step 301.

The tenth generation method is the same as the ninth generation method except for the backtrack processing. Thus, in the tenth generation method, paths that can be selected for propagating the fault value are limited to the branches s505a, s505b, and s506b similarly to the ninth generation method. When propagating the fault value set up to the signal line s504, the apparatus first selects the branch s505a that has the longer length of the longest test path among the branches s505a and 505b. Then, the apparatus selects the only selectable branch s506b. Then, when the apparatus performs activation and justification in order to propagate the fault value to the gates that follow the branch s506b, inconsistency arises. Here, the apparatus performs backtrack processing (Steps 805, 806, 808, and 1001-1003) different from that of the ninth generation method.

(Step 1001) At this time point, non-reaching signal lines include the signal lines s513 and s506b. Further, in the test target circuit shown in FIG. 8, the path extending from the test target signal line s504 to the observation points include the branches s505a, s505b, s506a, and s506b. Thus, for these four branches, the apparatus calculates the longest test path lengths with taking into account solely the paths that do not include the signal lines s513 and s506b. As a result, the longest test path lengths of the branches s505a, s505b, s506a, and s506b are 3, 4, 3, and 0, respectively.

(Step 1002) Among the stems included in the transition path set, the apparatus sets up to be a reaching signal line the branch s505 which is a stem connected to the branch having the maximum length of the longest test path calculated at Step 1001.

(Step 808) Since there is a reaching signal line other than the test target signal line s504, the apparatus goes to Step 1003.

(Step 1003) At the time point of execution of this step, the branch s505b has the maximum longest test path length among the branches s505a and 505b of the reaching signal line s505. Further, the longest test path length of the branch s505b is greater than or equal to the criterion value 4, and hence satisfies the criterion value. Thus, the apparatus goes to Step 103.

After that, the apparatus propagates the fault value to the observation point PO503 via the branch s505b. Thus, according to the tenth generation method, similarly to the ninth generation method, {P}={X, 0, X, 0, 0, X, 0, X} is generated as the test sequence T1, while {P}={0, 1, 1, 0, 0, X, 0, X} is generated as the test sequence T2.

As described above, according to the tenth generation method, return destinations in the backtracking are restricted so that a longer path is selected with priority. Thus, the influence of delay in the test target signal line can be detected using propagation along a longer path.

### Eleventh Embodiment

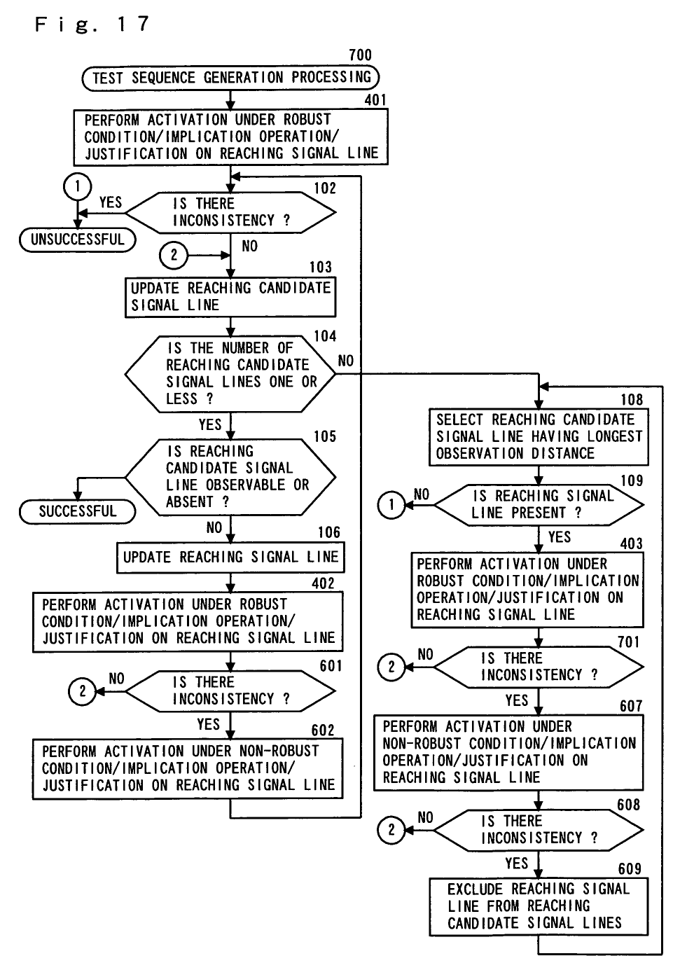

An eleventh generation method is a modification of the first generation method (FIG. 4), where Step 100 is replaced by Step 1100 (FIG. 21). Step 1100 is a modification of Step 800 (FIG. 18), where Step 806 is omitted. The eleventh generation method is characterized in that when backtracking is performed, the value of the control point is held intact that has been acquired for the purpose of propagation of the fault value to the propagation fail signal line.

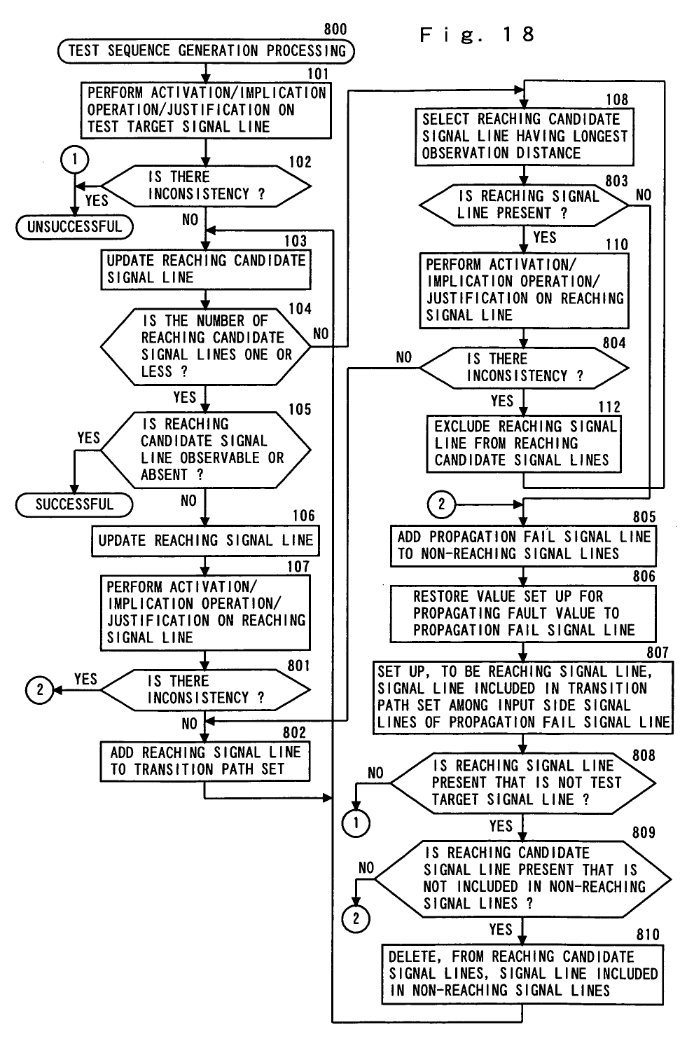

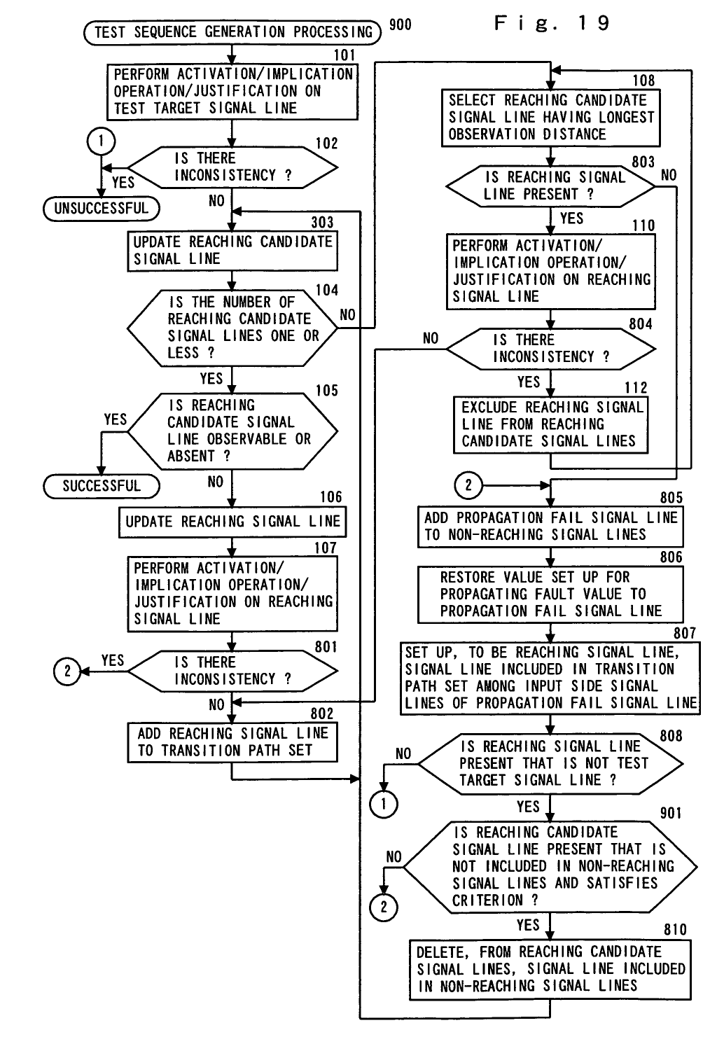

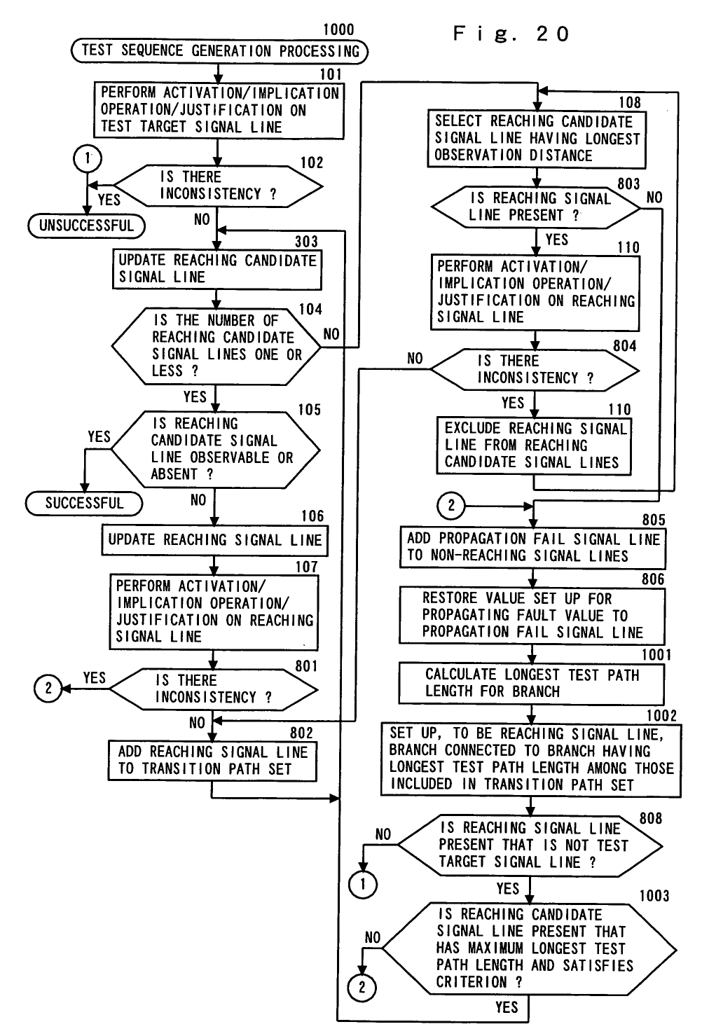

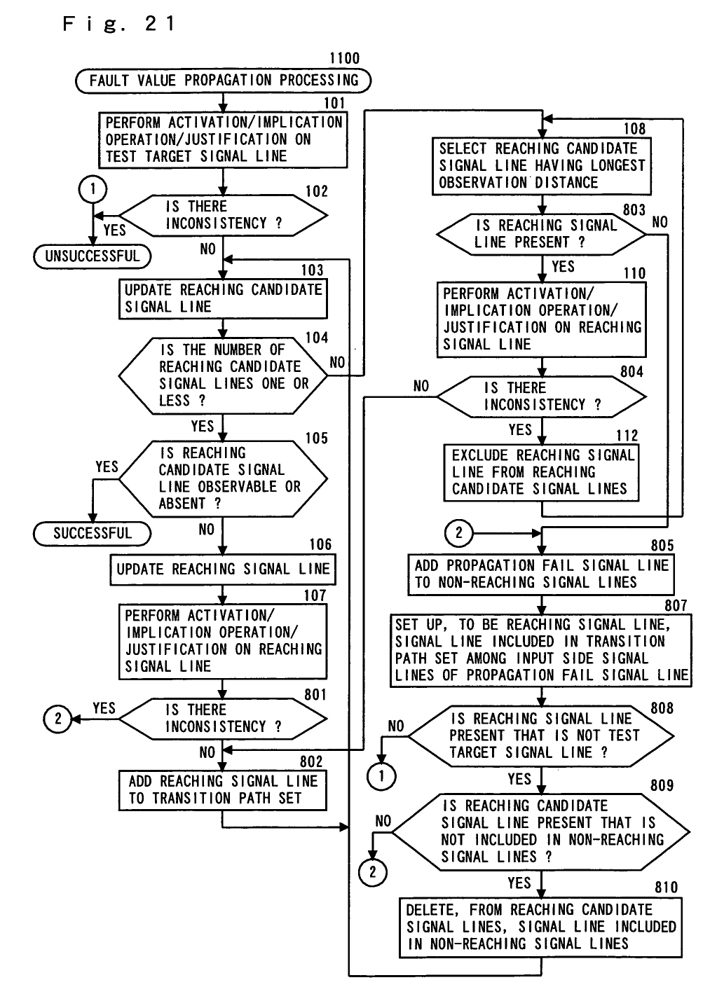

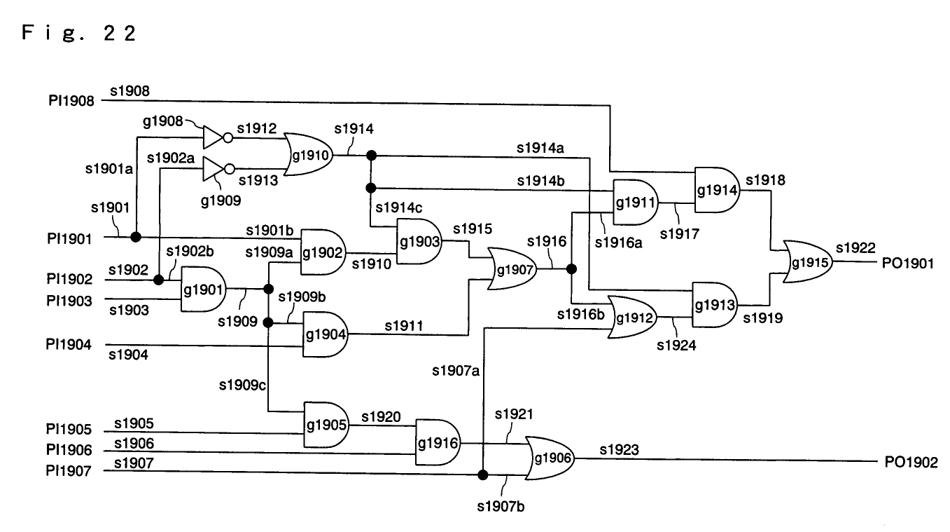

The processing is described below for the case that the eleventh generation method is applied to the test target circuit shown in FIG. 22. Here, a fall transition in the signal line s1903 is adopted as a test target. {PI1901, PI1902, PI1902, PI1903, PI1904, PI1905, PI1906, PI1907, PI1908} is denoted by {P}. In the following example, the apparatus performs activation according to the robust condition.

(Step 13) The apparatus sets up an initial value of 1 to the test target signal line s1903.

(Step 14) In order to set up an initial value of 1 to the test target signal line s1903, the apparatus sets up a value 1 to the control point PI1903. The test sequence T1 is updated into {P}={X, X, 1, X, X, X, X, X}.

(Step 15) Since the generation of the test sequence T1 has been successful, the apparatus goes to Step 16.

(Step 16) The apparatus sets up a fault value D to the test target signal line s1903.

(Step 101) In order to set up a fault value D to the test target signal line s1903, the apparatus performs activation under the robust condition, implication operation, and justification. As a result, the value of the control point PI1903 in the test sequence T2 is set up into 0. The test sequence T2 is updated into {P}={X, X, 0, X, X, X, X, X}.

(Step 102) Since no inconsistency arises at Step 101, the apparatus goes to Step 103.

(Steps 103-106) The apparatus sets up the signal line s1909 (unobservable) to be a reaching candidate signal line, and then sets up the signal line s1909 to be a reaching signal line.

(Step 107) In order to propagate the fault value D of the reaching signal line s1903 to the signal line s1909, the apparatus performs activation under the robust condition, implication operation, and justification. As a result, a value S1 is set up to the signal line s1902 and the control point PI1902. The test sequence T1 is updated into {P}={X, 1, 1, X, X, X, X, X}, while the test sequence T2 is updated into {P}={X, 1, 0, X, X, X, X, X}.

(Step 801) Since no inconsistency arises at Step 107, the apparatus goes to Step 802.

(Step 802) The apparatus adds the reaching signal line s1903 to the transition path set. After that, the apparatus goes to Step 103.

(Steps 103-104) Since the signal line s1909 is a stem, the apparatus sets up the signal lines s1909a, s1909b, and s1909c to be reaching candidate signal lines, and then goes to Step 108.

(Step 108) The apparatus acquires the longest observation distances of the reaching candidate signal lines s1909a, s1909b, and s1909c. When the observation distance is estimated in terms of the number of gate stages, the longest observation distance of the signal line s1909a is 6, while the longest observation distance of the signal line s1909b is 5, and while the longest observation distance of the signal line s1909c is 3. Thus, the apparatus selects as a reaching signal line the reaching candidate signal line s1909a having the maximum longest observation distance.

(Step 803) Since a reaching signal line has been selected at Step 108, the apparatus goes to Step 110.

(Step 110) In order to propagate the fault value D of the reaching signal line s1909a to the signal line s1910, the apparatus performs activation under the robust condition, implication operation, and justification. As a result, a value S1 is set up to the signal line s1901b and the control point PI1901, so that a fault value D is propagated to the signal line s1910. The test sequence T1 is updated into {P}={1, 1, 1, X, X, X, X, X}, while the test sequence T2 is updated into {P}={1, 1, 0, X, X, X, X, X}.

(Step 804) Since no inconsistency arises at Step 110, the apparatus goes to Step 802.

(Step 802) The apparatus adds the reaching signal line s1909a to the transition path set. After that, the apparatus goes to Step 103.

(Steps 103-106) The apparatus sets up the signal line s1910 (unobservable) to be a reaching candidate signal line, and then sets up the signal line s1910 to be a reaching signal line.

(Step 107) In order to propagate the fault value D of the reaching signal line s1910 to the signal line s1915, the apparatus performs activation under the robust condition, implication operation, and justification. Nevertheless, before this step is executed, a value S1 has been set up to the control points PI1901 and PI1902, while a value S0 has been set up to the signal line s1914c. Thus, when the apparatus sets up the value S1 to the signal line s1914c in order to propagate the fault value b of the reaching signal line s1910 to the signal line s1915, inconsistency arises.

(Step 810) Since inconsistency has arisen at Step 107, the apparatus goes to Step 805.

(Step 805) The apparatus adds the propagation fail signal lines s1910 and s1909a to the non-reaching signal lines.

(Step 807) Among the input side signal lines of the propagation fail signal lines s1910 and s1909a, the apparatus sets up to be a reaching signal line the signal line s1909a included in the transition path set.

(Step 808) Since there is a reaching signal line other than the test target signal line s1903, the apparatus goes to Step 809.

(Step 809) The apparatus sets up to be reaching candidate signal lines the signal lines s1909a, s1909b, and s1909c connected to the output side of the reaching signal line s1909. Among these, since the signal lines s1909b and s1909c are not included in the non-reaching signal lines, the apparatus goes to Step 810.

(Step 810) The apparatus deletes the signal line s1909a included in the non-reaching signal lines, from the reaching candidate signal lines. As a result, the signal lines s1909b and s1909c are included in the reaching candidate signal lines. After that, the apparatus goes to Step 103.

(Steps 103-104) Since the signal line s1909 is a stem, the apparatus sets up the signal lines s1909b and s1909c to be reaching candidate signal lines, and then goes to Step 108.

(Step 108) From among the reaching candidate signal lines s1909b and s1909c, the apparatus selects arbitrarily the reaching candidate signal line s1909b as a reaching signal line.

(Step 803) Since a reaching signal line has been selected at Step 109, the apparatus goes to Step 110.

(Step 110) In order to propagate the fault value D of the reaching signal line s1909b to the signal line s1911, the apparatus performs activation under the robust condition, implication operation, and justification. As a result, a value S1 is set up to the signal line s1904 and the control point PI1904, so that a fault value D is propagated to the signal line s1911. The test sequence T1 is updated into {P}={1, 1, 1, 1, X, X, X, X}, while the test sequence T2 is updated into {P}={1, 1, 0, 1, X, X, X, X}.

(Step 804) Since no inconsistency arises at Step 110, the apparatus goes to Step 802.

(Step 802) The apparatus adds the reaching signal line s1909b to the transition path set. After that, the apparatus goes to Step 103.

(Steps 103-106) The apparatus sets up the signal line s1911 (unobservable) to be a reaching candidate signal line, and then sets up the signal line s1911 to be a reaching signal line.

(Step 107) In order to propagate the fault value D of the reaching signal line s1911 to the signal line s1916, the apparatus performs activation under the robust condition, implication operation, and justification. However, before this step is executed, a value S1 has been set up to the control points PI1901 and PI1902, while a value S0 has been set up to the signal line s1915. Thus, without the necessity of setting up new values to the signal lines, a fault value D is propagated to the signal line s1916.

(Step 801) Since no inconsistency arises at Step 107, the apparatus goes to Step 802.

(Step 802) The apparatus adds the reaching signal line s1911 to the transition path set. After that, the apparatus goes to Step 103.

(Steps 103-106) The apparatus sets up the signal line s1916 (unobservable) to be a reaching candidate signal line, and then sets up the signal line s1916 to be a reaching signal line.

(Step 107) Since the reaching signal line s1916 is a stem, the apparatus goes to Step 801 without performing activation, implication operation, and justification.

(Step 801) Since no inconsistency arises at Step 107, the apparatus goes to Step 802.

(Step 802) The apparatus adds the reaching signal line s1916 to the transition path set. After that, the apparatus goes to Step 103.

(Steps 103-104) Since the signal line s1916 is a stem, the apparatus sets up the signal lines s1916a and s1916b to be reaching candidate signal lines, and then goes to Step 108.

(Step 108) The apparatus acquires the longest observation distances of the reaching candidate signal lines s1916a and s1916b. When the observation distance is estimated in terms of the number of gate stages, the longest observation distance of each of these two reaching candidate signal lines is 3. Thus, Among these, the apparatus selects arbitrarily the reaching candidate signal line s1916a as a reaching signal line.

(Step 803) Since a reaching signal line has been selected at Step 108, the apparatus goes to Step 110.

(Step 110) In order to propagate the fault value D of the reaching signal line s1916a to the signal line s1917, the apparatus performs activation under the robust condition, implication operation, and justification. Nevertheless, before this step is executed, a value S0 has been set up to the control points PI1901 and PI1902, while a value S0 has been set up to the signal line s1914b. Thus, when the apparatus sets up the value S1 to the signal line s1914b in order to propagate the fault value D of the reaching signal line s1916a to the signal line s1917, inconsistency arises.

(Step 804) Since inconsistency has arisen at Step 110, the apparatus goes to Step 112.

(Step 112) The apparatus excludes the reaching signal line s1916a from the reaching candidate signal lines. As a result, the signal line s1916b is solely included in the reaching candidate signal line.

(Step 108) The apparatus selects s1916b which is the only reaching candidate signal line

(Step 803) Since a reaching signal line has been selected at Step 108, the apparatus goes to Step 110.

(Step 110) In order to propagate the fault value D of the reaching signal line s1916b to the signal line s1924, the apparatus performs activation, implication operation, and justification. Nevertheless, before this step is executed, a value S0 has been set up to the control points PI1901 and PI1902, while a value S0 has been set up to the signal line s1916a. Thus, when the apparatus sets up the value S1 to the signal line s1914a in order to propagate the fault value D of the reaching signal line s1916b to the signal line s1924, inconsistency arises.

(Step 804) Since inconsistency has arisen at Step 110, the apparatus goes to Step 112.

(Step 112) The apparatus excludes the reaching signal line s1916b from the reaching candidate signal lines. As a result, no signal line is included as the reaching candidate signal line.

(Step 108) Since no reaching candidate signal line is present, the apparatus does not select any reaching candidate signal line as a reaching signal line.

(Step 803) Since no reaching signal line is present, the apparatus goes to Step 805.

(Step 805) The apparatus adds the propagation fail signal line s1911 to the non-reaching signal lines.

(Step 807) Among the input side signal lines of the propagation fail signal line s1911, the apparatus sets up to be a reaching signal line the signal line s1909 included in the transition path set.

(Step 808) Since there is a reaching signal line other than the test target signal line s1903, the apparatus goes to Step 809.

(Step 809) The apparatus sets up to be reaching candidate signal lines the signal lines s1909a, s1909b, and s1909c connected to the output side of the reaching signal line s1909. Among these, since the signal line s1909c is not included in the non-reaching signal lines, the apparatus goes to Step 810.

(Step 810) The apparatus deletes the signal lines s1909a and s1909b included in the non-reaching signal lines, from the reaching candidate signal lines. As a result, the signal line s1909c is solely included in the reaching candidate signal line. After that, the apparatus goes to Step 103.

(Steps 103-106) The apparatus sets up the signal line s1909c to be a reaching candidate signal line, and then sets up the signal line s1909c to be a reaching signal line.

(Step 107) In order to propagate the fault value D of the reaching signal line s1909c to the signal line s1920, the apparatus performs activation under the robust condition, implication operation, and justification. As a result, a value S1 is set up to the signal line s1905 and the control point PI1905, so that a fault value D is propagated to the signal line s1920. The test sequence T1 is updated into {P}={1, 1, 1, 1, 1, X, X, X}, while the test sequence T2 is updated into {P}={1, 1, 0, 1, 1, X, X, X}.

(Step 801) Since no inconsistency arises at Step 107, the apparatus goes to Step 802.

(Step 802) The apparatus adds the reaching signal line s1909c to the transition path set. After that, the apparatus goes to Step 103.

(Steps 103-106) The apparatus sets up the signal line s1921 to be a reaching candidate signal line, and then sets up the signal line s1921 to be a reaching signal line.

(Step 107) In order to propagate the fault value D of the reaching signal line s1920 to the signal line s1921, the apparatus performs activation under the robust condition, implication operation, and justification. As a result, a value S1 is set up to the signal line s1906 and the control point PI1906, so that a fault value D is propagated to the signal line s1921. The test sequence T1 is updated into {P}={1, 1, 1, 1, 1, 1, X, X}, while the test sequence T2 is updated into {P}={1, 1, 0, 1, 1, 1, X, X}.

(Step 801) Since no inconsistency arises at Step 107, the apparatus goes to Step 802.

(Step 802) The apparatus adds the reaching signal line s1920 to the transition path set. After that, the apparatus goes to Step 103.

(Steps 103-106) The apparatus sets up the signal line s1921 to be a reaching candidate signal line, and then sets up the signal line s1921 to be a reaching signal line.

(Step 107) In order to propagate the fault value D of the reaching signal line s1921 to the signal line s1923, the apparatus performs activation under the robust condition, implication operation, and justification. As a result, a value U0 is set up to the signal line s1907 and the control point PI1907, so that a fault value D is propagated to the signal line s1921. The test sequence T1 is updated into {P}={1, 1, 1, 1, 1, 1, X, X}, while the test sequence T2 is updated into {P}={1, 1, 0, 1, 1, 1, 0, X}.

(Step 801) Since no inconsistency arises at Step 107, the apparatus goes to Step 802.

(Step 802) The apparatus adds the reaching signal line s1921 to the transition path set. After that, the apparatus goes to Step 103.

(Step 103) The apparatus sets up the signal line s1923 to be a reaching candidate signal line.

(Step 104) Since the number of reaching candidate signal lines is one, the apparatus goes to Step 105.

(Step 105) The reaching candidate signal line s1923 is connected to the observation point PO1902 and can be observed. Thus, the apparatus goes to Step 19.

As a result of the above-mentioned processing, {P}={1, 1, 1, 1, 1, 1, X, X} is generated as the test sequence T1, while {P}={1, 1, 0, 1, 1, 1, 0, X} is generated as the test sequence T2.

Here, a test pattern generation method different from the eleventh generation method is considered in which when backtracking is performed, the value of the control point acquired for the purpose of propagation of the fault value to the propagation fail signal line is restored into the original one. In the case that this method is applied to the test target circuit shown in FIG. 22, when activation is performed for propagating the fault value to the outputs of the gates g1911 and g1913, the value of the signal line s1901 need be acquired repeatedly that has already been acquired when the fault value is propagated to the output of the gate g1902. This increases the processing time.

As described above, according to the eleventh generation method, when backtracking is performed, the value of the control point is held intact that has been acquired at the time of propagation of the fault value to the propagation fail signal line. This avoids the necessity of holding the value assigned to the signal line when the fault value is propagated. Thus, the processing time is shortened while the memory utilization is reduced.

In the eighth through the eleventh embodiments, the apparatus has performed backtracking by one gate stage at Steps 805-808. Instead, backtracking may be performed to a stem connected to a plurality of reaching candidate signal lines in a single process. In this case, branches included in the transition path set are set up to be non-reaching signal lines. Further, in the description given above, the apparatus has performed activation according to a robust condition. Instead, the apparatus may perform activation according to a non-robust condition or alternatively using the path activation table shown in FIG. 46.

### Twelfth Embodiment

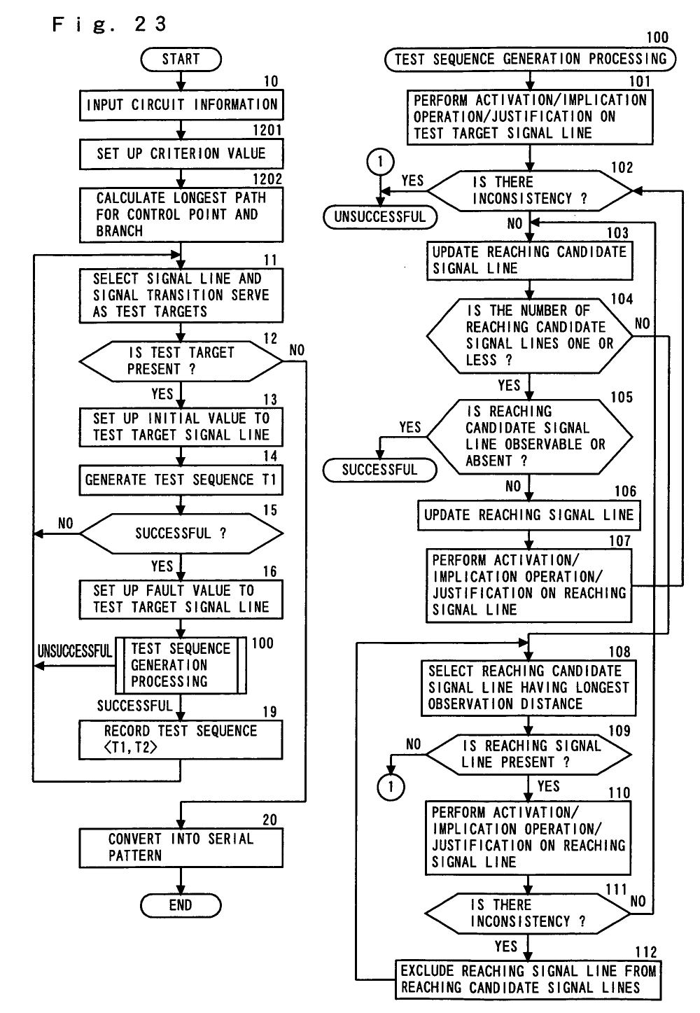

FIG. 23 is a flow chart showing a twelfth generation method. The twelfth generation method is a method where Steps 1201 and 1202 are added to the first generation method. The twelfth generation method is characterized in that processing is performed in a state that control points and signal lines which do not satisfy a predetermined criterion are excluded.

The following steps appear for the first time in the twelfth generation method.

(Step 1201) The apparatus sets up a criterion value for the control points and the signal lines. This criterion value may be inputted manually or alternatively using a computer.

(Step 1202) The apparatus acquires the longest test path length for each of the control points and the branches included in the test target circuit.

In the twelfth generation method, when the longest test path length of a control point is shorter than the criterion value set up at Step 1201, the apparatus excludes the control point from the test target signal line. That is, such a control point is not selected at Step 11. Further, when the longest test path length of a branch is shorter than the criterion value set up at Step 1201, the apparatus excludes the branch from the test target signal line, and excludes the branch from the candidate of signal line selection in the selection of the signal line. That is, this branch is not selected at Step 11, and not selected as a reaching signal line at Step 108.

The processing is described below for the case that the twelfth generation method is applied to the test target circuit shown in FIG. 5. Here, a rise transition in the signal line s9 is adopted as a test target. {PI1, PI2, PI3, PI4, PI5, PI6, PI7} is denoted by {P}.

(Step 1201) The apparatus sets up into 4 the criterion value for the control points and the signal lines.

(Step 1202) The test target circuit shown in FIG. 5 includes control points PI1, PI2, PI3, PI4, PI5, PI6, and PI7 and branches s5a, s5b, s5c, s6a, s6b, s10a, and s10b. The apparatus acquires the longest test path lengths for these control points and branches. As a result, the longest test path lengths of the control points PI1, PI2, PI3, PI4, PI5, PI6, and PI7 are 3, 4, 3, 4, 2, 3, and 1, respectively. The longest test path lengths of the branches s5a, s5b, s5c, s6a, s6b, s10a, and s10b are 3, 4, 3, 2, 3, 4, and 3, respectively.

In the processing after Step 1201, control points and branches having the longest test path length shorter than the criterion value 4 specified at Step 1201 are excluded from the processing targets. Specifically, at Step 11, among the seven control points, the control points PI2 and PI4 are solely selected as test targets, while among the seven branches, the branches s5b and s10b are solely selected as test targets. Further, at Step 103 among the branches s5a, s5b, and s5c, the branch s5b is solely set up to be a reaching candidate signal line, while among the branches s10a and s10b, the branch s10a is solely set up to be a reaching candidate signal line. Further, among the branches s6a and s6b, none is set up to be a reaching candidate signal line.

In this example, the branch s10a selected in the first generation method is treated as a reaching candidate signal line also in the twelfth generation method. Thus, in this example, the same test pattern as that of the first generation method is generated according to the twelfth generation method. That is, according to the twelfth generation method, {P}={X, X, X, 0, X, X, X} is generated as the test sequence T1, while {P}={0, 1, 0, 1, 0, X, X} is generated as the test sequence T2. However, in general, control points and signal lines that do not satisfy the predetermined criterion are excluded from processing targets in the twelfth generation method. Thus, a test pattern is generated that is different from that of the first generation method.

Before executing Step 1202, the apparatus may execute Step 201 (FIG. 7). When Step 201 is executed for the test target circuit shown in FIG. 8, an edge graph shown in FIG. 9 is obtained. When control points and signal lines having the longest test path length shorter than the criterion value 4 are excluded from the processing targets, the edge graph shown in FIG. 9 is simplified further (see FIG. 24). In this case, when Step 1202 is executed only for the groups indicated by solid lines in FIG. 24, the processing speed is improved.

As described above, according to the twelfth generation method, processing is performed in a state that control points and signal lines which do not satisfy a predetermined criterion are excluded, so that the processing time is shortened while the memory utilization is reduced.

### Thirteenth Embodiment

FIG. 25 is a flow chart showing a thirteenth generation method. The thirteenth generation method is a method where Steps 1301 and 1302 are added to the first generation method. The thirteenth generation method is characterized in that processing is performed in a state that specified signal lines are excluded.

The following steps appear for the first time in the thirteenth generation method.

(Step 1301) Information that specifies control points, signal lines, and observation points included in the test target circuit is inputted as non-target signal line information to the apparatus. This non-target signal line information may be inputted together with the circuit information at Step 10.

(Step 1302) On the basis of the non-target signal line information inputted at Step 1301, the apparatus determines signal lines to be excluded from the processing targets.

In the thirteenth generation method, when a control point is included in the non-target signal line information, a signal line that constitutes a path extending from the control point to a branch point that can be reached without going via a branch point is excluded from the processing target. When a signal line is included in the non-target signal line information, a signal line that constitutes a path extending from the signal line to an arbitrary observation point is excluded from the processing target. When an observation point is included in the non-target signal line information, a signal line that is included solely in a path that leads to the observation point is excluded from the processing target.

The processing is described below for the case that the thirteenth generation method is applied to the test target circuit shown in FIG. 5. Here, a rise transition in the signal line s9 is adopted as a test target. {PI1, PI2, PI3, PI4, PI5, PI6, PI7} is denoted by {P}.

(Step 1301) Non-target signal line information that specifies the observation point PO2 is inputted to the apparatus.

(Step 1302) The test target circuit shown in FIG. 5 includes the signal lines s5c, s10b, s12, s13, s14, s15, and s16 as signal lines that constitute solely a path that leads to the observation point PO2. The apparatus excludes these signal lines from the processing targets. Thus, even when Step 103 is executed later, the signal line s10b is not set up to be a reaching candidate signal line.

In this example, the branch s10a selected in the first generation method is treated as a reaching candidate signal line also in the thirteenth generation method. Thus, in this example, the same test pattern as that of the first generation method is generated according to the thirteenth generation method. That is, according to the thirteenth generation method, {P}={X, X, X, 0, X, X, X} is generated as the test sequence T1, while {P}={0, 1, 0, 1, 0, X, X} is generated as the test sequence T2. However, in general, control points and signal lines that do not satisfy the predetermined criterion are excluded from processing targets in the thirteenth generation method. Thus, a test pattern is generated that is different from that of the first generation method.

As described above, according to the thirteenth generation method, processing is performed in a state that specified signal lines are excluded, so that the processing time is shortened while the memory utilization is reduced. For example, when a multi-cycle pass and a false pass included in the test target circuit are specified, the effect is improved further.

In the description given above, non-target signal line information has been inputted from the outside to the apparatus. Instead, the apparatus itself may generate automatically the non-target signal line information on the basis of the results of static timing analysis and delay value calculation for the test target circuit.

In the first through the thirteenth embodiments, a test pattern has been generated for a combined circuit located between an external input terminal and a scan FF, a combined circuit between scan FFs, and a combined circuit located between a scan FF and an external output terminal. Instead, by taking into consideration the state of the test target circuit of the preceding test cycle, the apparatus may generate the test sequences T1 and T2 simultaneously. In this case, Steps 13-16 shown in FIG. 4 may be executed in the test sequence generation processing.

In each test pattern generation method according to fourteenth through sixteenth embodiments of the present invention, among one or more paths that can propagate a signal transition from a control point (where a signal is inputted) to a test target signal line, a path is selected that has the longer distance from the test target signal line to the control point. In the following description, test pattern generation methods according to the fourteenth through the sixteenth embodiments are referred to as fourteenth through sixteenth generation methods, respectively.

FIG. 26 is a diagram showing values used in a test pattern generation method according to fourteenth through nineteenth embodiments of the present invention. A logical value 1U shown in FIG. 26 indicates that the value of a signal line is 1 in the test sequence T1, and X (0 or 1) in the test sequence T2. A logical value 0U indicates that the value of a signal line is 0 in the test sequence T1, and X in the test sequence T2. A logical value 10 indicates that the value of a signal line is 1 in the test sequence T1, and 0 in the test sequence T2. A logical value 01 indicates that the value of a signal line is 0 in the test sequence T1, and 1 in the test sequence T2.

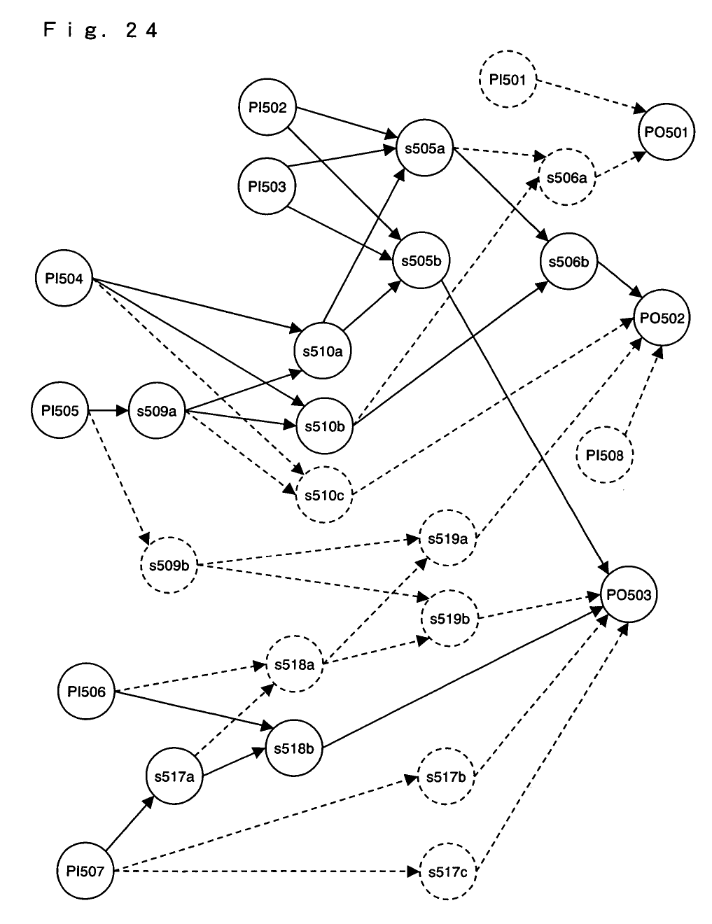

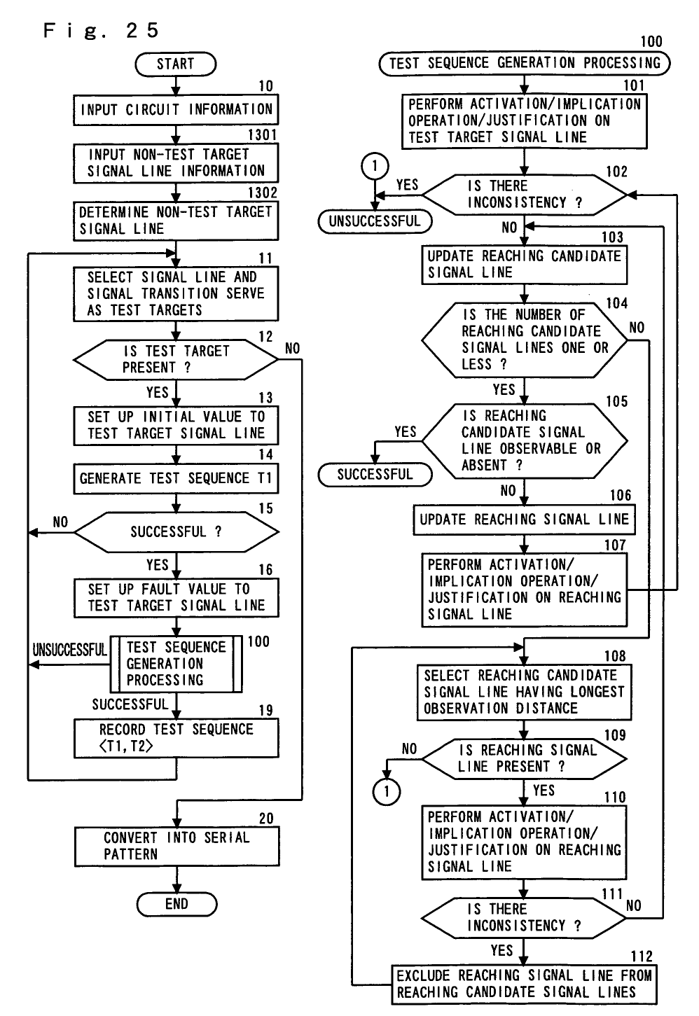

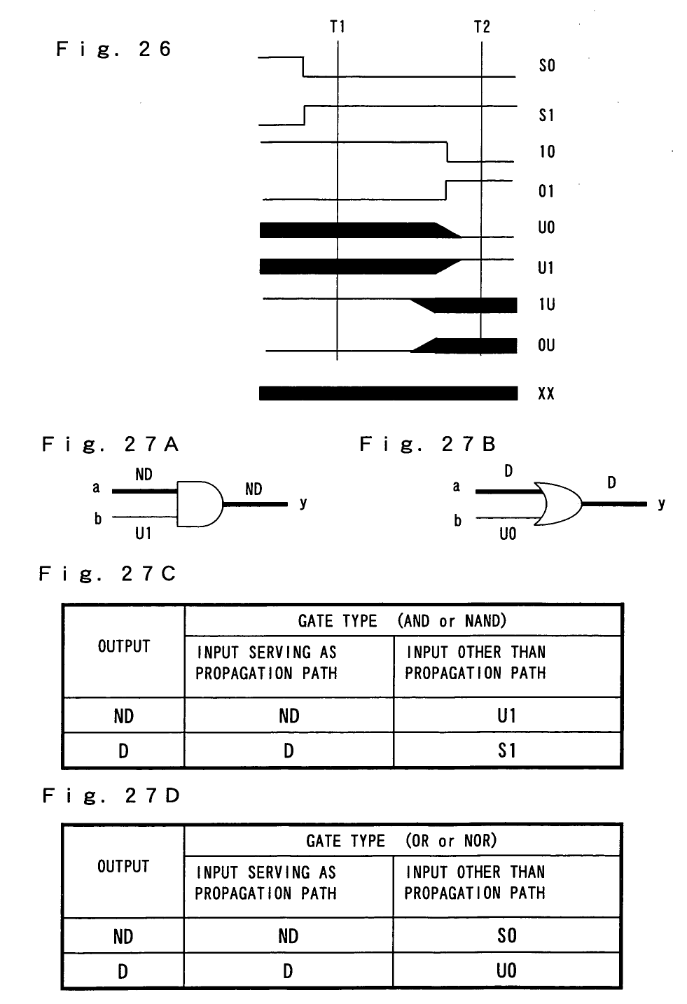

Here, described below is a condition to be set up to the input of a gate in order that a signal transition set up in advance should be propagated to the gate. For example, in an AND gate, the condition for ensuring that a rise transition ND should be propagated to an output y is that a rise transition ND is provided to an input “a” while a value U1 is provided to an input b (see FIG. 27A). Further, in an OR gate, the condition for ensuring that a fall transition D should be propagated to an output y is that a fall transition D is provided to an input “a” while a value U0 is provided to an input b (see FIG. 27B).

FIG. 27C shows the activation condition for the AND gate and the NAND gate. More specifically, this figure shows a value to be provided to the input other than the propagation path, for each combination between a signal transition set up to the output and a value to be provided to the input serving as the propagation path of the signal in an AND gate and a NAND gate. Further, FIG. 27D shows a value to be provided to the input other than the propagation path, for each combination between a signal transition set up to the output and a value to be provided to the input serving as the propagation path of the signal in an OR gate and a NOR gate. Alternatively, in place of FIGS. 27C and 27D, the activation condition shown in FIGS. 28A and 28B may be employed.

### Fourteenth Embodiment

FIG. 29 is a flow chart showing a fourteenth generation method of the present invention. In the fourteenth generation method, the following processing is executed.

(Step 2100) Information concerning storage elements and logic elements (gates) that constitute the test target circuit as well as concerning wiring between these elements is inputted as circuit information to the apparatus. In addition, information for specifying a signal line serving as a test target is inputted to the apparatus. Here, the information for specifying a signal line serving as a test target may be inputted manually or alternatively using a computer.

(Step 2101) The apparatus selects a signal line serving as a test target and a signal transition serving as a test target. At Step 2001, signal lines where a test pattern has already been generated and signal lines where a test pattern has already been determined as not capable of being generated are excluded from the targets of selection. Here, the signal line and the signal transition serving as test targets may be selected manually, or alternatively may be selected automatically by a computer on the basis of circuit information.

(Step 2102) When a signal line and a signal transition serving as test targets have been selected at Step 2101, the apparatus goes to Step 2103. Otherwise, the apparatus goes to Step 2117.

(Step 2103) The apparatus sets up a fault value (ND for a rise transition and D for a fall transition) corresponding to the signal transition selected at Step 2101, to the test target signal line selected at Step 2101.

(Step 2400) The apparatus performs test sequence generation processing described later, and thereby generates a test sequence <T1,T2>.

(Step 2115) When the generation of the test sequence <T1,T2> has been successful in the test sequence generation processing, the apparatus goes to Step 2116. Otherwise, the apparatus goes to Step 2101.

(Step 2116) The apparatus records the test sequence <T1,T2> generated at Step 2400, temporarily into the inside or into a file. Further, when a signal line where test pattern generation has already been determined as being impossible is present, the apparatus may check whether the signal line can be tested using the generated test sequence <T1,T2>. Then, the apparatus goes to Step 2101. As such, Steps 2101-2116 are executed for all combinations of the signal lines and the signal transitions serving as test targets.

(Step 2117) The apparatus converts into a serial pattern the test sequence <T1,T2> recorded at Step 2116, and then terminates the processing.

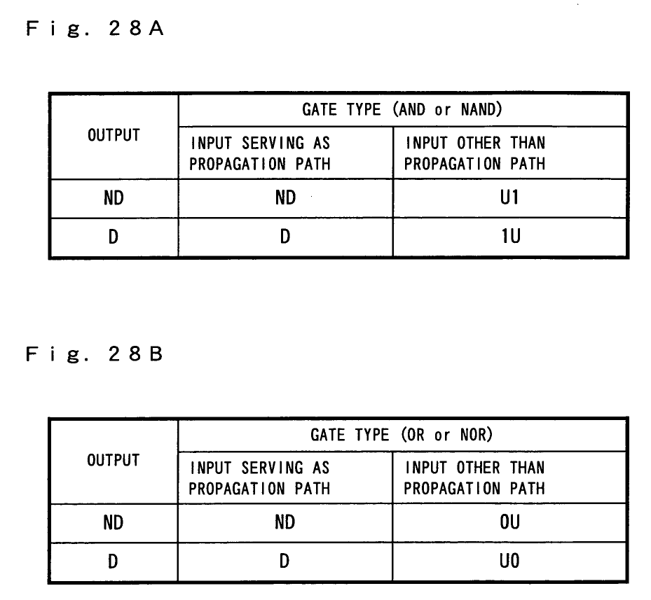

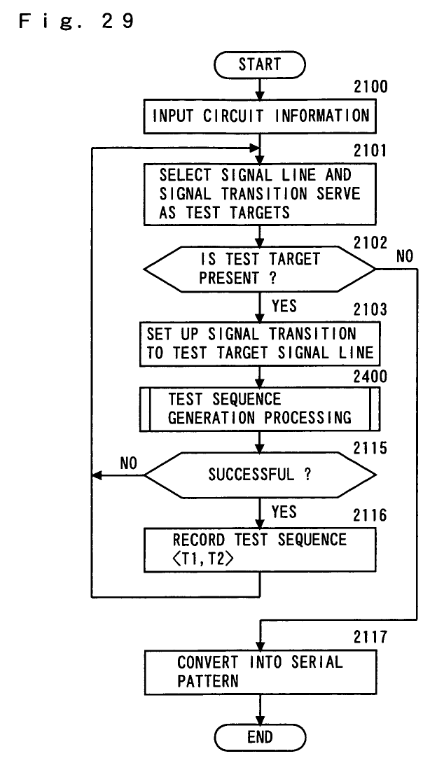

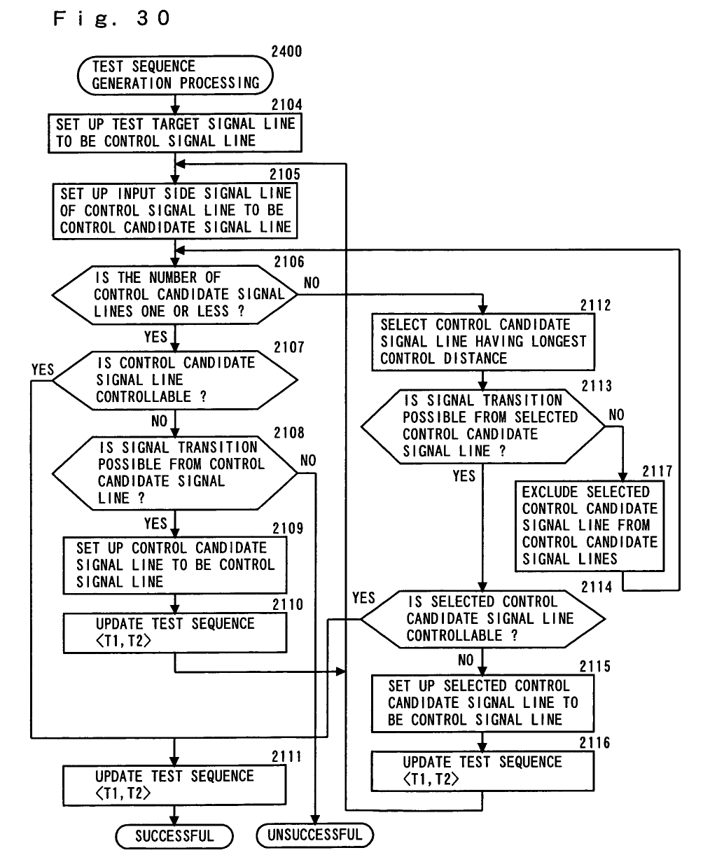

FIG. 30 is a flow chart showing details of test sequence generation processing shown in FIG. 29. At Step 2400, the following processing is executed. In the following description, a signal line in which a signal transition has been determined most recently is referred to as a “control signal line”. Further, a signal line which is connected to the input side of the control signal line and in which a signal transition could be determined next is referred to as a “control candidate signal line”.

(Step 2104) The apparatus sets up the test target signal line to be a control signal line.

(Step 2105) The apparatus sets up to be a control candidate signal line a signal line that can propagate a signal to the control signal line, that is, an input signal line of the gate connected to the input end of the control signal line.

(Step 2106) When the number of control candidate signal lines is one or less (that is, zero or one), the apparatus goes to Step 2107. Otherwise, the apparatus goes to Step 2111.

(Step 2107) When the control candidate signal line is controllable, the apparatus goes to Step 2111. Otherwise, the apparatus goes to Step 2108.

(Step 2108) The apparatus determines whether a signal transition can be performed from the control candidate signal line to the control signal line. When a signal transition can be performed, the apparatus goes to Step 2108. Otherwise, the apparatus determines as being pattern generation fail, and then terminates the processing.

(Step 2109) The apparatus sets up the control candidate signal line to be a new control signal line, and then goes to Step 2110.

(Step 2010) The apparatus updates the test sequence <T1,T2> and then goes to Step 2105.

(Step 2111) The apparatus reaches Step 2110 from Step 2107 when the control candidate signal line is connected to a controllable control point. The apparatus updates the test sequence <T1,T2> to be inputted to the control point where the control candidate signal line is connected. Then, the apparatus goes to Step 2101 (FIG. 29).

(Step 2112) The apparatus reaches this step from Step 2106 only when two or more control candidate signal lines (inputs of a gate) are present. For each control candidate signal line, the apparatus acquires the lengths of paths (control distance) from the control candidate signal line to one or more control points. Further, for each control candidate signal line, the apparatus acquires the maximum value of the acquired one or more control distances, as the longest control distance of each control candidate signal line. Similarly to the observation distance described above, the control distance is calculated on the basis of any one of the delay value table (FIG. 2), the via hole table (FIG. 3), and the number of gates connected between the control candidate signal line and the control point, or alternatively on the basis of a combination of these. Then, the apparatus selects a control candidate signal line having the maximum longest control distance among the control candidate signal lines.

(Step 2113) When it is determined that the signal transition can be propagated from the control candidate signal line selected at Step 2112 to the control signal line, the apparatus goes to Step 2114. Otherwise, the apparatus goes to Step 2117.

(Step 2114) The apparatus determines whether the control candidate signal line having been determined at Step 2112 as being capable of performing signal transition to the control signal line is controllable. When the control candidate signal line capable of performing signal transition is controllable, the apparatus goes to Step 2111. Otherwise, the apparatus goes to Step 2115.

(Step 2115) The apparatus sets up the selected control candidate signal line to be a new control signal line, and then goes to Step 2116.

(Step 2116) The apparatus updates the test sequence <T1,T2> and then goes to Step 2105.

(Step 2117) The apparatus excludes the selected control candidate signal line from the control candidate signal lines of the control signal line, and then goes to Step 2106. The processing of Step 2117 is performed in order to avoid that a signal line that cannot propagate a signal transition to the control signal line is selected again.

The processing is described below for the case that the fourteenth generation method is applied to the test target circuit shown in FIG. 31. Here, a transition in the signal line s3 is adopted as a test target. {PI1, PI2, PI3, PI4, PI5, PI6, PI7} is denoted by {P}. In the initial state, both of the test sequences T1 and T2 are set up to be {P}={X, X, X, X, X, X, X}. Further, it is assumed that the control distance is calculated at Step 2111 on the basis of the number of gates included in the path.

(Step 2103) The apparatus sets up a signal transition ND to the test target signal line s3.

(Step 2104) The apparatus sets up the test target signal line s3 to be a control signal line.

(Step 2105) The apparatus sets up the signal lines s2 and s6a to be control candidate signal lines.

(Step 2106) Since the number of control candidate signal lines is two, the apparatus goes to Step 2112.

(Step 2112) The apparatus calculates the longest control distance for each of the control candidate signal lines s2 and s6a. Specifically, in the test target circuit shown in FIG. 31, the signal line s2 is connected to control points PI1 and PI2. Each of the path extending from the control candidate signal line s2 to the control point PI1 and the path extending from the control candidate signal line s2 to the control point PI2 includes a single gate g1. Thus, when the distance from a control candidate signal line to a control point is estimated in terms of the number of gates, the longest control distance from the control candidate signal line s2 to the control point is 1. On the other hand, the control candidate signal line s6a is connected to the control point PI3. Then, the path extending from the control candidate signal line s6a to the control point PI3 does not include a gate. Thus, the longest control distance of the control candidate signal line s6a is 0. Among the control candidate signal lines s2 and s6a, the apparatus selects the control candidate signal line s2 having the maximum value of the acquired longest control distances.

(Step 2113) The apparatus performs activation, implication operation, and justification and thereby determines whether the signal transition can be propagated from the selected control candidate signal line s2 to the control signal line s3. The apparatus executes the determination at Step 2112 by using the activation condition or the like shown in FIG. 27 or 28. For example, when a rise transition ND is set up to the control signal line s3 (output), in accordance with FIG. 28B, a rise transition ND need be provided to the selected control candidate signal line s2 (an input serving as a propagation path), while a value S0 need be provided to the signal line s6a (an input other than the propagation path). In this case, no inconsistency arises at Step 2112. Thus, the apparatus goes to Step 2113.

(Step 2114) Since the signal line s2 is not directly connected to an external terminal (that is, not controllable), the apparatus goes to Step 2115.

(Step 2115) The apparatus sets up the selected control candidate signal line s2 to be a new control signal line, and then goes to Step 2116.

(Step 2116) The apparatus updates the test sequences T1 and T2 into {P}={X, X, 0, X, X, X, X}, and then goes to Step 2105.

(Step 2105) The apparatus sets up to be control candidate signal lines the signal lines s1 and s5a connected to the input side of the control signal line s2, and then goes to Step 2106.

(Step 2106) Since the number of control candidate signal lines is two, the apparatus goes to Step 2112.

(Step 2112) The apparatus calculates the longest path length for each of the control candidate signal lines s1 and s5a. Since the longest path length is 0 for each of the control candidate signal lines s1 and s5a, the apparatus selects the control candidate signal line s1, and then goes to Step 2113.

(Step 2113) A signal transition ND is set up to the control signal line s2. Thus, for example, in accordance with FIG. 28A, the apparatus sets up a signal value ND to the signal line s1, and sets up a signal value U1 to the signal line s5a. Since no inconsistency arises at Step 2112, the apparatus goes to 2114.

(Step 2114) Since the control candidate signal line s1 is controllable, the apparatus goes to Step 2111.

(Step 2111) The apparatus updates the test sequence T1 into {P}={0, X, 0, X, X, X, X} and the test sequence T2 into {P}={1, 1, 0, X, X, X, X}.

As a result of the above-mentioned processing, the apparatus determines {P}={0, X, 0, X, X, X, X} as the test sequence T1 and {P}={1, 1, 0, X, X, X, X} as the test sequence T2.

In the test target circuit shown in FIG. 31, three paths are present that propagate the signal transition to the test target signal line s3. These are a path extending from the signal line s3 through the signal line s2 to the control point PI1, a path extending from the signal line s3 through the signal line s2 to the control point PI2, and a path extending from the signal line s3 through the signal line s6a to the control point PI3. According to the fourteenth generation method, when a plurality of paths are present that propagate to a test target signal line the signal value inputted at a control point, a longer path (the path extending from the signal line s3 through the signal line s2 to the control point PI1) is selected with priority among the paths that can propagate the signal transition. When the signal value is propagated using a longer path, the quality of the test pattern is improved.

### Fifteenth Embodiment

FIG. 32 is a flow chart showing a test pattern generation method according to a fifteenth embodiment of the present invention. The fifteenth generation method is a method where Steps 2201, 2202, 2203, and 2204 are added to the fourteenth generation method. The fifteenth generation method is characterized by comprising a step of performing backtracking to a signal line where signal line selection has been performed in the past, when justification has been unsuccessful for all the control candidate signal lines that propagate a signal to a particular control signal line.

The following steps appear for the first time in the fifteenth generation method.

(Step 2201) When it is determined at Step 2108 that the signal transition cannot be performed from a particular control signal line, the apparatus determines whether the control signal line is a test target signal line. When the control signal line is a test target signal line, the apparatus determines that the processing is unsuccessful. Then, the apparatus goes to Step 2115 (FIG. 29). Otherwise, the apparatus goes to Step 2202. The reason for performing at Step 2201 the determination whether the control signal line is a test target signal line is that the test target signal line could be re-set to be a control signal line as a result of backtracking executed at Step 2203 described later.

(Step 2202) The apparatus sets up the control signal line to be an uncontrollable signal line (“non-control signal line”, hereinafter), and then goes to Step 2203.

(Step 2203) The apparatus sets up to be a new control signal line the output signal line of the gate connected to the output side of the non-control signal line set up at Step 2202. That is, the apparatus performs backtracking toward the output side of the test target circuit by one gate stage. Here, the non-control signal line is a control candidate signal line of a newly set-up control signal line (that is, the control signal line after the backtracking).

(Step 2204) The apparatus excludes the non-control candidate signal line set up at Step 2202 from the control candidate signal lines.

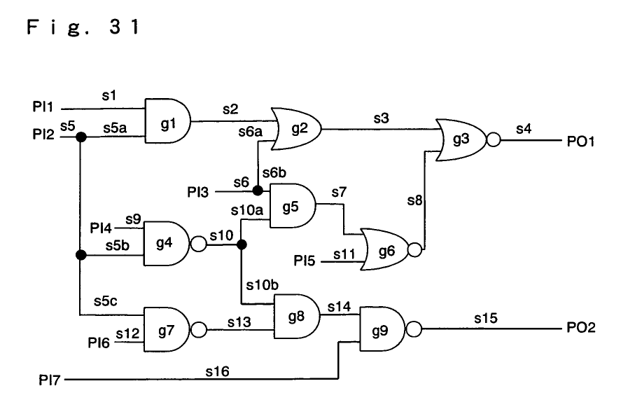

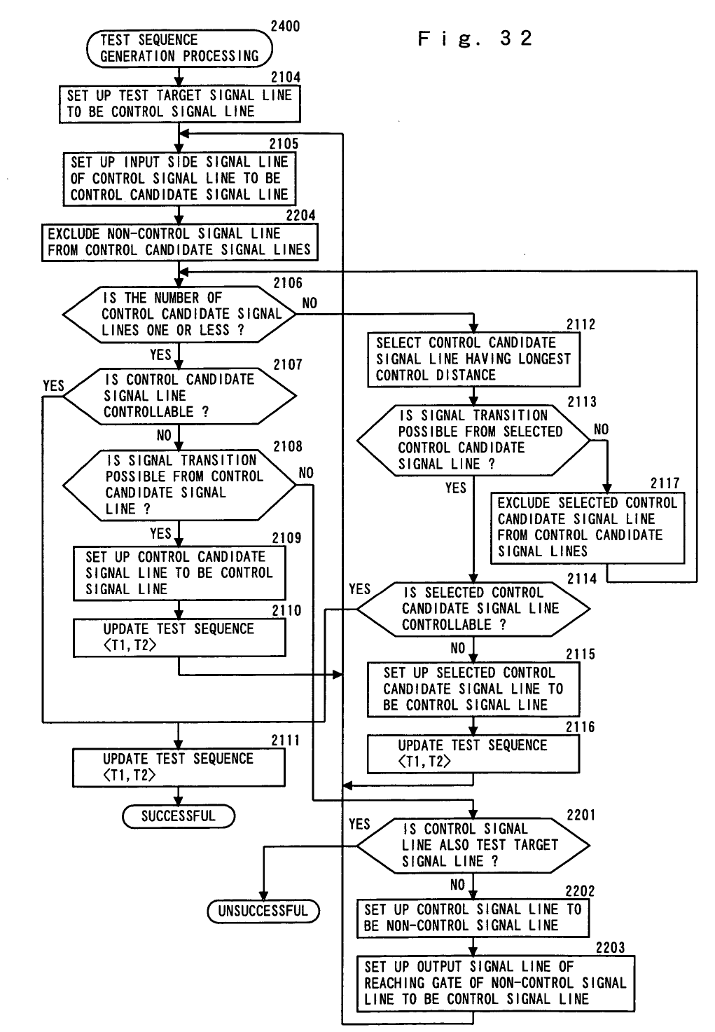

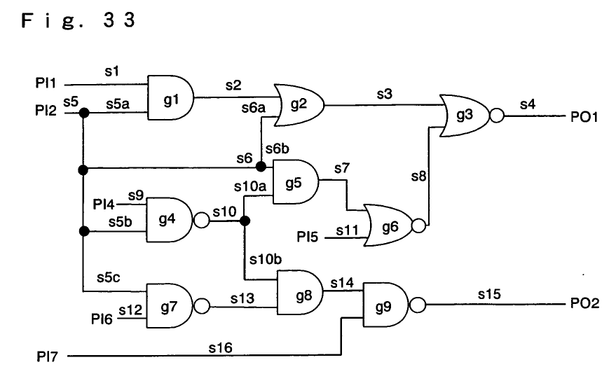

Here, the processing is described below for the case that the fifteenth generation method is applied to the test target circuit shown in FIG. 33. Here, a rise transition in the signal line s4 is adopted as a test target. {PI1, PI2, PI4, PI5, PI6, PI7} is denoted by {P}. In the initial state, both of the test sequences T1 and T2 are set up to be {P}={X, X, X, X, X, X, X}. Further, at Step 2112, the control distance is assumed to be calculated on the basis of the number of gates included in the path.

(Step 2103) The apparatus sets up a signal transition ND to the test target signal line s4.

(Step 2104) The apparatus sets up the test target signal line s4 to be a control signal line.

(Step 2105) The apparatus sets up the signal lines s3 and s8 to be control candidate signal lines.

(Step 2204) Since a non-control signal line is not present, the apparatus goes to Step 2106.

(Step 2106) Since the number of control candidate signal lines is two, the apparatus goes to Step 2112.

(Step 2112) The apparatus calculates the longest control distance for each of the signal lines s3 and s8. When the control distance is estimated in terms of the number of gates, the longest control distance of the signal line s3 is 2, while the longest control distance of the signal line s8 is 3. The apparatus selects the control candidate signal line s8 on the basis of the maximum value of the acquired longest control distances of the control candidate signal lines s3 and s8.

(Step 2113) Since a signal transition ND has been set up to the control signal line s4, the apparatus sets up a value D to the signal line s8 and a value U0 to the signal line s3. At that time, since the signal transition can be propagated from the control candidate signal line s8 to the control signal line s4, the apparatus goes to Step 2114.

(Step 2114) Since the selected control candidate signal line s8 is not controllable, the apparatus goes to Step 2115.

(Step 2115) The apparatus sets up the selected control candidate signal line s8 to be a new control signal line, and then goes to Step 2116.

(Step 2116) At this stage, the values of test sequences T1 and T2 are not specified ({P}={X, X, X, X, X, X, X}). Thus, the apparatus goes to Step 2105.

(Step 2105) The apparatus sets up to be control candidate signal lines the signal lines s7 and s11 connected to the input side of the control signal line s8.

(Step 2204) Since a non-control signal line is not present, the apparatus goes to Step 2106.

(Step 2106) Since the number of control candidate signal lines is two, the apparatus goes to Step 2112.

(Step 2112) The apparatus calculates the longest path length for each of the control candidate signal lines s7 and s11. Since the longest path length of the control candidate signal line s7 is 2 while the longest path length of the control candidate signal line s11 is 0, the apparatus selects the control candidate signal line s7, and then goes to Step 2113.

(Step 2113) In order to propagate the signal transition from the control candidate signal line s7 to the control signal line s8, the apparatus performs activation, implication operation, and justification. Since a value D has been set up to the signal line s8, the apparatus sets up a value ND to the signal line s7 and a value S0 to the signal line s11. At that time, since the signal can be propagated from the control candidate signal line s7 to s8, the apparatus goes to Step 2114.

(Step 2114) Since the selected control candidate signal line is not controllable, the apparatus goes to Step 2115.

(Step 2115) The apparatus sets up the selected control candidate signal line s7 to be a new control signal line, and then goes to Step 2116.

(Step 2116) The apparatus updates the test sequences T1 and T2 into {P}={X, X, X, X, 0, X, X}, and then goes to Step 2105.

(Step 2105) The apparatus sets up the input side signal lines s6b and s10a of the control signal line s7 to be control candidate signal lines.

(Step 2204) Since a non-control signal line is not present, the apparatus goes to Step 2106.

(Step 2106) Since the number of control candidate signal lines is two, the apparatus goes to Step 2112.

(Step 2112) The apparatus calculates the longest control distance for each of the signal lines s6b and s10a. When the control distance is estimated in terms of the number of gates, the longest control distance of the signal line s6b is 0, while the longest control distance of the signal line s10a is 1. The apparatus selects the control candidate signal line s10a on the basis of the maximum value of the acquired longest control distances of the control candidate signal lines s6b and s10a.

(Step 2113) Since a value ND is set up to the control signal line s7, the apparatus sets up a value ND to the signal line s10a and a value U1 to the signal line s6b, and then performs activation, justification, and implication operation. Nevertheless, before this step is performed, a value U0 has been set up to the signal line s3. Thus, inconsistency arises when the value U1 is set up to s6b. Thus, the apparatus determines that the signal transition cannot be propagated from the signal line s10a to the signal line s8. Then, the apparatus goes to Step 2117.

(Step 2117) The apparatus excludes the signal line s10a from the control candidate signal lines for the signal line s8, and then goes to Step 2106.

(Step 2106) The signal line s10a has been excluded from the control candidate signal lines for the signal line s8 at Step 2114. Thus, the only control candidate signal line for the signal line s8 is the signal line s6b. Thus, since the number of control candidate signal lines is one, the apparatus goes to Step 2107.

(Step 2107) Since the control candidate signal line s6b is not controllable, the apparatus goes to Step 2108.

(Step 2108) Since a value ND is set up to the control signal line s7, the apparatus sets up a value ND to the signal line s6b and a value U1 to the signal line s10a, and then performs activation, justification, and implication operation. Nevertheless, before this step is performed, a value U0 has been set up to the signal line s3. Thus, inconsistency arises when the value ND is set up to the signal line s6b. Thus, the apparatus determines that the signal transition cannot be propagated from the signal line s10a to the signal line s8. Then, the apparatus goes to Step 2201.

(Step 2201) The test target signal line is the signal line s4, while the control signal line at this time point is the signal line s7. Thus, the apparatus goes to Step 2202.

(Step 2202) The apparatus sets up the control signal line s7 to be a non-control signal line, and then goes to Step 2203.

(Step 2203) The apparatus re-sets to be a control signal line the output signal line s8 of the reaching gate of the signal line s7 having been set up to be a non-control signal line. Then, the apparatus goes to Step 2105.

(Step 2105) The apparatus sets up the input side signal lines s7 and s11 of the control signal line s8 to be control candidate signal lines, and then goes to Step 2203.

(Step 2204) The apparatus excludes the signal line s7 set up to be a non-control signal line at Step 2202, from the control candidate signal lines. Then, the apparatus goes to Step 2106.

(Step 2106) Since the signal line s7 has been excluded from the control candidate signal lines for the control signal line s8, the only control candidate signal line for the control signal line s8 is the signal line s11. Thus, since the number of control candidate signal lines is one, the apparatus goes to Step 2107.

(Step 2107) Since the control candidate signal line s11 is controllable, the apparatus goes to Step 2111.

(Step 2111) The apparatus updates the test sequence T1 into {P}={X, 0, X, X, 0, X, X} and the test sequence T2 into {P}={X, 0, X, X, 1, X, X}, and then terminates the processing.

As described above, according to the fifteenth generation method, when the activation and the justification have been unsuccessful, backtracking is performed. This permits more reliable generation of a test pattern that can propagate a signal transition from a control point to a test target signal line.

### Sixteenth Embodiment

FIG. 34 is a flow chart showing a test pattern generation method according to a sixteenth embodiment of the present invention. The sixteenth generation method is a method where Step 2301 is added to the fourteenth generation method.

The following steps appear for the first time in the sixteenth generation method.

(Step 2301) The apparatus sets up a fixed signal value to control candidate signal lines (each referred to as a “not-selected control candidate signal line”, hereinafter) having been determined as not having the maximum longest control distance. The purpose of this processing that the apparatus sets up a fixed value to the not-selected control candidate signal lines is to suppress as much as possible the situation that the path for propagating the signal transition is affected by signal delay occurring on the paths other than the propagation path. Here, when a fixed value cannot be set to the not-selected control candidate signal lines at Step 2301, a signal transition may be set up.

Here, the processing is described below for the case that the sixteenth generation method is applied to the test target circuit shown in FIG. 31. Here, a rise transition in the signal line s3 is adopted as a test target. {PI1, PI2, PI3, PI4, PI5, PI6, PI7} is denoted by {P}. In the initial state, both of the test sequences T1 and T2 are set up to be {P}={X, X, X, X, X, X, X}. Further, it is assumed that the control distance is calculated at Step 2111 on the basis of the number of gates included in the path.

(Step 2103) The apparatus sets up a signal transition ND to the test target signal line s3.

(Step 2104) The apparatus sets up the test target signal line s3 to be a control signal line.

(Step 2105) The apparatus sets up the signal lines s2 and s6a to be control candidate signal lines.

(Step 2106) Since the number of control candidate signal lines is two, the apparatus goes to Step 2112.

(Step 2112) The apparatus calculates the longest control distances of the control candidate signal lines s2 and s6a. When the control distance is estimated in terms of the number of gate stages, the longest control distance of the signal line s2 is 1, while the longest control distance of the signal line s6a is 0. Thus, the apparatus selects the control candidate signal line s2 having the maximum longest control distance. Then, the apparatus goes to Step 2113.

(Step 2113) Since the value ND has been set up to the control signal line s3, the apparatus sets up a value ND to the selected control candidate signal line s2 and a value S0 to the signal line s6a, and then performs activation, justification, and implication operation. At that time, since the signal can be propagated from the control candidate signal line s2 to the control signal line s3, the apparatus goes to Step 2114.

(Step 2114) Since the selected control candidate signal line s2 is not controllable, the apparatus goes to Step 2301.

(Step 2301) The apparatus provides to the not-selected control candidate signal line s6a a value 0 which is a fixed value that can be propagated from the control candidate signal line s2 to the control signal line s3. Then, the apparatus goes to Step 2115.

(Step 2115) The apparatus sets up the selected control candidate signal line s2 to be a new control signal line.

(Step 2116) The apparatus updates the test sequence T1 into {P}={X, X, 0, X, X, X, X} and the test sequence T2 into {P}={X, X, 0, X, X, X, X}. Then, the apparatus goes to Step 2105.

(Step 2105) The apparatus sets up to be control candidate signal lines the signal lines s1 and s5a connected to the input side of the control signal line s2.

(Step 2106) Since the number of control candidate signal lines is two, the apparatus goes to Step 2112.

(Step 2112) The apparatus calculates the longest path length for each of the control candidate signal lines s1 and s5a. Since the longest path length is 0 for each of the control candidate signal lines s1 and s5a, the apparatus selects the control candidate signal line s1, and then goes to Step 2113.

(Step 2113) Since the value ND has been set up to the selected control signal line s2, the apparatus sets up a value ND to the control candidate signal line s1 and a value U1 to the control candidate signal line s5a, and then performs activation, justification, and implication operation. At that time, since the signal can be propagated from the control candidate signal line s1 to the control signal line s2, the apparatus goes to Step 2301.

(Step 2114) Since the selected control candidate signal line s1 is controllable, the apparatus goes to Step 2111.

(Step 2111) The apparatus determines {P}={0, 1, 0, X, X, X, X} as the test sequence T1 and {P}={1, 1, 0, X, X, X, X} as the test sequence T2.

In this example, the value provided to the control point PI2 in the test sequence T1 may be any one of values X and 1 in the test sequence T1, as long as the value provided to the control point PI2 in the test sequence T2 is 1. However, when a fixed value 0 is set up to the control point PI2 in both of the test sequences T1 and T2, signal delay does not occur on the not-selected control candidate signal line s5a. Thus, the influence of signal delay to the control signal line s2 is removed that occurs on the paths other than the control candidate signal line s1 serving as the signal propagation path.

As described above, according to the sixteenth generation method, a fixed value is set up to the paths other than the longest path that can propagate a signal from a control point to a test target signal line. This reduces the influence of signal delay in the non-test target paths, and hence improves the reliability of the test pattern.

Seventeenth through nineteenth embodiments of the present invention are described below. In each test pattern generation method according to the seventeenth through the nineteenth embodiments, a longer path is selected with priority among the paths extending from a control point through a test target signal line to an observation point. In the following description, test pattern generation methods according to the seventeenth through the nineteenth embodiments are referred to as seventeenth through nineteenth generation methods, respectively.

### Seventeenth Embodiment

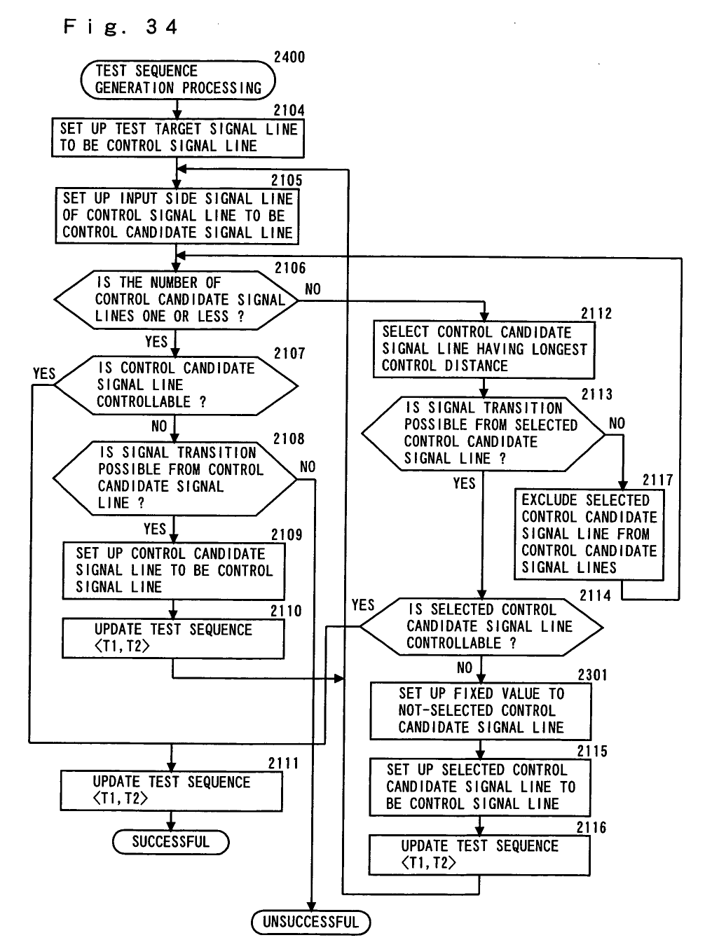

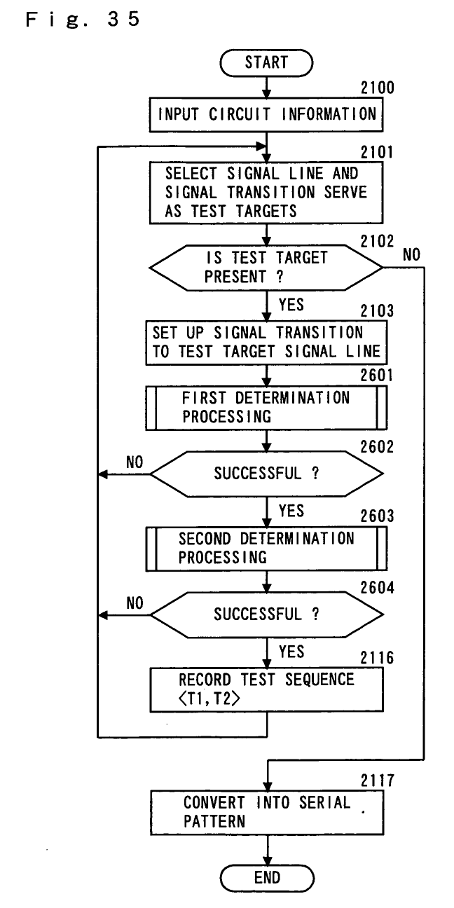

FIG. 35 is a flow chart showing a seventeenth generation method of the present invention. In the seventeenth generation method, in first determination processing, a longer path is first selected from among the paths that can propagate a signal transition from a test target signal line to an observation point. Then, a test sequence <T1,T2> is generated. Then, in second determination processing, a longer path is selected from among the paths that can propagate the signal transition from a control point to a test target signal line. Then, the generated test sequence <T1,T2> is updated. The processing of the seventeenth generation method is described below.

(Step 2100) Information concerning storage elements and logic elements (gates) that constitute the test target circuit as well as concerning wiring between these elements is inputted as circuit information to the apparatus. In addition, information for specifying a signal line serving as a test target is inputted to the apparatus. Here, the information for specifying a signal line serving as a test target may be inputted manually or alternatively using a computer.

(Step 2101) The apparatus selects a signal line serving as a test target and a signal transition serving as a test target. At Step 2001, signal lines where a test pattern has already been generated and signal lines where a test pattern has already been determined as not capable of being generated are excluded from the targets of selection. Here, the signal line and the signal transition serving as test targets may be selected manually, or alternatively may be selected automatically by a computer on the basis of circuit information.

(Step 2102) When a signal line and a signal transition serving as test targets have been selected at Step 2101, the apparatus goes to Step 2103. Otherwise, the apparatus goes to Step 2117.

(Step 2103) The apparatus sets up a fault value (ND for a rise transition and D for a fall transition) corresponding to the signal transition selected at Step 2101, to the test target signal line selected at Step 2101.

(Step 2601) The apparatus performs first determination processing described later, and thereby determines a test sequence <T1,T2>.

(Step 2602) When the first determination processing has been successful, the apparatus goes to Step 2602. Otherwise, the apparatus goes to Step 2101.

(Step 2603) The apparatus performs second determination processing described later, thereby updates the test sequence <T1,T2> determined at Step 2601, and thereby determines the test sequence <T1,T2>.

(Step 2604) When the second determination processing has been successful, the apparatus goes to Step 2116. Otherwise, the apparatus goes to Step 2101.

(Step 2116) The apparatus records the test sequence <T1,T2> generated at Step 2603, temporarily into the inside or into a file. Further, when a signal line where test pattern generation has already been determined as being impossible is present, the apparatus may check whether the signal line can be tested using the generated test sequence <T1,T2>. Then, the apparatus goes to Step 2101. As such, Steps 2101-2116 are executed for all combinations of the signal lines and the signal transitions serving as test targets.

(Step 2117) The apparatus converts into a serial pattern the test sequence <T1,T2> recorded at Step 2116, and then terminates the processing.

FIG. 36 is a flow chart showing details of the first determination processing shown in FIG. 35.

(Step 2501) The apparatus sets up the test target signal line to be a reaching signal line.

(Step 2502) In order to set up a fault value to the test target signal line and then propagate the set-up fault value toward the output side of the test target signal line by one gate stage, the apparatus performs activation, implication operation, and justification. Here, when a value to be provided to the control point has been determined in the justification, the test sequence T2 is updated. Further, depending on the situation, the test sequence T1 is also updated. This holds for all the justification processes described below.

(Step 2503) When inconsistency arises at Step 2502, the apparatus goes to Step 2101. Otherwise, the apparatus goes to Step 2504.

(Step 2504) The apparatus sets up to be reaching candidate signal lines the signal lines of the gate on the output side of the reaching signal line.

(Step 2505) When the number of reaching candidate signal lines is one or less (that is, zero or one), the apparatus goes to Step 2506. Otherwise, the apparatus goes to Step 2508.

(Step 2506) When the reaching candidate signal line can be observed or alternatively when the number of reaching candidate signal lines is zero (that is, when a reaching candidate signal line is connected to the observation point or alternatively when no reaching candidate signal line is present), the apparatus goes to Step 2513. Otherwise, the apparatus goes to Step 2507.

(Step 2507) The apparatus reaches this step only when the number of reaching candidate signal lines is one. The apparatus sets up the only reaching candidate signal line to be a new reaching signal line.

(Step 2508) For each branch, the apparatus acquires the length (the observation distance) of a path to each observation point, and then acquires the maximum value (the longest observation distance, hereinafter) of the observation distances. As described above, the observation distance is calculated using the delay value table (FIG. 2), the via hole table (FIG. 3), and the like. The apparatus selects a signal line having the maximum longest observation distance among the reaching candidate signal lines.

(Step 2509) In order to set up a fault value to the test target signal line and then propagate the set-up fault value toward the output side of the test target signal line by one gate stage, the apparatus performs activation, implication operation, and justification.

(Step 2510) When inconsistency arises at Step 2509, the apparatus goes to Step 2512. Otherwise, the apparatus goes to Step 2511.

(Step 2511) The apparatus sets up the reaching candidate signal line to be a new reaching signal line, and then goes to Step 2502.

(Step 2512) The apparatus excludes the reaching candidate signal line having caused inconsistency at Step 2509, from the reaching candidate signal lines for the reaching signal line. Then, the apparatus goes to Step 2505.

(Step 2513) The apparatus updates the test sequence <T1,T2> and then goes to Step 2601.

Here, the first determination processing may be implemented by any one of the test sequence generation methods in the first through the thirteenth generation methods described above. Further, the second determination processing may be implemented by any one of the test sequence generation methods in the fourteenth through the sixteenth generation methods described above. Thus, their description is omitted.

Here, the processing is described below for the case that the seventeenth generation method is applied to the test target circuit shown in FIG. 37. Here, a rise transition in the signal line s10 is adopted as a test target. {PI1, PI2, PI3, PI4, PI5, PI6, PI7} is denoted by {P}. In the initial state, both of the test sequences T1 and T2 are set up to be {P}={X, X, X, X, X, X, X}.

(Step 2103) The apparatus sets up a value ND to the test target signal line s10.

(Step 2501) The apparatus sets up the test target signal line s10 to be a reaching signal line.

(Step 2502) Since the reaching signal line s10 is a stem, the apparatus goes to Step 2503 without performing activation, implication operation, and justification.

(Step 2503) Since no inconsistency arises at Step 2502, the apparatus goes to Step 2504.

(Step 2504) Since the reaching signal line s10 is a stem, the apparatus sets up the signal lines s10a and s10b to be reaching candidate signal lines.

(Step 2505) Since two reaching candidate signal lines are present, the apparatus goes to Step 2508.

(Step 2508) The apparatus acquires the longest observation distance for each of the reaching candidate signal lines s10a and s10b. When the observation distance is estimated in terms of the number of gate stages, the longest observation distance of the signal line s10a is 3, while the longest observation distance of the signal line s10b is 2. Thus, the apparatus selects the reaching candidate signal line s10a having the maximum longest observation distance.

(Step 2509) In order to propagate the signal transition set up to the reaching candidate signal line s10 toward the output side of the test target circuit by one gate stage, the apparatus performs activation, implication operation, and justification. As a result, the apparatus sets up a value ND to the signal line s7 and a value S0 to the signal line s6b. Accordingly, the test sequence T1 is updated into {P}={X, X, 0, X, X, X, X}, while the test sequence T2 is updated into {P}={X, X, 0, X, X, X, X}.

(Step 2510) Since no inconsistency arises at Step 2509, the apparatus goes to Step 2512.

(Step 2511) The apparatus sets up the reaching candidate signal line s7 to be a new reaching signal line, and then goes to Step 2502.

Similarly, the apparatus executes the processing shown in FIG. 36. The method of generating a test pattern with selecting a path extending from the test target signal line to the observation point has been described in the first through the fourteenth embodiments. Thus, detailed explanation is omitted in the following description. As a result, the apparatus determines a test sequence <T1,T2> with selecting a path extending sequentially from the test target signal line s10 through the signal lines s7, s8a, and s4 to the observation point PO1. At Step 2513, the apparatus updates the test sequence T1 into {P}={X, X, 0, X, 0, X, X} and the test sequence T2 into {P}={0, X, 0, X, 0, X, X}. After that, the apparatus goes to Step 2602.

(Step 2602) Since the first determination processing has been successful, the apparatus goes to Step 2603.

The following description is given for the case that the apparatus executes as the second determination processing the test sequence generation processing according to the fourteenth embodiment (FIG. 30). Thus, the apparatus goes to Step 2104.

(Step 2104) The apparatus sets up the test target signal line s10 to be a control signal line.

(Step 2105) The apparatus sets up the signal lines s9 and s5b to be control candidate signal lines.

(Step 2106) Since the number of control candidate signal lines is two, the apparatus goes to Step 2112.

(Step 2112) The apparatus calculates the control distance for each of the signal line s9 and the signal line s5b. When the path length is estimated in terms of the number of gate stages, the longest control distance of the control candidate signal line s9 is 0, while the longest control distance of the control candidate signal line s5b is 1. Thus, the apparatus selects the control candidate signal line s5b and then goes to Step 2113.

(Step 2113) The apparatus determines whether a value D can be set up to the selected control candidate signal line s5b so that a value ND can be propagated to the control signal line s10. As a result of justification, activation, and implication operation, the signal transition is possible. Thus, the apparatus goes to Step 2114.

(Step 2114) Since the control candidate signal line s5b is not controllable, the apparatus goes to Step 2115.

(Step 2115) The apparatus sets up the reaching candidate signal line s5b to be a control signal line, and then goes to Step 2116.

(Step 2116) The apparatus updates the test sequence T1 into {P}={X, X, 0, 1, 0, X, X} and the test sequence T2 into {P}={0, X, 0, 1, 0, X, X}. Then, the apparatus goes to Step 2105.

(Steps 2105-2111) The only reaching candidate signal line of the control signal line s5b is s5, and the signal line s5 is controllable. Thus, the apparatus goes to Steps 2106 and 2107, and then updates the test sequence at Step 2111.

As a result of the above-mentioned processing, the apparatus determines {P}={X, 0, 0, 1, 0, X, X} as the test sequence T1 and {P}={0, 1, 0, 1, 0, X, X} as the test sequence T2.

As such, first, in the first determination processing, a test pattern is generated for a path having a longer path extending from the test target signal line to the observation point. Then, in the second determination processing, a test pattern is determined with updating the test pattern generated in the first determination processing, for a path having the longer distance from the control point to the test target signal line. Thus, according to the seventeenth generation method, a test pattern can be generated in which the length of the path extending from a control point to an observation point becomes longer.

Further, a path that can propagate a signal from a test target signal line to an observation point is selected first. This permits efficient generation of a test pattern for a path in which the signal transition can be observed reliably on the test target signal line.

### Eighteenth Embodiment

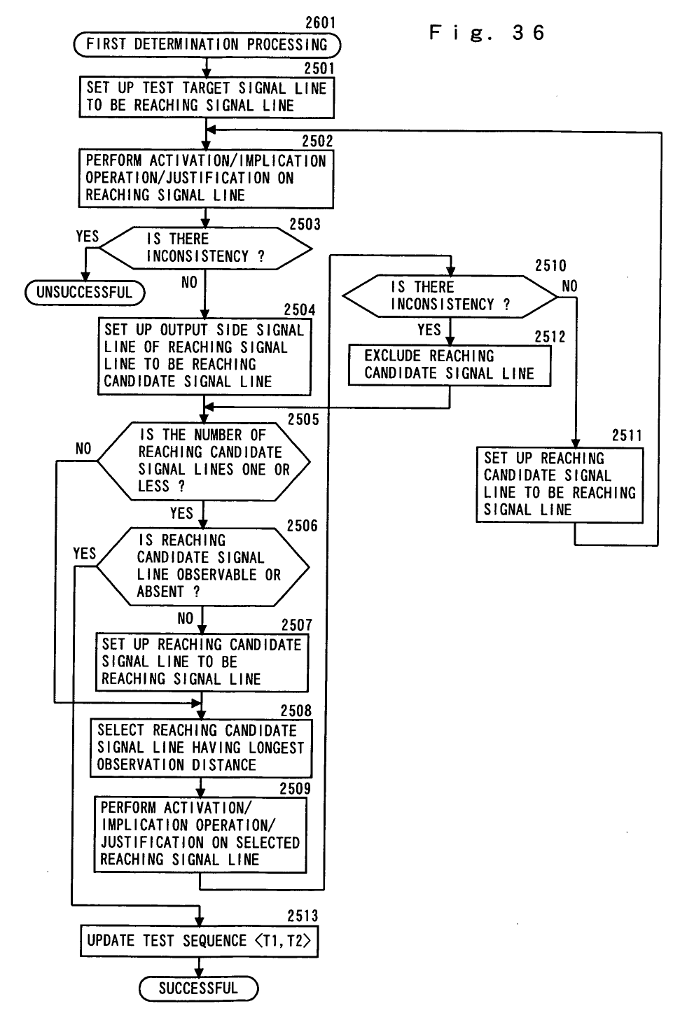

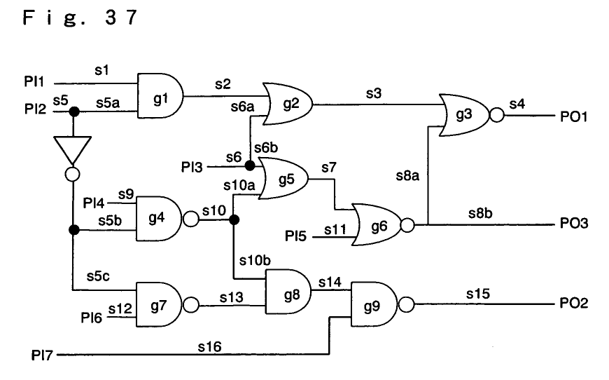

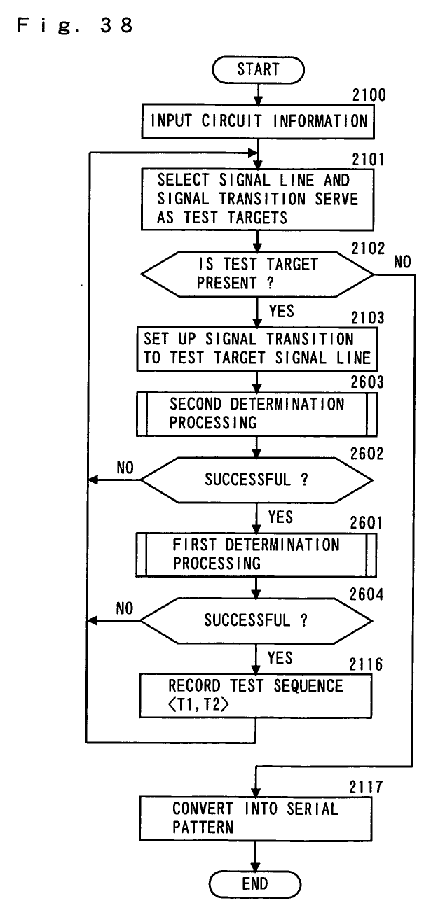

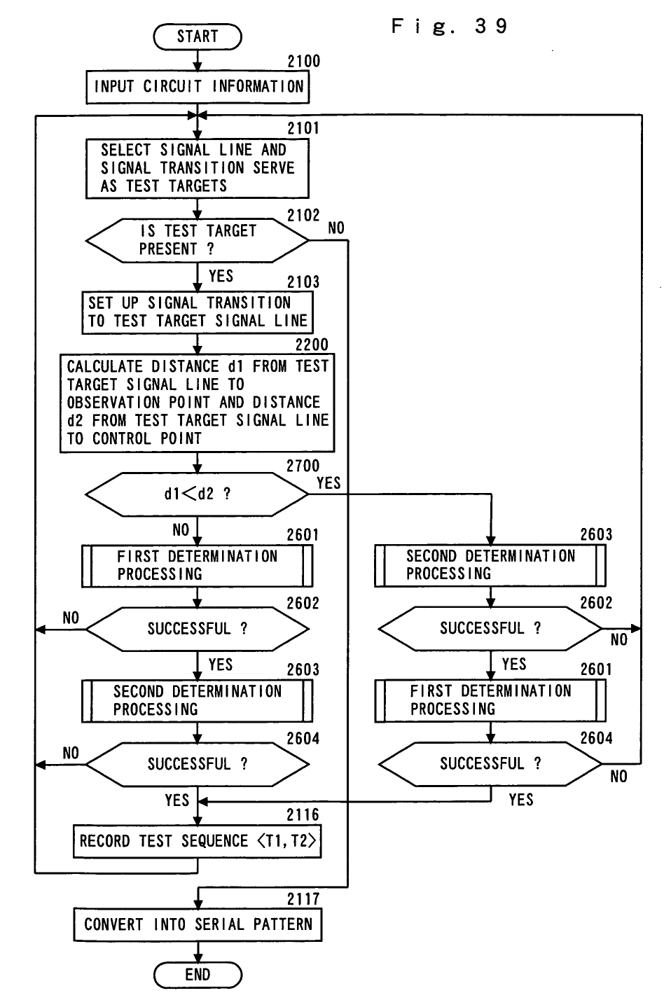

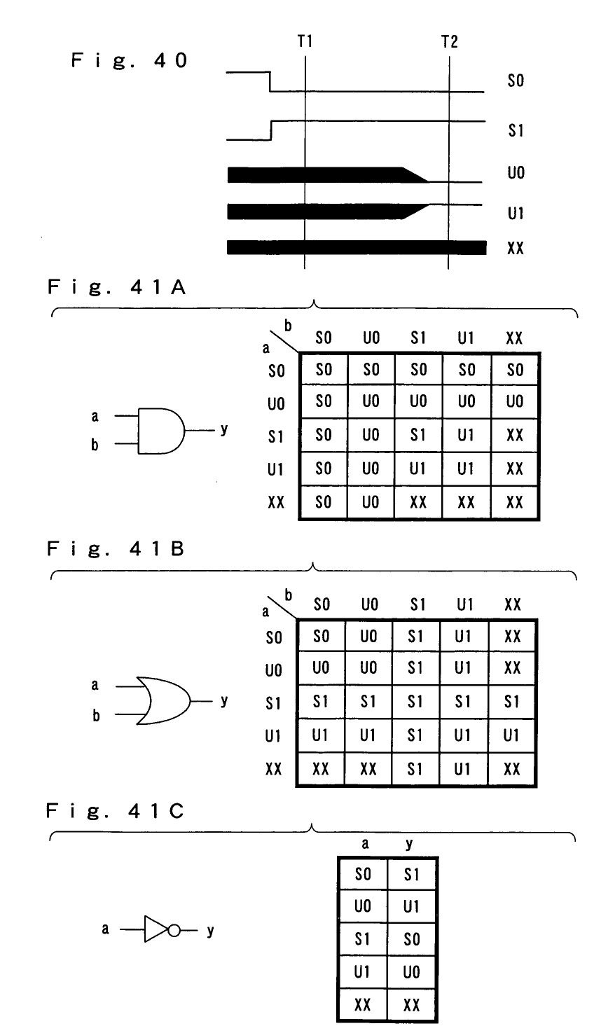

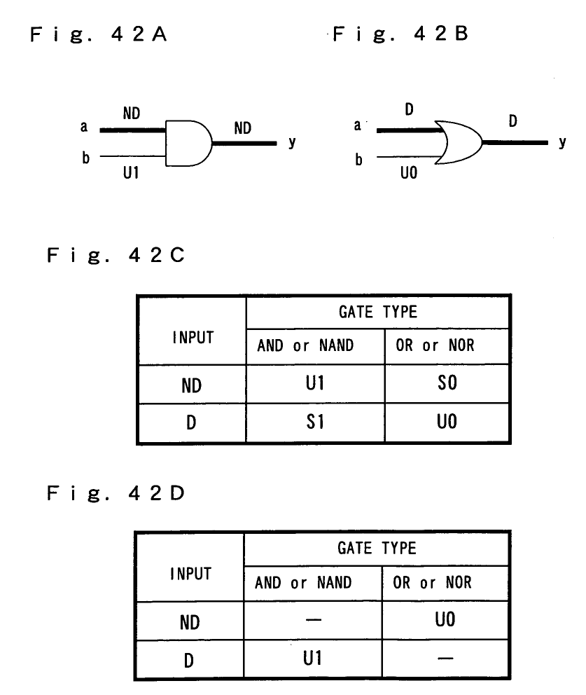

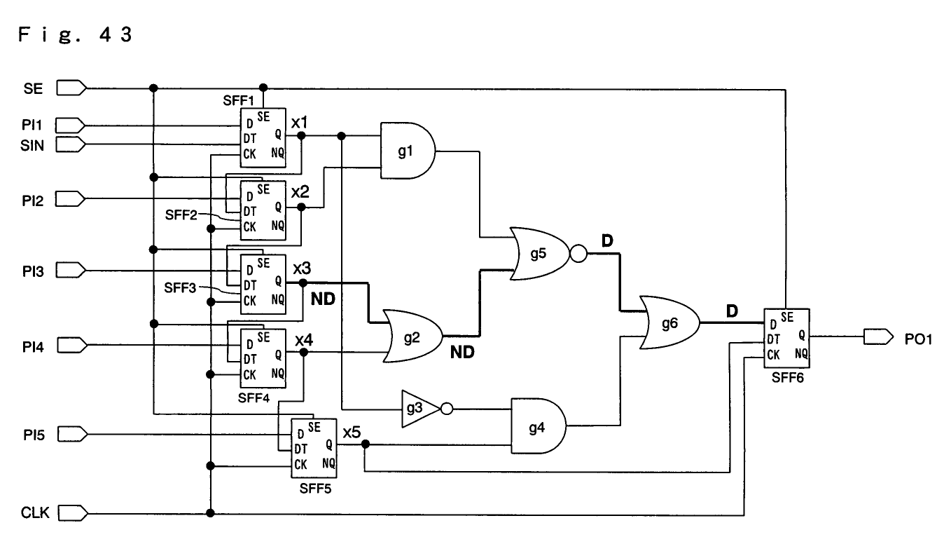

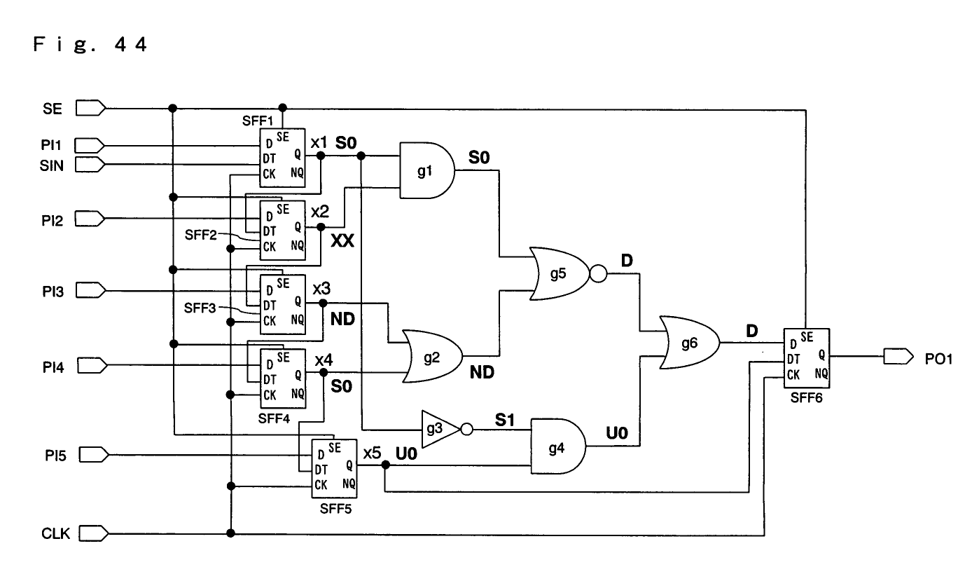

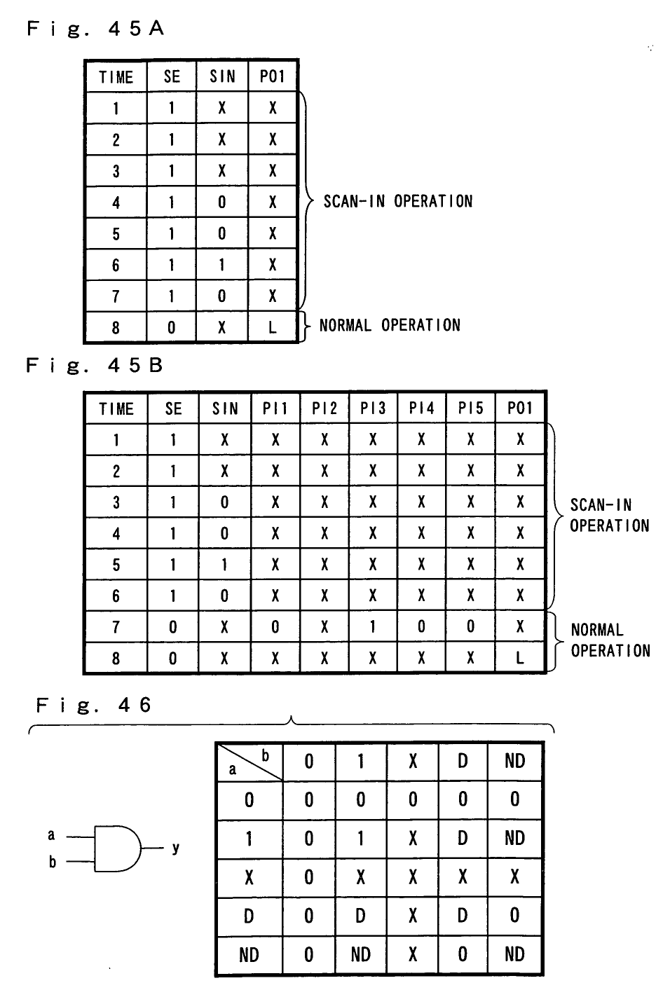

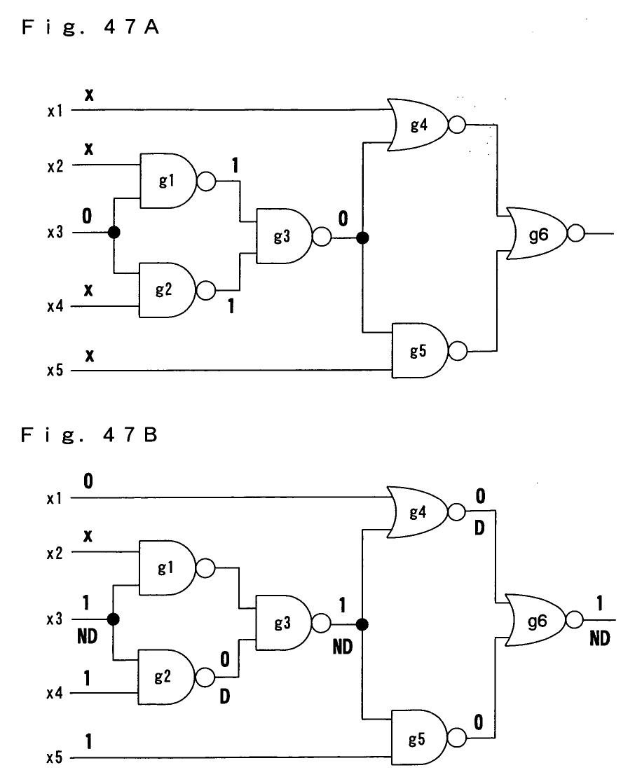

FIG. 38 is a flow chart showing an eighteenth generation method of the present invention. As shown in FIG. 38, the eighteenth generation method is a modification of the seventeenth generation method, where the order of execution of Step 2601 and Step 2603 is exchanged. Thus, the first determination processing (Step 2601) is executed after the second determination processing (Step 2603). More specifically, a longer path is first selected from among the paths that can propagate a signal transition from a control point to a test target signal line. Then, a test sequence <T1,T2> is generated. After that, a longer path is selected from among the paths that can propagate the signal transition from a test target signal line to an observation point. Then, the test sequence <T1,T2> is updated.

Here, the first determination processing may be implemented by any one of the test sequence generation processes in the first through the thirteenth generation methods described above. Alternatively, similarly to the seventeenth generation method, the first determination processing may be implemented by the test sequence generation processing shown in FIG. 36. On the other hand, the second determination processing may be implemented by any one of the test sequence generation processes in the fourteenth through the sixteenth generation methods described above.

Here, the processing is described below for the case that the eighteenth generation method is applied to the test target circuit shown in FIG. 37. Here, a rise transition in the signal line s10 is adopted as a test target. {PI1, PI2, PI3, PI4, PI5, PI6, PI7} is denoted by {P}. In the initial state, both of the test sequences T1 and T2 are set up to be {P}={X, X, X, X, X, X, X}.

Further, the following example is described for the case that the test sequence generation processing shown in FIG. 36 is employed as the first determination processing and that the test sequence generation processing shown in FIG. 30 is employed as the second determination processing.

(Step 2103) The apparatus sets up a value ND to the test target signal line s10, and then goes to Step 2104.

(Step 2104) The apparatus sets up the test target signal line s10 to be a control signal line.

(Step 2105) The apparatus sets up the signal lines s9 and s5b to be control candidate signal lines.

(Step 2106) Since the number of control candidate signal lines is two, the apparatus goes to Step 2112.

(Step 2112) The apparatus calculates the control distance for each of the signal line s2 s9 and the signal line s6a s5b. When the path length is estimated in terms of the number of gate stages, the longest control distance of the control candidate signal line s9 is 0, while the longest control distance of the control candidate signal line s5b is 1. Thus, the apparatus selects the control candidate signal line s5b and then goes to Step 2113.

(Step 2113) In order to generate a predetermined signal transition to the control signal line s10, the apparatus performs activation, implication operation, and justification. Then, the apparatus determines whether the signal transition can be propagated from the selected control candidate signal line s2 s5b to the control signal line s3 s10. As a result, the apparatus sets up a value D to the signal line s5b and a value S1 to the signal line s9, and then goes to Step 2114.

(Step 2114) Since the selected control candidate signal line s5b is not controllable, the apparatus goes to Step 2115.

(Step 2115) The apparatus sets up the selected control candidate signal line s5b to be a new control signal line, and then goes to Step 2116.

(Step 2116) The apparatus determines the test sequence T1 into {P}={X, X, X, 1, X, X, X}, and then updates the test sequence T2 into {P}={X, X, X, 1, X, X, X}. Then, the apparatus goes to Step 2105.

(Step 2105) The apparatus sets up the input side signal line s5 of the control signal line s5b to be a control candidate signal line.

(Steps 2106-2111) Since the number of control candidate signal lines is one, and the control candidate signal line is controllable. Thus, the apparatus goes through Steps 2107 and 2109 to Step 2111.

(Step 2110 2111) The apparatus determines {P}={X, 0, X, 1, X, X, X} as the test sequence T1 and {P}={X, 1, X, 1, X, X, X} as the test sequence T2. After that, the apparatus goes to Step 2602.

(Step 2602) Since the second determination processing has been successful, the apparatus goes to Step 2601.

(Step 2501) The apparatus sets up the test target signal line s10 to be a reaching signal line.

(Step 2502) Since the reaching signal line s10 is a stem, the apparatus goes to Step 2503 without performing activation, implication operation, and justification.

(Step 2503) Since no inconsistency arises at Step 2502, the apparatus goes to Step 2504.

(Step 2504) Since the reaching signal line s10 is a stem, the apparatus sets up the signal lines s10a and s10b to be reaching candidate signal lines.

(Step 2505) Since two reaching candidate signal lines are present, the apparatus goes to Step 2508.

(Step 2508) The apparatus acquires the longest observation distance for each of the reaching candidate signal lines s10a and s10b. When the observation distance is estimated in terms of the number of gate stages, the longest observation distance of the signal line s10a is 3, while the longest observation distance of the signal line s10b is 2. The longest observation distance of the reaching candidate signal line 10a is 3, which is the maximum longest observation distance. Further, the longest observation distance of the signal line s10b is 2. Thus, the apparatus selects as a reaching signal line the reaching candidate signal line s10a having the maximum longest observation distance.

(Step 2509) In order to propagate the signal transition set up to the reaching candidate signal line s10a toward the output side of the test target circuit by one gate stage, the apparatus performs activation, implication operation, and justification. As a result, the apparatus sets up a value ND to the signal line s7 and a value S0 to the signal line s6b. Accordingly, the test sequence T1 is updated into {P}={X, 0, 0, 1, 1, X, X}, while the test sequence T2 is updated into {P}={X, 1, X, 1, X, X, X}.

(Step 2510) Since no inconsistency arises at Step 2509, the apparatus goes to Step 2512.

(Step 2511) The apparatus sets up the reaching candidate signal line s7 to be a new reaching signal line, and then goes to Step 2502.

Similarly, the apparatus executes the processing shown in FIG. 36. The method of generating a test pattern with selecting a path extending from the test target signal line to the observation point has been described in the first through the fourteenth thirteenth embodiments. Thus, detailed explanation is omitted in the following description. As a result, the apparatus determines a test sequence <T1,T2> with selecting a path extending sequentially from the test target signal line s10 through the signal lines s7, s8a, and 34 to the observation point PO1. At Step 2513, the apparatus updates the test sequence T1 into {P}={X, 0, 0, 1, 1, X, X} and the test sequence T2 into {P}={X, 1, X, 1, X, X, X}. After that, the apparatus goes to Step 2604.

As such, first, in the second determination processing, a test pattern is generated for a path having a longer path extending from a control point to the test target signal line. Then, in the first determination processing, a test pattern is determined with updating the test pattern generated in the first second determination processing, for a path having a longer distance from the test target signal line to an observation point. Thus, according to the eighteenth generation method, a test pattern can be generated in which the length of the path extending from a control point to an observation point becomes longer.

Further, a path that can propagate a signal from a control point to a test target signal line is selected first. This permits efficient generation of a test pattern for a path in which the signal propagation on the test target signal line can be controlled reliably.

### Nineteenth Embodiment

FIG. 39 is a flow chart showing a nineteenth generation method of the present invention. The nineteenth generation method is different from the seventeenth generation method mainly in the point that Steps 2200 and 2700 are added to the seventeenth generation method.

The following steps appear for the first time in the nineteenth generation method.

(Step 2200) The apparatus calculates the longest observation distance d1 from the test target signal line to the observation point and the longest control distance d2 from the test target signal line to the control point. Similarly to each generation method described above, the longest observation distance and the longest control distance are calculated using the delay value table (FIG. 2) and the via hole table (FIG. 3) or alternatively using the number of gates or the like connected between the control candidate signal line and the control point.

(Step 2700) The longest observation distance d1 and the longest control distance d2 calculated at Step 2200 are compared with each other. When d1 is not smaller than d2 (that is, d1 is greater than or equal to d2), the first determination processing (Step 2601) is executed first, and then the second determination processing (Step 2603) is executed. In this case, the nineteenth generation method is the same as the seventeenth generation method. On the other hand, when d1 is smaller than d2, the second determination processing (Step 2603) is executed first, and then the first determination processing (Step 2601) is executed. In this case, the nineteenth generation method is the same as the eighteenth generation method.

Here, the first determination processing may be implemented by any one of the test sequence generation processes in the first through the thirteenth generation methods described above. Alternatively, similarly to the seventeenth generation method, the first determination processing may be implemented by the test sequence generation processing shown in FIG. 36. On the other hand, the second determination processing may be implemented by any one of the test sequence generation processes in the fourteenth through the sixteenth generation methods described above.

Here, the processing is described below for the case that the nineteenth generation method is applied to the test target circuit shown in FIG. 37. Here, a rise transition in the signal line s10 is adopted as a test target. {PI1, PI2, PI3, PI4, PI5, PI6, PI7} is denoted by {P}. In the initial state, both of the test sequences T1 and T2 are set up to be {P}={X, X, X, X, X, X, X}.

Further, the following example is described for the case that the test sequence generation processing shown in FIG. 36 is employed as the first determination processing and that the test sequence generation processing shown in FIG. 30 is employed as the second determination processing.

(Step 2103) The apparatus sets up a value ND to the test target signal line s10, and then goes to Step 2200.

(Step 2200) The apparatus calculates the longest observation distance from the test target signal line s10 to the observation point. When the observation distance is estimated in terms of the number of gates, the path extending sequentially from the test target signal line s10 through the signal lines s10a, s7, s8a, and s4 to the control observation point PO1 is the longest. Its longest observation distance d1 is 3. On the other hand, when the control distance is estimated in terms of the number of gates, the path extending sequentially from the test target signal line s10 through the signal lines s5b and s5 to the control point PI2 is the longest. Its longest control distance d2 is 2.

(Step 2700) Since the longest observation distance d1 is not smaller than the longest control distance d2, the apparatus goes to Step 2601, and then executes the first determination processing before the second determination processing.

Here, details of the subsequent processing are the same as those of the seventeenth generation method. Thus, their description is not repeated.

As a result, the apparatus determines {P}={1, 1, 0, 1, 1, X, X} as the test sequence T1 and {P}={1, 1, 0, 0, 1, X, X} as the test sequence T2.

As such, in the nineteenth generation method, the length of the longest path from a test target signal line to an observation point is compared with the length of the longest path from the test target signal line to a control point. Then, on the basis of the comparison result, the order of execution of the first and the second determination processes is determined. The determination of a test pattern becomes more difficult with increasing observation distance and control distance of the test target signal line. However, according to the nineteenth generation method, a test pattern that propagates a signal through a longer path is determined first. This permits efficient generation of a test pattern.

The test pattern generation method of the present invention can generate at a high speed a high-quality test pattern for testing a delay fault, and hence is applicable to the generation of a test pattern for testing a delay fault occurring in various kinds of semiconductor integrated circuits.

The present invention has been described above in detail. The description given above is fully illustrative, and does not limit the scope of the present invention from any point of view. Thus, obviously, various kinds of improvements and modifications are achievable without deviating from the scope of the present invention.

1. A test pattern generation method for generating a first test pattern and a second test pattern which is provided at a next test cycle, for the purpose of detection of a delay fault that occurs in a test target circuit, the method comprising steps of:
acquiring as the first test pattern a combination of input values that cause a value of a test target signal line to agree with an initial value corresponding to an assumed delay fault; and
acquiring as the second test pattern a combination of input values for propagating to an observation point the fault value set up to the test target signal line in correspondence to the assumed delay fault, wherein
the step of acquiring a second test pattern includes steps of:
selecting a signal line for propagating the fault value, from among a plurality of branches at a branch point included in the test target circuit;
performing activation and justification in order to propagate the fault value to the selected signal line, and thereby acquiring a value of the signal line included in the test target circuit; and
updating the second test pattern on the basis of the acquired value of the signal line, when the activation and the justification have been successful, and wherein
in the step of selecting a signal line, one of branches is selected on the basis of a length of the longest path from each branch to the observation point.

2. The test pattern generation method as claimed in claim 1, wherein
the test target signal line is selected from control points and branches included in the test target circuit, and
in the step of selecting a signal line, signal lines are collectively selected that constitute a path that leads to a stem or an observation point which can be reached from a branch without going via a branch point.

3. The test pattern generation method as claimed in claim 1, wherein in the step of selecting a signal line, when the length of the longest test path including a particular branch does not satisfy a predetermined criterion, the branch is excluded from candidates of signal line selection.

4. The test pattern generation method as claimed in claim 1, wherein
in the step of acquiring the value of a signal line, activation is performed according to a robust condition, and wherein
the method further comprises a step of updating the first test pattern on the basis of the acquired value of the signal line, when the activation under the robust condition and the justification have been successful.

5. The test pattern generation method as claimed in claim 1, wherein in the step of acquiring the value of a signal line, activation is performed according to a non-robust condition.

6. The test pattern generation method as claimed in claim 1, wherein
in the step of acquiring the value of a signal line, activation is performed according to a robust condition first, and then when activation under the robust condition has been unsuccessful for all branches that are selectable at a particular branch point, activation is performed according to a non-robust condition, and
the method further comprises a step of updating the first test pattern on the basis of the acquired value of the signal line, when the activation under the robust condition and the justification have been successful.

7. The test pattern generation method as claimed in claim 1, wherein
in the step of acquiring the value of a signal line, for a selected branch, activation is performed according to a robust condition, and then when the processing has been unsuccessful, activation is performed according to a non-robust condition, and
the method further comprises a step of updating the first test pattern on the basis of the acquired value of the signal line, when the activation under the robust condition and the justification have been successful.

8. The test pattern generation method as claimed in claim 1, wherein the step of acquiring a second test pattern further includes
a step of backtracking to a branch point where signal line selection has been performed in the past, when the activation and the justification have been unsuccessful for all branches that are selectable at a particular branch point.

9. The test pattern generation method as claimed in claim 8, wherein in the step of backtracking, the backtracking is performed to a branch point where signal line selection has been performed immediately before.

10. The test pattern generation method as claimed in claim 8, wherein in the step of backtracking, the backtracking is performed to a nearest branch point where signal line selection has been performed, among branch points where a length of the longest test path including any one of not-selected branches satisfies a predetermined criterion.

11. The test pattern generation method as claimed in claim 8, wherein in the step of backtracking, the backtracking is performed to a branch point having the maximum length of the longest test path including a not-selected branch, among branch points where signal line selection has been performed in the past.

12. The test pattern generation method as claimed in claim 8, wherein in the step of backtracking, the backtracking is performed in a state that the value of a control point acquired in order to propagate a fault value beyond the branch point serving as a backtracking destination is holding intact.

13. The test pattern generation method as claimed in claim 1, wherein
when the length of the longest test path including a particular control point does not satisfy a predetermined criterion, the control point is excluded from the test target signal line, and
when the length of the longest test path including a particular branch does not satisfy a predetermined criterion, the branch is excluded from the test target signal line and excluded from the candidates of signal line selection in the step of selecting a signal line.

14. The test pattern generation method as claimed in claim 1, further comprising
a step of specifying a control point, a signal line, and an observation point which are included in the test target circuit, wherein
among the signal lines included in the test target circuit, a signal line that constitutes a path leading to a branch point which can be reached from the specified control point without going via a branch point, a signal line that constitutes a path extending from the specified signal line to an arbitrary observation point, and a signal line included solely in a path that leads to the specified observation point are excluded from the test target signal line and excluded from the candidates of signal line selection in the step of selecting a signal line, so that a fixed value is provided at the step of acquiring the value of a signal line.

15. A test pattern generation method for generating a first test pattern and a second test pattern which is provided at a next test cycle, for the purpose of detection of a delay fault that occurs in a test target circuit, the method comprising steps of:
setting up a signal transition to a test target signal line selected from a plurality of signal lines included in the test target circuit and then setting up the test target signal line to be a control signal line;
acquiring a length of the longest path from a control candidate signal line to a control point where a signal is inputted, for each of one or more control candidate signal lines that propagate a signal to the control signal line, and then selecting a control candidate signal line from the control candidate signal lines on the basis of the maximum value of the acquired lengths of the longest paths;
performing activation and justification in order to propagate the signal transition from the selected control candidate signal line to the control signal line, and thereby acquiring a signal value to be set up to the signal line included in the test target circuit; and
determining the first and the second test patterns on the basis of the acquired signal value when the activation and the justification have been successful.

16. The test pattern generation method as claimed in claim 15, wherein:
when the activation and the justification have been successful, the selected control candidate signal line is re-set to be a control signal line;
when the activation and the justification have been unsuccessful, a signal line is selected from the not-selected control candidate signal lines; and
the step of selecting a signal line, the step of acquiring a signal value, and the step of determining the first and the second test patterns are repeated until a controllable control point is reached.

17. The test pattern generation method as claimed in claim 15, further comprising a step of backtracking to a signal line where signal line selection has been performed in the past, when the activation and the justification have been unsuccessful for all of the control candidate signal lines that propagate a signal to a particular control signal line.

18. The test pattern generation method as claimed in claim 15, wherein in the step of acquiring a signal value, when a plurality of control candidate signal lines are present, a signal transition is set up only for a control candidate signal line having a longest path from the control candidate signal line to the control point while a fixed signal value is set up to the other control candidate signal lines.

19. The test pattern generation method as claimed in claim 15, wherein in the step of selecting a signal line, a path having a maximum value in the number of gates included in a path extending from the control signal line to the control point is selected as the longest path.

20. The test pattern generation method as claimed in claim 15, wherein in the step of selecting a signal line, a path having a maximum value in the number of via holes included in a path extending from the control signal line to the control point is selected as the longest path.

21. The test pattern generation method as claimed in claim 15, wherein in the step of selecting a signal line, a longest path is selected on the basis of delay information of each path extending from the control signal line to the control point.

22. A test pattern generation method for generating a first test pattern and a second test pattern which is provided at a next test cycle, for the purpose of detection of a delay fault that occurs in a test target circuit, the method comprising:
a step of selecting a test target signal line from a plurality of signal lines included in the test target circuit and then setting up a signal transition to the test target signal line;
a first determination step of determining the first and the second test patterns that propagate the signal transition set up to the test target signal line, from the test target signal line to an observation point where a signal is outputted; and
a second determination step of determining the first and the second test patterns that propagate the set-up signal transition from an observation point where a signal is outputted to the test target signal line, wherein
the first determination step includes steps of:
setting up the test target signal line to be a reaching signal line;
acquiring a length of the longest path from the control candidate signal line to any one of control points, for each of one or more reaching candidate signal lines that branch from the reaching signal line, and then selecting a reaching candidate signal line from the reaching candidate signal lines on the basis of the maximum value of the acquired lengths of the longest paths;
performing activation and justification in order to propagate a signal to the selected reaching candidate signal line, and thereby acquiring a signal value to be set up to the signal line included in the test target circuit; and
updating the first and the second test patterns on the basis of the acquired signal value, when the activation and the justification have been successful, and
the second determination step includes steps of:
setting up the test target signal line to be a control signal line;
acquiring a length of the longest path from the control candidate signal line to any one of control points, for each of one or more control candidate signal lines that propagate a signal to the control signal line, and then selecting a control candidate signal line from the control candidate signal lines on the basis of the maximum value of the acquired lengths of the longest paths;
performing activation and justification in order to propagate the signal transition from the selected control candidate signal line to the control signal line, and thereby acquiring a signal value to be set up to the signal line included in the test target circuit; and
determining the first and the second test patterns on the basis of the acquired signal value when the activation and the justification have been successful.

23. The test pattern generation method as claimed in claim 22, wherein the first determination step is performed before the second determination step.

24. The test pattern generation method as claimed in claim 22, wherein the first determination step is performed after the second determination step.

25. The test pattern generation method as claimed in claim 22, further comprising
a step of calculating as a first maximum path length a maximum value of the lengths of the paths from the test target signal line to the observation point and calculating as a second maximum path length a maximum value of the lengths of the paths from the test target signal line to the control point, wherein
when the first maximum path length is longer than the second maximum path length, the first determination step is performed before the second determination step, while when the first maximum path length is shorter than or equal to the second maximum path length, the first determination step is performed after the second determination step.
